(19) United States
(12) Patent Application Publication
(10) Pub. No.: US 2015/0318171 A1
(43) Pub. Date: Nov. 5, 2015

(54) METHOD FOR MANUFACTURING OXIDE

(71) Applicant: Semiconductor Energy Laboratory Co., Ltd., Atsugi-shi (JP)

(72) Inventor: Shunpei YAMAZAKI, Tokyo (JP)

(21) Appl. No.: 14/657,445

(22) Filed: Mar. 13, 2015

(30) Foreign Application Priority Data
May 2, 2014 (JP) 2014-095302
May 16, 2014 (JP) 2014-102747
Jun. 19, 2014 (JP) 2014-126083

(51) Int. Cl. H01L 21/02; C23C 14/35

(52) U.S. Cl. CPC H01L 21/02565; H01L 21/02631; C23C 14/35

(57) ABSTRACT

An oxide that can be used as a semiconductor of a transistor or the like is manufactured. In particular, an oxide having few defects such as grain boundaries is manufactured. By a magnetron sputtering method in which a magnetic field containing a component in a direction parallel to a substrate is applied, the magnetic field includes a region with a magnetic flux density of greater than or equal to 10 G and less than or equal to 100 G, and a target is a crystal body or a polycrystalline body, a crystal in the crystal body or the polycrystalline body is made to have a pellet-like shape, fly in plasma, and be stacked on a formation surface to be arranged parallel or substantially parallel to the formation surface.

### BACKGROUND OF THE INVENTION

1. Field of the Invention

The present invention relates to, for example, an oxide, a transistor, a semiconductor device, and manufacturing methods thereof. The present invention relates to, for example, an oxide, a display device, a light-emitting device, a lighting device, a power storage device, a memory device, a processor, or an electronic device. The present invention relates to a manufacturing method of an oxide, a display device, a liquid crystal display device, a light-emitting device, a memory device, or an electronic device. The present invention relates to a driving method of a semiconductor device, a display device, a liquid crystal display device, a light-emitting device, a memory device, or an electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

2. Description of the Related Art

A technique for forming a transistor by using a semiconductor over a substrate having an insulating surface has attracted attention. The transistor is applied to a wide range of semiconductor devices such as an integrated circuit and a display device. Silicon is known as a semiconductor applicable to a transistor.

As silicon which is used as a semiconductor of a transistor, either amorphous silicon or polycrystalline silicon is used depending on the purpose. For example, in the case of a transistor included in a large display device, it is preferable to use amorphous silicon, which can be used to form a film on a large substrate with the established technique. On the other hand, in the case of a transistor included in a high-performance display device where a driver circuit and a pixel circuit are formed over the same substrate, it is preferable to use polycrystalline silicon, which can be used to form a transistor having a high field-effect mobility. As a method for forming polycrystalline silicon, a method of performing high-temperature heat treatment or laser light treatment on amorphous silicon has been known.

Recently, a transistor which includes an amorphous oxide semiconductor and a transistor which includes an amorphous oxide semiconductor containing a microcrystal have been disclosed (see Patent Document 1). An oxide semiconductor can be formed by a sputtering method or the like, and thus can be used for a semiconductor of a transistor in a large display device. Because a transistor including an oxide semiconductor has high field-effect mobility, a high-performance display device in which, for example, a driver circuit and a pixel circuit are formed over the same substrate can be obtained. In addition, there is an advantage that capital investment can be reduced because part of production equipment for a transistor including amorphous silicon can be retrofitted and utilized.

In 1985, synthesis of an In—Ga—Zn oxide crystal was reported (see Non-Patent Document 1). Furthermore, in 1995, it was reported that an In—Ga—Zn oxide has a homologous structure and is represented by a composition formula InGaO₃(ZnO)ₘ (m is a natural number) (see Non-Patent Document 2).

In 2014, it was reported that a transistor including a crystalline In—Ga—Zn oxide has more excellent electrical characteristics and higher reliability than a transistor including an amorphous In—Ga—Zn oxide (see Non-Patent Document 3 and Non-Patent Document 4). Non-Patent Documents 3 and 4 report that a crystal boundary is not clearly observed in an In—Ga—Zn oxide including a c-axis aligned crystalline oxide semiconductor (CAAC-OS).

It is known that a transistor including an oxide semiconductor has an extremely low leakage current in an off state. For example, a low power consumption CPU and the like utilizing a characteristic of a low leakage current of the transistor including an oxide semiconductor are disclosed (see Patent Document 2). Patent Document 3 discloses that a transistor having high field-effect mobility can be obtained by a well potential formed using an active layer formed of oxide semiconductors.

### REFERENCE

### Patent Document

[Patent Document 1] Japanese Published Patent Application No. 2006-165528
[Patent Document 2] Japanese Published Patent Application No. 2012-257187
[Patent Document 3] Japanese Published Patent Application No. 2012-59860

### Non-Patent Document

[Non-Patent Document 1] N. Kimizuka, and T. Mohri, Journal of Solid State Chemistry, Vol. 60, 1985, pp. 382-384
[Non-Patent Document 2] N. Kimizuka, M. Isobe, and M. Nakamura, Journal of Solid State Chemistry, Vol. 116, 1995, pp. 170-178
[Non-Patent Document 3] S. Yamazaki, H. Suzawa, K. Inoue, K. Kato, T. Hirohashi, K. Okazaki, and N. Kimizuka, Japanese Journal of Applied Physics, Vol. 53, 2014, 04ED18
[Non-Patent Document 4] S. Yamazaki, T. Hirohashi, M. Takahashi, S. Adachi, M. Tsubuku, J. Koezuka, K. Okazaki, Y. Kanzaki, H. Matsukizono, S. Kaneko, S. Mori, and T. Matsuo, Journal of the Society for Information Display, 8 Apr. 2014, 211

### SUMMARY OF THE INVENTION

An object of the present invention is to provide a method for forming an oxide that can be used as a semiconductor of a transistor or the like. In particular, an object of the present invention is to provide a method for forming an oxide having few defects such as grain boundaries.

Another object is to provide a semiconductor device using an oxide as a semiconductor. Another object is to provide a module that includes a semiconductor device using an oxide as a semiconductor. Another object is to provide an electronic device that includes a semiconductor device using an oxide as a semiconductor, or an electronic device that includes a module including a semiconductor device using an oxide as a semiconductor.

Another object is to provide a transistor with favorable electrical characteristics. Another object is to provide a transistor with stable electrical characteristics. Another object is to provide a transistor with high frequency characteristics. Another object is to provide a transistor having a low off-state current. Another object is to provide a semiconductor device including the transistor. Another object is to provide a module including the semiconductor device. Another object is to provide an electronic device including the semiconductor device or the module. Another object is to provide a novel semiconductor device. Another object is to provide a novel module. Another object is to provide a novel electronic device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1) One embodiment of the present invention is a method for manufacturing an oxide, which includes a step of, by a magnetron sputtering method in which a magnetic field containing a component in a direction parallel to a substrate is applied, the magnetic field includes a region with a magnetic flux density of greater than or equal to 10 G and less than or equal to 100 G, and a target is a crystal body or a polycrystalline body, making a crystal in the crystal body or the polycrystalline body have a pellet-like shape, fly in plasma, and be stacked on a formation surface to be arranged parallel or substantially parallel to the formation surface.

(2) Another embodiment of the present invention is the method for manufacturing the oxide of (1), in which the crystal with the pellet-like shape is charged up, and the magnetic field is rotated or moved with a beat of greater than or equal to 0.1 Hz and less than or equal to 1 kHz with respect to the formation surface to arrange the crystal with the pellet-like shape on the formation surface.

(3) Another embodiment of the present invention is a method for manufacturing an oxide, in which the oxide is formed by a magnetron sputtering method; the magnetron sputtering method includes a first step and a second step; a magnetic field containing a component in a direction parallel to a top surface of a substrate is applied in the first step and the second step; a target used in the magnetron sputtering method includes a region with a polycrystalline structure; the target is placed to face the substrate; the target includes a crystal grain; in the first step, the crystal grain has a pellet-like shape and flies in plasma; and in the second step, the crystal grain having the pellet-like shape is stacked on the top surface of the substrate to be arranged parallel or substantially parallel to the top surface.

(4) Another embodiment of the present invention is a method for manufacturing an oxide with a sputtering apparatus, which includes a first step, a second step, and a third step. The sputtering apparatus includes a target, a substrate, and a magnet unit. The target includes indium, zinc, an element M (the element M is aluminum, gallium, yttrium, or tin), and oxygen. The target includes a region with a polycrystalline structure. The target is placed to face the substrate. The magnet unit is placed on a back side of the target and includes a first magnet whose N pole is on the target side, a second magnet whose S pole is on the target side, and a base. A magnetic field is formed between the first magnet and the second magnet. The first step includes a step in which the substrate and the magnet unit are moved or rotated relatively. The first step includes a step in which a potential difference is applied between the target and the substrate to generate plasma. The first step includes a step in which an ion generated in the plasma is made to collide with a front side of the target to separate a flat-plate oxide. The flat-plate oxide includes a first layer, a second layer, and a third layer. The first layer includes the element M, zinc, and oxygen. The second layer includes indium and oxygen. The third layer includes the element M, zinc, and oxygen. The second step includes a step in which the flat-plate oxide is negatively charged by passing through the plasma and then approaches a top surface of the substrate while maintaining a crystal structure. The third step includes a step in which the flat-plate oxide moves over the top surface of the substrate and is then deposited by an effect of the magnetic field and a current. The current flows from the substrate toward the target.

(5) Another embodiment of the present invention is the method for manufacturing the oxide of (4), in which a magnetic flux density of a horizontal magnetic field on the top surface of the substrate is greater than or equal to 10 G and less than or equal to 100 G.

(6) Another embodiment of the present invention is the method for manufacturing the oxide of (4) or (5), in which the magnet unit is rotated about a center of the base, and rotation speed of the magnet unit is greater than or equal to 0.1 Hz and less than or equal to 1 kHz.

(7) Another embodiment of the present invention is the method for manufacturing the oxide of any one of (4) to (6), in which an oxygen atom positioned on a side surface of the flat-plate oxide and bonded to an indium atom, an atom of the element M, or a zinc atom is negatively charged.

(8) Another embodiment of the present invention is the method for manufacturing the oxide of any one of (4) to (7), in which the negatively charged oxygen atoms are made to repel each other to maintain a shape of the flat-plate oxide.

(9) Another embodiment of the present invention is the method for manufacturing the oxide of any one of (4) to (8), in which the flat-plate oxide moves over the top surface of the substrate, the side surface of the flat-plate oxide is bonded to the side surface of the flat-plate oxide that has already been deposited, and the flat-plate oxide is then fixed to the top surface of the substrate.

(10) Another embodiment of the present invention is the method for manufacturing the oxide of any one of (4) to (9), in which when the flat-plate oxide is deposited on the top surface of the substrate, an angle between a normal vector of the top surface of the substrate and a c-axis is greater than or equal to −30° and less than or equal to 30°.

(11) Another embodiment of the present invention is the method for manufacturing the oxide of any one of (4) to (10), in which a composition formula of a crystalline oxide contained in the target is InMO₃(ZnO)ₘ (m is a natural number).

(12) Another embodiment of the present invention is the method for manufacturing the oxide of any one of (4) to (11), in which the ion is a positive oxygen ion.

It is possible to provide a method for forming an oxide that can be used as a semiconductor of a transistor or the like. In particular, it is possible to provide a method for forming an oxide having few defects such as grain boundaries.

It is possible to provide a semiconductor device using an oxide as a semiconductor. It is possible to provide a module that includes a semiconductor device using an oxide as a semiconductor. It is possible to provide an electronic device that includes a semiconductor device using an oxide as a semiconductor, or an electronic device that includes a module including a semiconductor device using an oxide as a semiconductor.

It is possible to provide a transistor with favorable electrical characteristics. It is possible to provide a transistor with stable electrical characteristics. It is possible to provide a transistor with high frequency characteristics. It is possible to provide a transistor having a low off-state current. It is possible to provide a semiconductor device including the transistor. It is possible to provide a module including the semiconductor device. It is possible to provide an electronic device including the semiconductor device or the module. It is possible to provide a novel semiconductor device. It is possible to provide a novel module. It is possible to provide a novel electronic device.

Note that the descriptions of these effects do not disturb the existence of other effects. One embodiment of the present invention does not necessarily achieve all the effects listed above. Other effects will be apparent from and can be derived from the description of the specification, the drawings, the claims, and the like.

### BRIEF DESCRIPTION OF THE DRAWINGS

FIGS. 1A and 1B are a cross-sectional view illustrating an example of a deposition chamber and a top view illustrating an example of a magnet unit.

FIGS. 2A and 2B are a cross-sectional view illustrating an example of a deposition chamber and a top view illustrating an example of a magnet unit.

FIG. 3 is a schematic diagram of a deposition model of a CAAC-OS and illustrates a pellet.

FIG. 4 illustrates a pellet.

FIG. 5 illustrates force applied to a pellet on a formation surface.

FIGS. 6A and 6B illustrate movement of pellets on formation surfaces.

FIGS. 7A and 7B show an InGaZnO₄ crystal.

FIG. 8 is a triangular diagram for explaining composition of an In-M-Zn oxide.

FIG. 9 is a top view illustrating an example of a deposition apparatus.

FIGS. 10A to 10C illustrate a structure example of a deposition apparatus.

FIGS. 11A and 11B are a top view and a cross-sectional view illustrating a transistor of one embodiment of the present invention.

FIGS. 12A and 12B are cross-sectional views each illustrating a transistor of one embodiment of the present invention.

FIGS. 13A and 13B are a top view and a cross-sectional view illustrating a transistor of one embodiment of the present invention.

FIGS. 14A and 14B are a top view and a cross-sectional view illustrating a transistor of one embodiment of the present invention.

FIGS. 15A and 15B are a top view and a cross-sectional view illustrating a transistor of one embodiment of the present invention.

FIGS. 16A and 16B are a top view and a cross-sectional view illustrating a transistor of one embodiment of the present invention.

FIGS. 17A and 17B are cross-sectional views each illustrating a transistor of one embodiment of the present invention.

FIGS. 18A and 18B are each a circuit diagram of a semiconductor device of one embodiment of the present invention.

FIGS. 19A and 19B are each a circuit diagram of a memory device of one embodiment of the present invention.

FIG. 20 is a block diagram illustrating a CPU of one embodiment of the present invention.

FIG. 21 is a circuit diagram of a memory element of one embodiment of the present invention.

FIGS. 22A to 22C are a top view and circuit diagrams of a display device of one embodiment of the present invention.

FIGS. 23A to 23F illustrate electronic devices of embodiments of the present invention.

FIGS. 24A to 24F are TEM images of an In—Ga—Zn oxide deposited by a PLD method.

FIGS. 25A to 25F are TEM images of an In—Ga—Zn oxide deposited by a PLD method.

FIGS. 26A to 26F are TEM images of an In—Ga—Zn oxide deposited by a PLD method.

FIGS. 27A to 27D are TEM images of an In—Ga—Zn oxide deposited by a PLD method.

FIGS. 28A to 28D show a TEM image and electron diffraction patterns of an In—Ga—Zn oxide deposited by a PLD method.

FIGS. 29A to 29D show a TEM image and electron diffraction patterns of an In—Ga—Zn oxide deposited by a PLD method.

FIGS. 30A to 30C show electron diffraction patterns of an In—Ga—Zn oxide deposited by a PLD method.

FIGS. 31A to 31C show electron diffraction patterns of an In—Ga—Zn oxide deposited by a PLD method.

FIGS. 32A to 32D show XRD analysis results of In—Ga—Zn oxides deposited by a PLD method.

FIGS. 33A to 33D show XRD analysis results of In—Ga—Zn oxides deposited by a PLD method.

FIGS. 34A to 34D are schematic diagrams showing a deposition model of a CAAC-OS.

FIG. 35 shows a change in crystal part of an In—Ga—Zn oxide induced by electron irradiation.

FIGS. 36A to 36D are TEM images of In—Ga—Zn oxides.

FIGS. 37A and 37B are a TEM image of an In—Ga—Zn oxide and a graph showing a change in crystal part of the In—Ga—Zn oxide induced by electron irradiation.

FIGS. 38A and 38B are hydrogen concentration profiles in the depth direction of In—Ga—Zn oxides.

FIGS. 39A to 39C are a TEM image and electron diffraction patterns of an In—Ga—Zn oxide.

FIGS. 40A to 40C are a TEM image and electron diffraction patterns of an In—Ga—Zn oxide.

FIGS. 41A to 41C are a graph showing a change in crystal part of an In—Ga—Zn oxide induced by electron irradiation and TEM images thereof.

FIGS. 42A to 42D are a graph showing a change in crystal part of an In—Ga—Zn oxide induced by electron irradiation and TEM images thereof.

FIGS. 43A and 43B are TEM images of an In—Ga—Zn oxide deposited by a PLD method.

FIGS. 44A to 44E are an ADF-STEM image and element mapping images of an In—Ga—Zn oxide deposited by a PLD method.

FIGS. 45A to 45C show electrical characteristics of transistors using In—Ga—Zn oxides deposited by a PLD method.

FIG. 46 shows electrical characteristics of a transistor using an In—Ga—Zn oxide deposited by a PLD method.

### DETAILED DESCRIPTION OF THE INVENTION

Embodiments of the present invention will be described in detail with reference to the drawings. However, the present invention is not limited to the description below, and it is easily understood by those skilled in the art that modes and details disclosed herein can be modified in various ways. Furthermore, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in drawings is sometimes exaggerated for clarity.

A voltage usually refers to a potential difference between a given potential and a reference potential (e.g., a source potential or a ground potential (GND)). A voltage can be referred to as a potential and vice versa.

Note that the ordinal numbers such as “first” and “second” in this specification are used for convenience and do not denote the order of steps or the stacking order of layers. Therefore, for example, the term “first” can be replaced with the term “second”, “third”, or the like as appropriate. In addition, the ordinal numbers in this specification and the like do not correspond to the ordinal numbers which specify one embodiment of the present invention in some cases.

Note that a “semiconductor” includes characteristics of an “insulator” in some cases when the conductivity is sufficiently low, for example. Furthermore, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Furthermore, a “semiconductor” includes characteristics of a “conductor” in some cases when the conductivity is sufficiently high, for example. Furthermore, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. When the semiconductor is an oxide semiconductor, oxygen vacancies may be formed by entry of impurities such as hydrogen, for example. Furthermore, when the semiconductor is silicon, examples of an impurity which changes the characteristics of the semiconductor include oxygen, Group 1 elements except hydrogen, Group 2 elements, Group 13 elements, and Group 15 elements.

In this specification, the phrase “A has a region with a concentration B” includes, for example, the cases where “the concentration in the entire region in a region of A in the depth direction is B”, “the average concentration in a region of A in the depth direction is B”, “the median value of the concentration in a region of A in the depth direction is B”, “the maximum value of the concentration in a region of A in the depth direction is B”, “the minimum value of the concentration in a region of A in the depth direction is B”, “a convergence value of the concentration in a region of A in the depth direction is B”, and “a concentration in a region of A in which a probable value is obtained in measurement is B”.

In this specification, the phrase “A has a region with a size B, a length B, a thickness B, a width B, or a distance B” includes, for example, “the size, the length, the thickness, the width, or the distance of the entire region in a region of A is B”, “the average value of the size, the length, the thickness, the width, or the distance of a region of A is B”, “the median value of the size, the length, the thickness, the width, or the distance of a region of A is B”, “the maximum value of the size, the length, the thickness, the width, or the distance of a region of A is B”, “the minimum value of the size, the length, the thickness, the width, or the distance of a region of A is B”, “a convergence value of the size, the length, the thickness, the width, or the distance of a region of A is B”, and “the size, the length, the thickness, the width, or the distance of a region of A in which a probable value is obtained in measurement is B”.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of the semiconductor in some cases. In that case, an effective channel width obtained when a channel is actually formed is greater than an apparent channel width shown in the top view.

In a transistor having a three-dimensional structure, an effective channel width is difficult to measure in some cases. For example, estimation of an effective channel width from a design value requires an assumption that the shape of a semiconductor is known. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may denote a surrounded channel width or an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A has a shape such that an end portion extends beyond an end portion of B” may indicate, for example, the case where at least one of end portions of A is positioned on an outer side than at least one of end portions of B in a top view or a cross-sectional view. Thus, the description “A has a shape such that an end portion extends beyond an end portion of B” can be alternatively referred to as the description “one of end portions of A is positioned on an outer side than one of end portions of B”.

### <Sputtering Apparatus>

A sputtering apparatus of one embodiment of the present invention and a method for forming an oxide having crystallinity with the sputtering apparatus are described below.

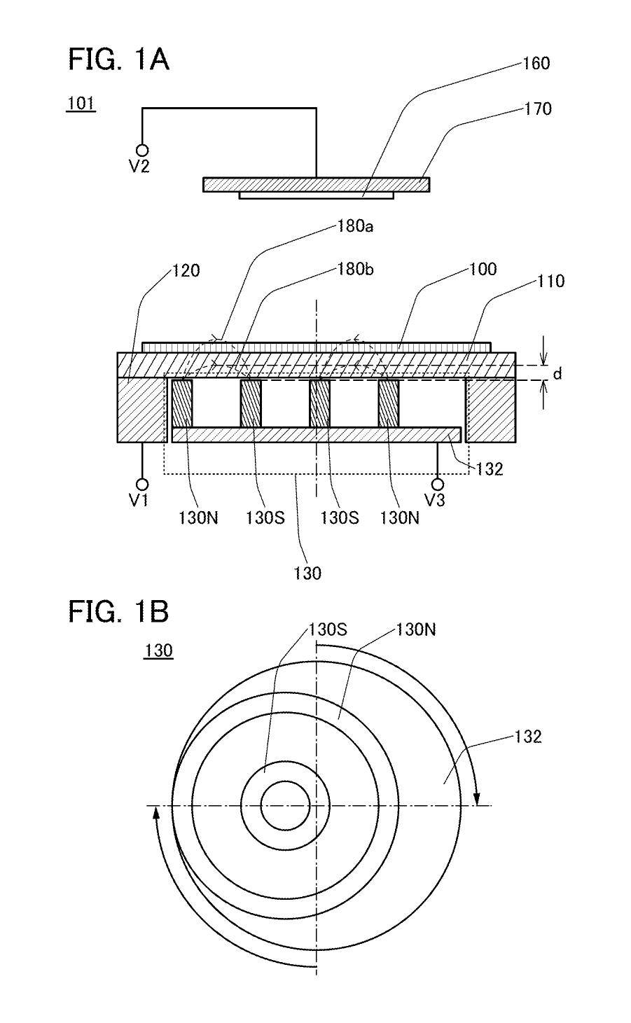

FIG. 1A is a cross-sectional view of a deposition chamber 101 that is a sputtering apparatus. The deposition chamber 101 in FIG. 1A includes a target holder 120, a backing plate 110, a target 100, a magnet unit 130, and a substrate holder 170. Note that the target 100 is placed over the backing plate 110. The backing plate 110 is placed over the target holder 120. The magnet unit 130 is placed under the target 100 with the backing plate 110 positioned therebetween. The substrate holder 170 faces the target 100. Note that in this specification, a magnet unit means a group of magnets. The magnet unit can be replaced with “cathode”, “cathode magnet”, “magnetic member”, “magnetic part”, or the like. The magnet unit 130 includes a magnet 130N, a magnet 130S, and a magnet holder 132. Note that in the magnet unit 130, the magnet 130N and the magnet 130S are placed over the magnet holder 132. The magnet 130N and the magnet 130S are spaced. When a substrate 160 is transferred into the deposition chamber 101, the substrate 160 is placed on the substrate holder 170.

The target holder 120 and the backing plate 110 are fixed to each other with a bolt and have the same potential. The target holder 120 has a function of supporting the target 100 with the backing plate 110 positioned therebetween.

The backing plate 110 has a function of fixing the target 100.

FIG. 1A illustrates a magnetic force line 180a and a magnetic force line 180b formed by the magnet unit 130.

The magnetic force line 180a is one of magnetic force lines that form a horizontal magnetic field in the vicinity of a top surface of the target 100. The vicinity of the top surface of the target 100 corresponds to a region in which the vertical distance from the top surface of the target 100 is, for example, greater than or equal to 0 mm and less than or equal to 10 mm, in particular, greater than or equal to 0 mm and less than or equal to 5 mm. Note that the top surface of the target means a surface to be sputtered. The top surface can also be called, for example, a bottom surface, a side surface, a front surface, a surface to be processed, or the like depending on the orientation of the target.

The magnetic force line 180b is one of magnetic force lines that form a horizontal magnetic field in a plane apart from the top surface of the magnet unit 130 by a vertical distance d. The vertical distance d is, for example, greater than or equal to 0 mm and less than or equal to 20 mm or greater than or equal to 5 mm and less than or equal to 15 mm. Note that the top surface of the magnet unit means a surface thereof on the target side. The top surface can also be called, for example, a bottom surface, a side surface, a front surface, or the like depending on the orientation of the magnet unit.

Here, with the use of the strong magnet 130N and the strong magnet 130S, an intense magnetic field can be generated in the vicinity of the top surface of the substrate 160. Specifically, the magnetic flux density of the horizontal magnetic field on the top surface of the substrate 160 can be greater than or equal to 10 G and less than or equal to 100 G, preferably greater than or equal to 15 G and less than or equal to 60 G, further preferably greater than or equal to 20 G and less than or equal to 40 G. When the magnetic flux density of the horizontal magnetic field on the top surface of the substrate 160 is in the above range, a deposition model described later can be realized. Note that the top surface of the substrate means a surface over which a film is formed. The top surface can also be called, for example, a bottom surface, a side surface, a front surface, a formation surface, or the like depending on the orientation of the substrate.

Note that the magnetic flux density of the horizontal magnetic field may be measured when the magnetic flux density of the vertical magnetic field is 0 G.

By setting the magnetic flux density of the magnetic field in the deposition chamber 101 to be in the above range, an oxide with high density and high crystallinity can be deposited. The deposited oxide hardly includes plural kinds of crystal phases and is a substantially-single crystalline phase.

FIG. 1B is a top view of the magnet unit 130. In the magnet unit 130, the circular or substantially circular magnet 130N and the circular or substantially circular magnet 130S are fixed to the magnet holder 132. The magnet unit 130 can be rotated about a normal vector at the center of the top surface of the magnet unit 130 or a normal vector substantially at the center of the top surface of the magnet unit 130. For example, the magnet unit 130 may be rotated with a beat (also referred to as rhythm, pulse, frequency, period, cycle, or the like) of greater than or equal to 0.1 Hz and less than or equal to 1 kHz.

Thus, a region where a magnetic field on the target 100 is intense changes as the magnet unit 130 is rotated. The region with an intense magnetic field is a high-density plasma region; thus, sputtering of the target 100 easily occurs in the vicinity of the region. For example, when the region with an intense magnetic field is fixed, only a specific region of the target 100 is used. In contrast, when the magnet unit 130 is rotated as shown in FIG. 1B, the target 100 can be uniformly used. By rotating the magnet unit 130, a film with a uniform thickness and uniform quality can be deposited.

By rotating the magnet unit 130, the direction of the magnetic force line on the top surface of the substrate 160 can also be changed.

Although the magnet unit 130 is rotated in this example, one embodiment of the present invention is not limited to this example. For example, the magnet unit 130 may be oscillated vertically or horizontally. For example, the magnet unit 130 may be moved with a beat of greater than or equal to 0.1 Hz and less than or equal to 1 kHz. Alternatively, the target 100 may be rotated or moved. For example, the target 100 may be rotated or moved with a beat of greater than or equal to 0.1 Hz and less than or equal to 1 kHz. Further alternatively, the direction of a magnetic force line on the top surface of the substrate 160 may be changed relatively by rotating the substrate 160. These methods may be combined.

The deposition chamber 101 may have a water channel inside or under the backing plate 110. By making fluid (air, nitrogen, a rare gas, water, oil, or the like) flow through the water channel, discharge anomaly due to an increase in the temperature of the target 100 or damage to the deposition chamber 101 due to deformation of a component can be prevented in the sputtering. In that case, the backing plate 110 and the target 100 are preferably adhered to each other with a bonding member because the cooling capability is increased.

A gasket is preferably provided between the target holder 120 and the backing plate 110, in which case an impurity is less likely to enter the deposition chamber 101 from the outside or the water channel.

In the magnet unit 130, the magnet 130N and the magnet 130S are placed such that their surfaces on the target 100 side have opposite polarities. Here, the case where the pole of the magnet 130N on the target 100 side is the north pole and the pole of the magnet 130S on the target 100 side is the south pole is described. Note that the layout of the magnets and the poles in the magnet unit 130 are not limited to those described here or those illustrated in FIG. 1A.

In the deposition, a potential V1 applied to a terminal V1 connected to the target holder 120 is, for example, lower than a potential V2 applied to a terminal V2 connected to the substrate holder 170. The potential V2 applied to the terminal V2 connected to the substrate holder 170 is, for example, the ground potential. A potential V3 applied to a terminal V3 connected to the magnet holder 132 is, for example, the ground potential. Note that the potentials applied to the terminals V1, V2, and V3 are not limited to the above description. Not all the target holder 120, the substrate holder 170, and the magnet holder 132 are necessarily supplied with potentials. For example, the substrate holder 170 may be electrically floating. Note that although the potential V1 is applied to the terminal V1 connected to the target holder 120 (i.e., a DC sputtering method is employed) in the example illustrated in FIG. 1A, one embodiment of the present invention is not limited thereto. For example, it is possible to employ what is called an RF sputtering method, in which case a high-frequency power supply with a frequency of 13.56 MHz or 27.12 MHz, for example, is connected to the target holder 120.

FIG. 1A illustrates an example where the backing plate 110 and the target holder 120 are not electrically connected to the magnet unit 130 and the magnet holder 132, but electrical connection is not limited thereto. For example, the backing plate 110 and the target holder 120 may be electrically connected to the magnet unit 130 and the magnet holder 132, and the backing plate 110, the target holder 120, the magnet unit 130, and the magnet holder 132 may have the same potential.

To increase the crystallinity of the formed oxide, the temperature of the substrate 160 may be set high. By setting the temperature of the substrate 160 high, migration of sputtered particles at the top surface of the substrate 160 can be promoted. Thus, an oxide with higher density and higher crystallinity can be deposited. Note that the temperature of the substrate 160 is, for example, higher than or equal to 100° C. and lower than or equal to 450° C., preferably higher than or equal to 150° C. and lower than or equal to 400° C., more preferably higher than or equal to 170° C. and lower than or equal to 350° C.

When the partial pressure of oxygen in the deposition gas is too high, an oxide including plural kinds of crystal phases is likely to be deposited; therefore, a mixed gas of oxygen and a rare gas such as argon (other examples of the rare gas are helium, neon, krypton, and xenon) is preferably used as the deposition gas. For example, the proportion of oxygen in the whole deposition gas is less than 50 vol %, preferably less than or equal to 33 vol %, more preferably less than or equal to 20 vol %, further more preferably less than or equal to 15 vol %.

The vertical distance between the target 100 and the substrate 160 is greater than or equal to 10 mm and less than or equal to 600 mm, preferably greater than or equal to 20 mm and less than or equal to 400 mm, more preferably greater than or equal to 30 mm and less than or equal to 200 mm, further more preferably greater than or equal to 40 mm and less than or equal to 100 mm. Within the above range, the vertical distance between the target 100 and the substrate 160 is small enough to suppress a decrease in the energy of the sputtered particles until the sputtered particles reach the substrate 160 in some cases. Within the above range, the vertical distance between the target 100 and the substrate 160 is large enough to make the incident direction of the sputtered particle approximately vertical to the substrate 160, so that damage to the substrate 160 caused by collision of the sputtered particles can be reduced in some cases.

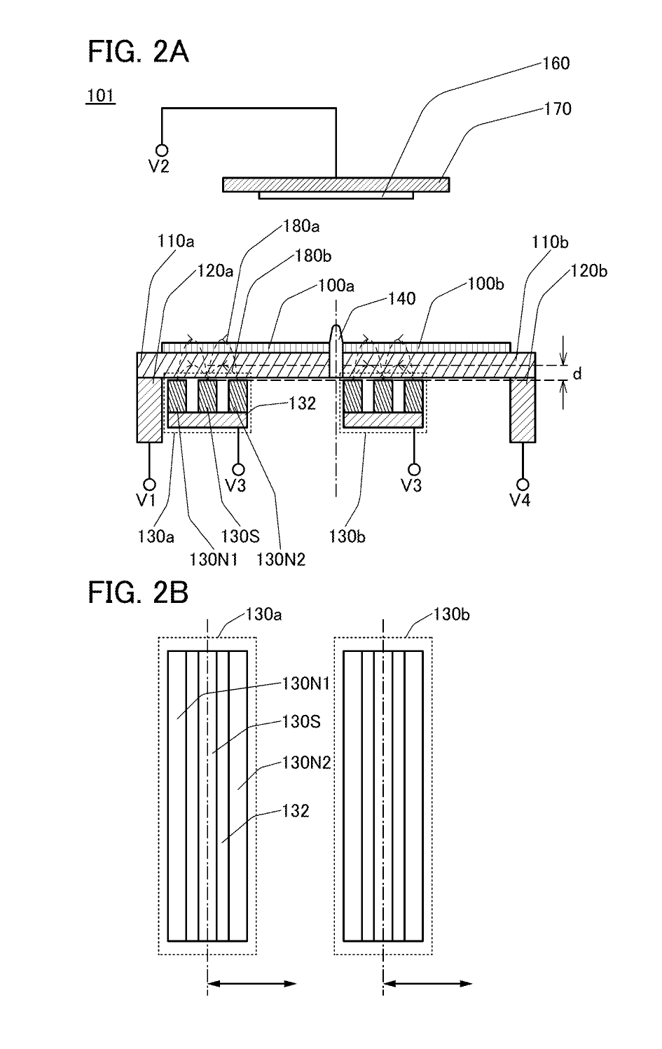

FIG. 2A illustrates an example of a deposition chamber different from that in FIG. 1A.

The deposition chamber 101 in FIG. 2A includes a target holder 120a, a target holder 120b, a backing plate 110a, a backing plate 110b, a target 100a, a target 100b, a magnet unit 130a, a magnet unit 130b, a member 140, and the substrate holder 170. Note that the target 100a is placed over the backing plate 110a. The backing plate 110a is placed over the target holder 120a. The magnet unit 130a is placed under the target 100a with the backing plate 110a positioned therebetween. The target 100b is placed over the backing plate 110b. The backing plate 110b is placed over the target holder 120b. The magnet unit 130b is placed under the target 100b with the backing plate 110b positioned therebetween.

The magnet unit 130a includes a magnet 130N1, a magnet 130N2, the magnet 130S, and the magnet holder 132. Note that in the magnet unit 130a, the magnet 130N1, the magnet 130N2, and the magnet 130S are placed over the magnet holder 132. The magnet 130N1, the magnet 130N2, and the magnet 130S are spaced. Note that the magnet unit 130b has a structure similar to that of the magnet unit 130a. When the substrate 160 is transferred into the deposition chamber 101, the substrate 160 is placed on the substrate holder 170.

The target 100a, the backing plate 110a, and the target holder 120a are separated from the target 100b, the backing plate 110b, and the target holder 120b by the member 140. Note that the member 140 is preferably an insulator. The member 140 may be a conductor or a semiconductor. The member 140 may be a conductor or a semiconductor whose surface is covered with an insulator.

The target holder 120a and the backing plate 110a are fixed to each other with a bolt and have the same potential. The target holder 120a has a function of supporting the target 100a with the backing plate 110a positioned therebetween. The target holder 120b and the backing plate 110b are fixed to each other with a bolt and have the same potential. The target holder 120b has a function of supporting the target 100b with the backing plate 110b positioned therebetween.

The backing plate 110a has a function of fixing the target 100a. The backing plate 110b has a function of fixing the target 100b.

FIG. 2A illustrates the magnetic force line 180a and the magnetic force line 180b formed by the magnet unit 130a.

The magnetic force line 180a is one of magnetic force lines that form a horizontal magnetic field in the vicinity of a top surface of the target 100a. The vicinity of the top surface of the target 100a corresponds to a region in which the vertical distance from the top surface of the target 100a is, for example, greater than or equal to 0 mm and less than or equal to 10 mm, in particular, greater than or equal to 0 mm and less than or equal to 5 mm.

The magnetic force line 180b is one of magnetic force lines that form a horizontal magnetic field in a plane apart from the top surface of the magnet unit 130a by a vertical distance d. The vertical distance d is, for example, greater than or equal to 0 mm and less than or equal to 20 mm or greater than or equal to 5 mm and less than or equal to 15 mm.

Here, with the use of the strong magnet 130N1, the strong magnet 130N2, and the strong magnet 130S, an intense magnetic field can be generated in the vicinity of the top surface of the substrate 160. Specifically, the magnetic flux density of the horizontal magnetic field on the top surface of the substrate 160 can be greater than or equal to 10 G and less than or equal to 100 G, preferably greater than or equal to 15 G and less than or equal to 60 G, further preferably greater than or equal to 20 G and less than or equal to 40 G. When the magnetic flux density of the horizontal magnetic field on the top surface of the substrate 160 is in the above range, a deposition model described later can be realized.

By setting the magnetic flux density of the magnetic field in the deposition chamber 101 to be in the above range, an oxide with high density and high crystallinity can be deposited. The deposited oxide hardly includes plural kinds of crystal phases and is a substantially-single crystalline phase.

Note that the magnet unit 130b forms a magnetic force line similar to that formed by the magnet unit 130a.

FIG. 2B is a top view of the magnet units 130a and 130b. In the magnet unit 130a, the rectangular or substantially rectangular magnet 130N1, the rectangular or substantially rectangular magnet 130N2, and the rectangular or substantially rectangular magnet 130S are fixed to the magnet holder 132. The magnet unit 130a can be oscillated horizontally as shown in FIG. 2B. For example, the magnet unit 130a may be oscillated with a beat of greater than or equal to 0.1 Hz and less than or equal to 1 kHz.

Thus, a region where a magnetic field on the target 100a is intense changes as the magnet unit 130a is oscillated. The region with an intense magnetic field is a high-density plasma region; thus, sputtering of the target 100a easily occurs in the vicinity of the region. For example, when the region with an intense magnetic field is fixed, only a specific region of the target 100a is used. In contrast, when the magnet unit 130a is oscillated as shown in FIG. 2B, the target 100a can be uniformly used. By oscillating the magnet unit 130a, a film with a uniform thickness and uniform quality can be deposited.

By oscillating the magnet unit 130a, the state of the magnetic force line on the top surface of the substrate 160 can also be changed. The same applies to the magnet unit 130b.

Although the magnet unit 130a and the magnet unit 130b are oscillated in this example, one embodiment of the present invention is not limited to this example. For example, the magnet unit 130a and the magnet unit 130b may be rotated. For example, the magnet unit 130a and the magnet unit 130b may be rotated with a beat of greater than or equal to 0.1 Hz and less than or equal to 1 kHz. Alternatively, the target 100 may be rotated or moved. For example, the target 100 may be rotated or moved with a beat of greater than or equal to 0.1 Hz and less than or equal to 1 kHz. Further alternatively, the state of a magnetic force line on the top surface of the substrate 160 may be changed relatively by rotating the substrate 160. These methods may be combined.

The deposition chamber 101 may have a water channel inside or under the backing plate 110a and the backing plate 110b. By making fluid (air, nitrogen, a rare gas, water, oil, or the like) flow through the water channel, discharge anomaly due to an increase in the temperature of the target 100a and the target 100b or damage to the deposition chamber 101 due to deformation of a component can be prevented in the sputtering. In that case, the backing plate 110a and the target 100a are preferably adhered to each other with a bonding member because the cooling capability is increased. Furthermore, the backing plate 110b and the target 100b are preferably adhered to each other with a bonding member because the cooling capability is increased.

A gasket is preferably provided between the target holder 120a and the backing plate 110a, in which case an impurity is less likely to enter the deposition chamber 101 from the outside or the water channel. A gasket is preferably provided between the target holder 120b and the backing plate 110b, in which case an impurity is less likely to enter the deposition chamber 101 from the outside or the water channel.

In the magnet unit 130a, the magnets 130N1 and 130N2 and the magnet 130S are placed such that their surfaces on the target 100a side have opposite polarities. Here, the case where the pole of each of the magnets 130N1 and 130N2 on the target 100a side is the north pole and the pole of the magnet 130S on the target 100a side is the south pole is described. Note that the layout of the magnets and the poles in the magnet unit 130a are not limited to those described here or those illustrated in FIG. 2A. The same applies to the magnet unit 103b.

In the deposition, a potential whose level is varied between a high level and a low level is applied to the terminal V1 connected to the target holder 120a and a terminal V4 connected to the target holder 120b. The potential V2 applied to the terminal V2 connected to the substrate holder 170 is, for example, the ground potential. A potential V3 applied to a terminal V3 connected to the magnet holder 132 is, for example, the ground potential. Note that the potentials applied to the terminals V1, V2, V3, and V4 are not limited to the above description. Not all the target holder 120a, the target holder 120b, the substrate holder 170, and the magnet holder 132 are necessarily supplied with potentials. For example, the substrate holder 170 may be electrically floating. Note that the potential whose level is varied between the high level and the low level is applied to the terminal V1 connected to the target holder 120a and the terminal V4 connected to the target holder 120b (i.e., an AC sputtering method is employed) in the example illustrated in FIG. 2A; however, one embodiment of the present invention is not limited thereto.

FIG. 2A illustrates an example where the backing plate 110a and the target holder 120a are not electrically connected to the magnet unit 130a and the magnet holder 132, but electrical connection is not limited thereto. For example, the backing plate 110a and the target holder 120a may be electrically connected to the magnet unit 130a and the magnet holder 132, and the backing plate 110a, the target holder 120a, the magnet unit 130a, and the magnet holder 132 may have the same potential. The backing plate 110b and the target holder 120b are not electrically connected to the magnet unit 130b and the magnet holder 132 in the example, but electrical connection is not limited thereto. For example, the backing plate 110b and the target holder 120b may be electrically connected to the magnet unit 130b and the magnet holder 132, and the backing plate 110b, the target holder 120b, the magnet unit 130b, and the magnet holder 132 may have the same potential.

To increase the crystallinity of the formed oxide, the temperature of the substrate 160 may be set high. By setting the temperature of the substrate 160 high, migration of sputtered particles at the top surface of the substrate 160 can be promoted. Thus, an oxide with higher density and higher crystallinity can be deposited. Note that the temperature of the substrate 160 is, for example, higher than or equal to 100° C. and lower than or equal to 450° C., preferably higher than or equal to 150° C. and lower than or equal to 400° C., more preferably higher than or equal to 170° C. and lower than or equal to 350° C.

When the partial pressure of oxygen in the deposition gas is too high, an oxide including plural kinds of crystal phases is likely to be deposited; therefore, a mixed gas of oxygen and a rare gas such as argon (other examples of the rare gas are helium, neon, krypton, and xenon) is preferably used as the deposition gas. For example, the proportion of oxygen in the whole deposition gas is less than 50 vol %, preferably less than or equal to 33 vol %, more preferably less than or equal to 20 vol %, further more preferably less than or equal to 15 vol %.

The vertical distance between the target 100a and the substrate 160 is greater than or equal to 10 mm and less than or equal to 600 mm, preferably greater than or equal to 20 mm and less than or equal to 400 mm, more preferably greater than or equal to 30 mm and less than or equal to 200 mm, further more preferably greater than or equal to 40 mm and less than or equal to 100 mm. Within the above range, the vertical distance between the target 100a and the substrate 160 is small enough to suppress a decrease in the energy of the sputtered particles until the sputtered particles reach the substrate 160 in some cases. Within the above range, the vertical distance between the target 100a and the substrate 160 is large enough to make the incident direction of the sputtered particle approximately vertical to the substrate 160, so that damage to the substrate 160 caused by collision of the sputtered particles can be reduced in some cases.

The vertical distance between the target 100b and the substrate 160 is greater than or equal to 10 mm and less than or equal to 600 mm, preferably greater than or equal to 20 mm and less than or equal to 400 mm, more preferably greater than or equal to 30 mm and less than or equal to 200 mm, further more preferably greater than or equal to 40 mm and less than or equal to 100 mm. Within the above range, the vertical distance between the target 100b and the substrate 160 is small enough to suppress a decrease in the energy of the sputtered particles until the sputtered particles reach the substrate 160 in some cases. Within the above range, the vertical distance between the target 100b and the substrate 160 is large enough to make the incident direction of the sputtered particle approximately vertical to the substrate 160, so that damage to the substrate 160 caused by collision of the sputtered particles can be reduced in some cases.

### <Oxide>

An oxide of one embodiment of the present invention is described below.

### <Structure of Oxide Semiconductor>

The structure of an oxide semiconductor is described below. Note that an oxide semiconductor means an oxide having semiconductor properties.

In this specification, the term “parallel” indicates that the angle formed between two straight lines is greater than or equal to −10° and less than or equal to 10°, and accordingly also includes the case where the angle is greater than or equal to −5° and less than or equal to 5°. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. The term “substantially perpendicular” indicates that the angle formed between two straight lines is greater than or equal to 60° and less than or equal to 120°.

In this specification, trigonal and rhombohedral crystal systems are included in a hexagonal crystal system.

Oxide semiconductors are classified roughly into a single-crystal oxide semiconductor and a non-single-crystal oxide semiconductor. The non-single-crystal oxide semiconductor includes any of a CAAC-OS, a polycrystalline oxide semiconductor, a microcrystalline oxide semiconductor, an amorphous oxide semiconductor, and the like.

First, a CAAC-OS is described.

The CAAC-OS is an oxide semiconductor having a plurality of c-axis aligned crystal parts.

With a transmission electron microscope (TEM), a combined analysis image (high-resolution TEM image) of a bright-field image and a diffraction pattern of the CAAC-OS is observed, and a plurality of crystal parts can be clearly observed. However, in the high-resolution TEM image, a boundary between crystal parts, that is, a grain boundary is not clearly observed. Thus, in the CAAC-OS, a reduction in electron mobility due to the grain boundary is less likely to occur.

According to the high-resolution cross-sectional TEM image of the CAAC-OS observed in a direction substantially parallel to a sample surface, metal atoms are arranged in a layered manner in the crystal parts. Each metal atom layer reflects unevenness of a surface over which the CAAC-OS is formed (hereinafter a surface over which the CAAC-OS is formed is referred to as a formation surface) or a top surface of the CAAC-OS, and is arranged parallel to the formation surface or the top surface of the CAAC-OS.

In the high-resolution plan-view TEM image of the CAAC-OS observed in a direction substantially perpendicular to the sample surface, metal atoms arranged in a triangular or hexagonal configuration are seen in the crystal parts. However, there is no regularity of arrangement of metal atoms between different crystal parts.

A CAAC-OS is subjected to structural analysis with an X-ray diffraction (XRD) apparatus. For example, when the CAAC-OS including an InGaZnO₄ crystal is analyzed by an out-of-plane method, a peak appears frequently at a diffraction angle (2 θ) of around 31°. This peak is derived from the (0 0 9) plane of the InGaZnO₄ crystal, which indicates that crystals in the CAAC-OS have c-axis alignment, and that the c-axes are aligned in a direction substantially perpendicular to the formation surface or the top surface of the CAAC-OS.

When the CAAC-OS with an InGaZnO₄ crystal is analyzed by an out-of-plane method, a peak may also be observed at 2 θ of around 36° as well as at 2 θ of around 31°. The peak at 28 of around 36° indicates that a crystal having no c-axis alignment is included in part of the CAAC-OS. It is preferable that in the CAAC-OS, a peak appear at 2 θ of around 31° and a peak not appear at 2 θ of around 36°.

The CAAC-OS is an oxide semiconductor having low impurity concentration. The impurity is an element other than the main components of the oxide semiconductor, such as hydrogen, carbon, silicon, or a transition metal element. In particular, an element that has higher bonding strength to oxygen than a metal element included in the oxide semiconductor, such as silicon, disturbs the atomic arrangement of the oxide semiconductor by depriving the oxide semiconductor of oxygen and causes a decrease in crystallinity. A heavy metal such as iron or nickel, argon, carbon dioxide, or the like has a large atomic radius (molecular radius), and thus disturbs the atomic arrangement of the oxide semiconductor and causes a decrease in crystallinity when it is contained in the oxide semiconductor. Note that the impurity contained in the oxide semiconductor might serve as a carrier trap or a carrier generation source.

The CAAC-OS is an oxide semiconductor having a low density of defect states. In some cases, oxygen vacancies in the oxide semiconductor serve as carrier traps or serve as carrier generation sources when hydrogen is captured therein.

The state in which the impurity concentration is low and the density of defect states is low (the number of oxygen vacancies is small) is referred to as a “highly purified intrinsic” or “substantially highly purified intrinsic” state. A highly purified intrinsic or substantially highly purified intrinsic oxide semiconductor has few carrier generation sources, and thus can have a low carrier density. Thus, a transistor including the oxide semiconductor rarely has negative threshold voltage (rarely has normally-on characteristics). The highly purified intrinsic or substantially highly purified intrinsic oxide semiconductor has few carrier traps. Consequently, the transistor including the oxide semiconductor has little variation in electrical characteristics and high reliability. Electric charge trapped by the carrier traps in the oxide semiconductor takes a long time to be released and might behave like fixed electric charge. Thus, the transistor including the oxide semiconductor having high impurity concentration and a high density of defect states has unstable electrical characteristics in some cases.

With the use of the CAAC-OS in a transistor, variation in the electrical characteristics of the transistor due to irradiation with visible light or ultraviolet light is small.

Next, a microcrystalline oxide semiconductor is described.

In a high-resolution TEM image of a microcrystalline oxide semiconductor, there are a region where a crystal part is observed and a region where a crystal part is not clearly observed. In most cases, a crystal part in the microcrystalline oxide semiconductor ranges from 1 nm to 100 nm, or from 1 nm to 10 nm. A microcrystal with a size in the range of 1 nm to 10 nm or of 1 nm to 3 nm is specifically referred to as nanocrystal (nc). An oxide semiconductor including nanocrystal is referred to as a nanocrystalline oxide semiconductor (nc-OS). In a high-resolution TEM image of the nc-OS, a grain boundary cannot be found clearly in some cases.

In the nc-OS, a microscopic region (e.g., a region with a size ranging from 1 nm to 10 nm, in particular, from 1 nm to 3 nm) has a periodic atomic order. There is no regularity of crystal orientation between different crystal parts in the nc-OS. Thus, the orientation of the whole film is not observed. Consequently, in some cases, the nc-OS cannot be distinguished from an amorphous oxide semiconductor depending on an analysis method. For example, when the nc-OS is subjected to structural analysis by an out-of-plane method with an XRD apparatus using an X-ray having a diameter larger than that of a crystal part, a peak showing a crystal plane does not appear. A diffraction pattern like a halo pattern appears in a selected-area electron diffraction pattern of the nc-OS obtained by using an electron beam having a probe diameter larger than the diameter of a crystal part (e.g., having a probe diameter of 50 nm or larger). Meanwhile, spots are shown in a nanobeam electron diffraction pattern of the nc-OS obtained by using an electron beam having a probe diameter close to or smaller than the diameter of a crystal part. Furthermore, in a nanobeam electron diffraction pattern of the nc-OS, regions with high luminance in a circular (ring) pattern are sometimes shown. Also in a nanobeam electron diffraction pattern of the nc-OS, a plurality of spots are sometimes shown in a ring-like region.

The nc-OS is an oxide semiconductor that has higher regularity than an amorphous oxide semiconductor, and therefore has a lower density of defect states than an amorphous oxide semiconductor. However, there is no regularity of crystal orientation between different crystal parts in the nc-OS; hence, the nc-OS has a higher density of defect states than the CAAC-OS.

Next, an amorphous oxide semiconductor is described.

The amorphous oxide semiconductor has disordered atomic arrangement and no crystal part. An example of the amorphous oxide semiconductor is an oxide semiconductor with a non-crystalline state like quartz.

In a high-resolution TEM image of the amorphous oxide semiconductor, crystal parts cannot be found.

When the amorphous oxide semiconductor is subjected to structural analysis by an out-of-plane method with an XRD apparatus, a peak showing a crystal plane does not appear. A halo pattern is shown in an electron diffraction pattern of the amorphous oxide semiconductor. Furthermore, a halo pattern is shown but a spot is not shown in a nanobeam electron diffraction pattern of the amorphous oxide semiconductor.

Note that an oxide semiconductor may have a structure with physical properties between the nc-OS and the amorphous oxide semiconductor. The oxide semiconductor having such a structure is specifically referred to as an amorphous-like oxide semiconductor (a-like OS).

In a high-resolution TEM image of the a-like OS, a void may be seen. Furthermore, in the high-resolution TEM image, there are a region where a crystal part is clearly observed and a region where a crystal part is not observed. In the a-like OS, crystallization occurs by a slight amount of electron beam used for TEM observation and growth of the crystal part is found in some cases. In contrast, crystallization due to a slight amount of electron beam used for TEM observation is hardly observed in the nc-OS having good quality.

Note that the crystal part size in the a-like OS and the nc-OS can be measured using high-resolution TEM images. For example, an InGaZnO₄ crystal has a layered structure in which two Ga—Zn—O layers are included between In—O layers. A unit cell of the InGaZnO₄ crystal has a structure in which nine layers of three In—O layers and six Ga—Zn—O layers are layered in the c-axis direction. Thus, the spacing between these adjacent layers is substantially equivalent to the lattice spacing (also referred to as d value) on the (0 0 9) plane, and is 0.29 nm according to crystal structure analysis. Consequently, focusing on the lattice fringes in the high-resolution TEM image, lattice fringes with a spacing ranging from 0.28 nm to 0.30 nm each correspond to the a-b plane of the InGaZnO₄ crystal.

The density of an oxide semiconductor might vary depending on its structure. For example, when the composition of an oxide semiconductor becomes clear, the structure of the oxide semiconductor can be estimated from a comparison between the density of the oxide semiconductor and the density of a single crystal oxide semiconductor having the same composition as the oxide semiconductor. For instance, the density of an a-like OS is 78.6% or higher and lower than 92.3% of the density of the single crystal oxide semiconductor. In addition, for example, the density of an nc-OS or a CAAC-OS is 92.3% or higher and lower than 100% of the density of the single crystal oxide semiconductor. Note that it is difficult to deposit an oxide semiconductor whose density is lower than 78% of the density of the single crystal oxide semiconductor.

A specific example of the above is described. For example, in an oxide semiconductor with an atomic ratio of In:Ga:Zn=1:1:1, the density of single crystal InGaZnO₄ with a rhombohedral crystal structure is 6.357 g/cm³. Thus, for example, the density of an a-like OS with an atomic ratio of In:Ga:Zn=1:1:1 is higher than or equal to 5.0 g/cm³ and lower than 5.9 g/cm³. Moreover, for example, the density of an nc-OS or a CAAC-OS with an atomic ratio of In:Ga:Zn=1:1:1 is higher than or equal to 5.9 g/cm³ and lower than 6.3 g/cm³.

Note that single crystals with the same composition do not exist in some cases. In such a case, by combining single crystals with different compositions at a given proportion, it is possible to calculate a density that corresponds to the density of a single crystal with a desired composition. The density of the single crystal with a desired composition may be calculated using weighted average with respect to the combination ratio of the single crystals with different compositions. Note that it is preferable to combine as few kinds of single crystals as possible for density calculation.

### <Property of Oxide Semiconductor>

A difference in physical property between structures of an oxide semiconductor is described below.

Samples A, B, and C are prepared. Each of the samples is an In—Ga—Zn oxide.

First, high-resolution cross-sectional TEM images of the samples A to C are obtained. The high-resolution cross-sectional TEM images show that all the samples A to C have crystal parts.

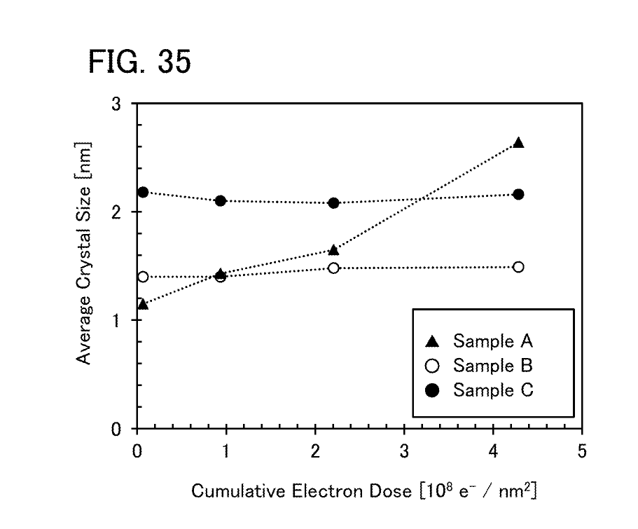

Then, the sizes of the crystal parts of the samples A to C are measured. For the method for measuring the size of a crystal part, description of the structure of an oxide semiconductor is to be referred to. FIG. 35 shows the change in average size of crystal parts (at 22 points to 45 points) in each of the samples A to C. FIG. 35 indicates that the crystal part size in the sample A increases with an increase in the cumulative electron dose. Specifically, a crystal part of approximately 1.2 nm at the start of TEM observation grows to a size of approximately 2.6 nm at a cumulative electron dose of 4.2×10⁸ e⁻/nm². In contrast, the crystal part size in the samples B and C shows little change from the start of electron irradiation to a cumulative electron dose of 4.2×10⁸ e⁻/nm² regardless of the cumulative electron dose.

According to the above classification, the sample A is an a-like OS. Furthermore, the samples B and C are not an a-like OS. Note that according to the high-resolution cross-sectional TEM images, the sample B is an nc-OS. The sample C is a CAAC-OS.

Furthermore, in FIG. 35, by linear approximation of the change in crystal part size in the samples A to C and extrapolation to the cumulative electron dose of 0 e⁻/nm², the average size of the crystal part is found to have a positive value. This means that the crystal parts exist in the samples A to C before the TEM observation. Table 1 shows change in size of the crystal parts and the like for the samples A to C.

TABLE 1

| | | Cumulative | Cumulative | Cumulative | Cumulative |
|---|---|---|---|---|---|
| | | irradiation | irradiation | irradiation | irradiation |
| Sample | | time: 0 min | time: 2 min | time: 5 min | time: 10 min |
| A | Average [nm] | 2.18 | 2.10 | 2.08 | 2.16 |
| | Standard deviation | 0.63 | 0.54 | 0.67 | 0.66 |
| | Minimum [nm] | 1.00 | 1.11 | 1.03 | 1.06 |
| | Maximum [nm] | 3.41 | 3.30 | 3.52 | 3.56 |
| | Number of points | 31 | 30 | 31 | 30 |
| B | Average [nm] | 1.40 | 1.40 | 1.48 | 1.49 |
| | Standard deviation | 0.24 | 0.29 | 0.31 | 0.29 |
| | Minimum [nm] | 0.84 | 1.00 | 0.98 | 1.02 |
| | Maximum [nm] | 1.89 | 2.13 | 2.34 | 2.10 |
| | Number of points | 29 | 22 | 23 | 30 |
| C | Average [nm] | 1.15 | 1.43 | 1.65 | 2.64 |
| | Standard deviation | 0.21 | 0.52 | 0.83 | 1.40 |
| | Minimum [nm] | 0.84 | 0.79 | 0.94 | 0.83 |
| | Maximum [nm] | 1.82 | 3.04 | 5.40 | 5.97 |
| | Number of points | 32 | 39 | 45 | 38 |

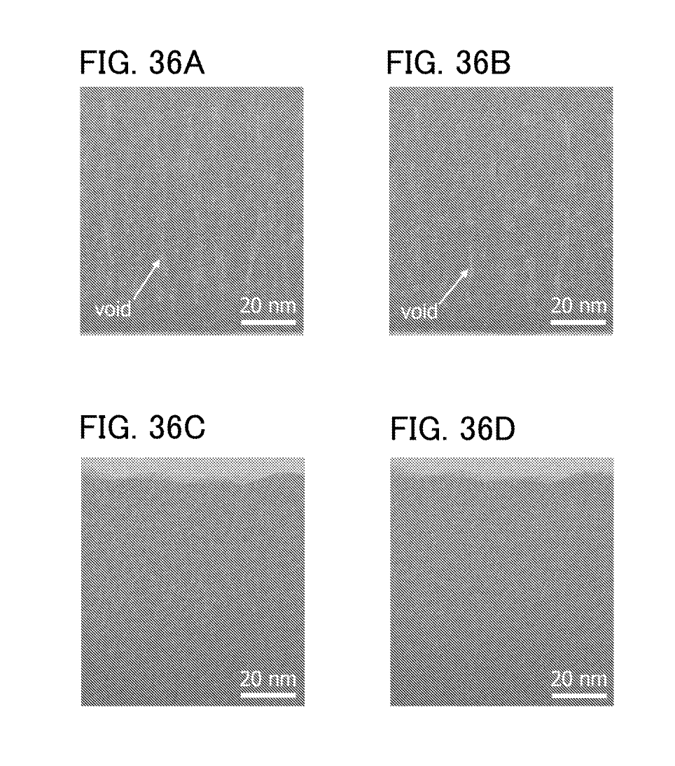

FIGS. 36A to 36D show high-resolution cross-sectional TEM images of the samples A and B. FIG. 36A is the high-resolution cross-sectional TEM image of the sample A at the start of the electron irradiation. FIG. 36B is the high-resolution cross-sectional TEM image of the sample A after the electron irradiation. FIG. 36C is the high-resolution cross-sectional TEM image of the sample B at the start of the electron irradiation. FIG. 36D is the high-resolution cross-sectional TEM image of the sample B after the electron irradiation. Note that the cumulative electron dose is 4.3×10⁸ e⁻/nm².

FIGS. 36A and 36B show that stripe-like bright regions extending vertically are observed in the sample A from the start of the electron irradiation. It can be also found that the shape of the bright region changes after the electron irradiation. Note that the bright region is presumably a void or a low-density region. Meanwhile, as can be seen from FIGS. 36C and 36D, no bright regions are observed in the sample B at the start of the electron irradiation or after the electron irradiation.

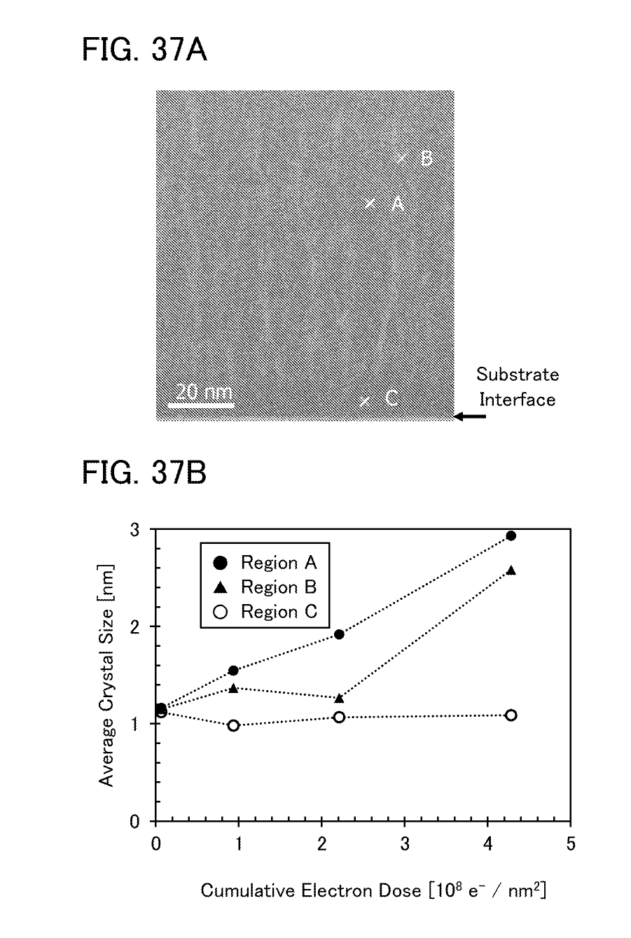

Next, change in size of a crystal part in the TEM observation region in the sample A by electron irradiation is measured. Note that FIG. 37A shows regions to be measured. The vicinity of the bright region is denoted as a region A. A portion between bright regions is denoted as a region B. A bottom part of the sample A in which no bright regions are observed is denoted as a region C.

FIG. 37B shows the results. From FIG. 37B, it can be found that the region A shows the most significant change in size of a crystal part and the region B shows the second most significant change in size of a crystal part. In the region C, the size of a crystal part after the electron irradiation is hardly different from that at the start of the electron irradiation. The significant change in size of a crystal part in each of the regions A and B can be probably attributed to an unstable structure due to closeness to the bright region observed in the high-resolution cross-sectional TEM image.

Then, whether oxides deposited by a sputtering method under a variety of conditions (samples D, E, F, G, H, I, and J) are an nc-OS or an a-like OS is determined. Note that the deposition conditions for a CAAC-OS are not used. Here, not only change in crystal part size due to electron irradiation but also the density and hardness are measured. Note that the density can be measured by an X-ray reflectivity (XRR) method or the like. Hardness can be measured by a nanoindentation method using TriboScope manufactured by Hysitron, Inc., or the like.

Observation of high-resolution cross-sectional TEM images is performed in the following manner. First, high-resolution cross-sectional TEM observation is performed on a range with a diameter of 400 nm for two minutes with the amount of electron irradiation being 5.5×10⁴ e⁻/(nm²s). Next, electron irradiation is performed on a range with a diameter of 230 nm for 10 minutes with the amount of electron irradiation being 6.7×10⁵ e⁻/(nm²s). Then, high-resolution cross-sectional TEM observation is performed on a range with a diameter of 400 nm for two minutes with the amount of electron irradiation being 5.5×10⁴ e⁻/(nm²s). Next, electron irradiation is performed on a range with a diameter of 230 nm for eight minutes with the amount of electron irradiation being 6.7×10⁵ e⁻/(nm²s). Finally, high-resolution cross-sectional TEM observation is performed on a range with a diameter of 400 nm for two minutes with the amount of electron irradiation being 5.5×10⁴ e⁻/(nm²s). When change in size of a crystal part is seen in a high-resolution cross-sectional TEM image during the above process, the oxide is determined to be an a-like OS. When the size of a crystal part in a high-resolution cross-sectional TEM image does not change during the above process, the oxide is determined to be an nc-OS.

Deposition conditions and determination results are listed in Table 2.

TABLE 2

| | | | | | | Deposition | | | |
|---|---|---|---|---|---|---|---|---|---|
| | Power | Ar | O₂ | H₂O | Pressure | rate | Density | Hardness | Determination |
| Sample | [W] | [sccm] | [sccm] | [sccm] | [Pa] | [nm/min] | [g/cm³] | [GPa] | results by TEM |
| D | 70 | 66 | 1.3 | 2.5 | 1.0 | 1.14 | 5.05 | 6.12 | a-like OS |
| E | 70 | 98 | 2.0 | 0 | 1.0 | 0.24 | 5.48 | 6.59 | a-like OS |
| F | 100 | 98 | 2.0 | 0 | 1.0 | 0.48 | 5.57 | 6.72 | a-like OS |
| G | 200 | 98 | 2.0 | 0 | 1.0 | 1.84 | 5.85 | 7.61 | a-like OS |
| H | 300 | 98 | 2.0 | 0 | 1.0 | 3.97 | 5.91 | 7.77 | nc-OS |
| I | 100 | 98 | 2.0 | 0 | 0.4 | 1.78 | 6.10 | 7.85 | nc-OS |
| J | 100 | 98 | 2.0 | 0 | 1.0 | 3.13 | 5.55 | 6.71 | a-like OS |

Note that the device used for the sample D is different from that used for the other samples.

As Table 2 shows, the density of the samples determined to be an a-like OS is from 5.05 g/cm³ to 5.85 g/cm³. The density of the samples determined to be an nc-OS is from 5.91 g/cm³ to 6.10 g/cm³. The hardness of the samples determined to be an a-like OS is from 6.12 GPa to 7.61 GPa. The hardness of the samples determined to be an nc-OS is from 7.77 GPa to 7.85 GPa. In other words, an nc-OS has higher density and hardness than an a-like OS.

Next, to compare the properties of an a-like OS and an nc-OS, a sample K and a sample L are newly prepared and subjected to measurement of hydrogen concentration profiles in the depth direction by secondary ion mass spectrometry (SIMS). Note that the sample K is an a-like OS. The sample L has a stacked-layer structure formed by depositing an nc-OS without exposure to the air over an a-like OS that is deposited under the same conditions as the sample K.

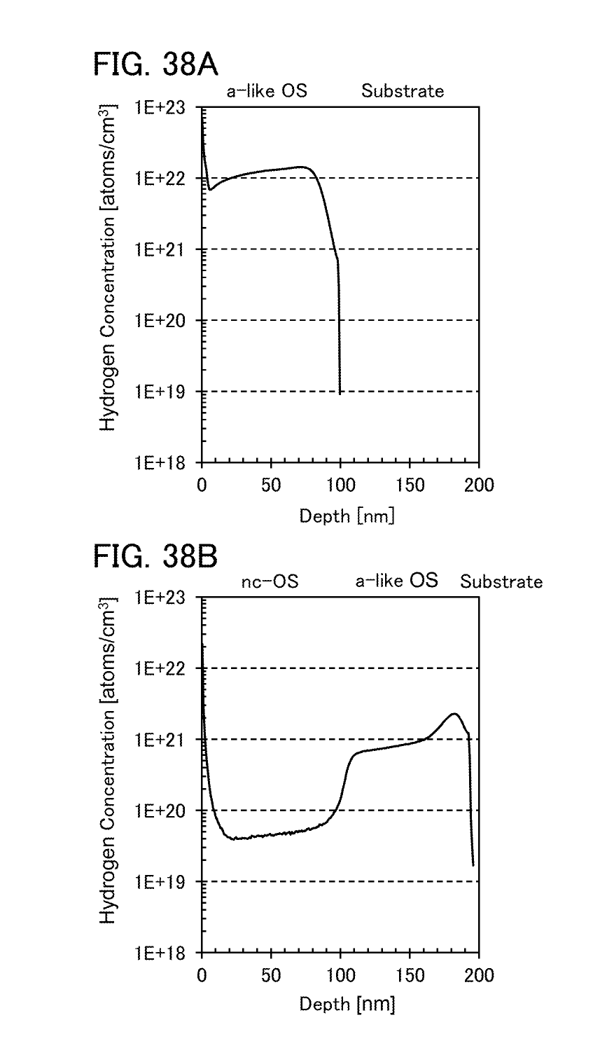

FIGS. 38A and 38B show the results. FIG. 38A shows the hydrogen concentration profile of the sample K, and FIG. 38B shows the hydrogen concentration profile of the sample L. From FIG. 38A, it is found that the hydrogen concentration of the a-like OS exceeds 1×10²² atoms/cm³ in a region. From FIG. 38B, it is found that the hydrogen concentration of the a-like OS is from 5×10²⁰ atoms/cm³ to 2×10²¹ atoms/cm³ in a region, and the hydrogen concentration of the nc-OS is from 5×10¹⁹ atoms/cm³ to 7×10¹⁹ atoms/cm³ in a region.

Accordingly, hydrogen concentration immediately after the deposition is higher in the a-like OS than in the nc-OS. The hydrogen concentration of the a-like OS is low when the a-like OS is capped with the nc-OS, which suggests that the a-like OS absorbs moisture or the like in the air when exposed to the air.

### <Deposition Model>

An example of a deposition model of a CAAC-OS is described below.

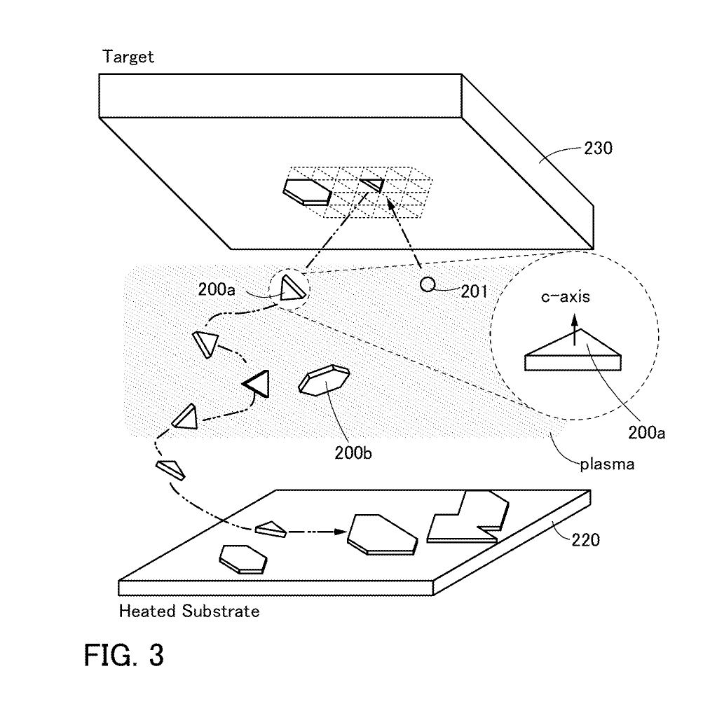

FIG. 3 is a schematic diagram of the inside of a deposition chamber where a CAAC-OS is deposited by a sputtering method.

A target 230 is attached to a backing plate. A plurality of magnets are provided to face the target 230 with the backing plate positioned therebetween. The plurality of magnets generate a magnetic field. The above description on the deposition chamber is referred to for the layout and structure of magnets. A sputtering method in which the disposition rate is increased by utilizing a magnetic field of magnets is called a magnetron sputtering method.

The target 230 has a polycrystalline structure in which a cleavage plane exists in at least one crystal grain. Note that the details of the cleavage plane are described later.

A substrate 220 is placed to face the target 230, and the distance d (also referred to as a target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 5 vol % or higher) and the pressure in the deposition chamber is controlled to be higher than or equal to 0.01 Pa and lower than or equal to 100 Pa, preferably higher than or equal to 0.1 Pa and lower than or equal to 10 Pa. Here, discharge starts by application of a voltage at a certain value or higher to the target 230, and plasma is observed. The magnetic field forms a high-density plasma region in the vicinity of the target 230. In the high-density plasma region, the deposition gas is ionized, so that an ion 201 is generated. Examples of the ion 201 include an oxygen cation (O⁺) and an argon cation (Ar⁺).

The ion 201 is accelerated toward the target 230 side by an electric field, and then the ion 201 collides with the target 230. At this time, a pellet 200a and a pellet 200b, which are flat-plate-like (pellet-like) sputtered particles, are separated and sputtered from the cleavage plane. Note that structures of the pellet 200a and the pellet 200b may be distorted by an impact of collision of the ion 201.

The pellet 200a is a flat-plate-like (pellet-like) sputtered particle having a triangle plane, e.g., regular triangle plane. The pellet 200b is a flat-plate-like (pellet-like) sputtered particle having a hexagon plane, e.g., regular hexagon plane. Note that flat-plate-like (pellet-like) sputtered particles such as the pellet 200a and the pellet 200b are collectively called pellets. The shape of a flat plane of the pellet is not limited to a triangle or a hexagon. For example, the flat plane may have a shape formed by combining two or more triangles. For example, a quadrangle (e.g., rhombus) may be formed by combining two triangles (e.g., regular triangles).

The thickness of the pellet is determined depending on the kind of deposition gas and the like. The thicknesses of the pellets are preferably uniform; the reason for this is described later. In addition, the sputtered particle preferably has a pellet shape with a small thickness as compared to a dice shape with a large thickness. For example, the thickness of the pellet is greater than or equal to 0.4 nm and less than or equal to 1 nm, preferably greater than or equal to 0.6 nm and less than or equal to 0.8 nm. In addition, for example, the width of the pellet is greater than or equal to 1 nm and less than or equal to 3 nm, preferably greater than or equal to 1.2 nm and less than or equal to 2 nm.

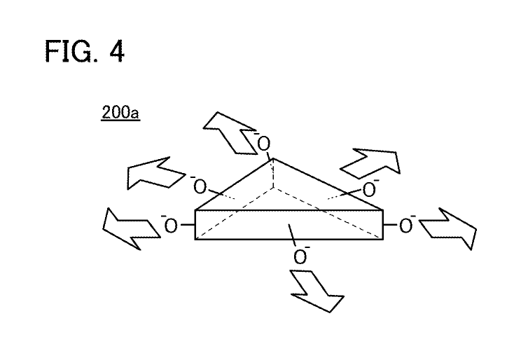

The pellet may receive a charge when passing through the plasma, so that side surfaces thereof are negatively or positively charged. The pellet includes an oxygen atom on its side surface, and the oxygen atom may be negatively charged. For example, a case in which the pellet 200a includes, on its side surfaces, oxygen atoms that are negatively charged is illustrated in FIG. 4. In this manner, when the side surfaces are charged with the same polarity, charges repel each other, and accordingly, the pellet 200a can maintain a flat-plate shape. In the case where a CAAC-OS is an In—Ga—Zn oxide, there is a possibility that an oxygen atom bonded to an indium atom is negatively charged. There is another possibility that an oxygen atom bonded to an indium atom, a gallium atom, or a zinc atom is negatively charged.

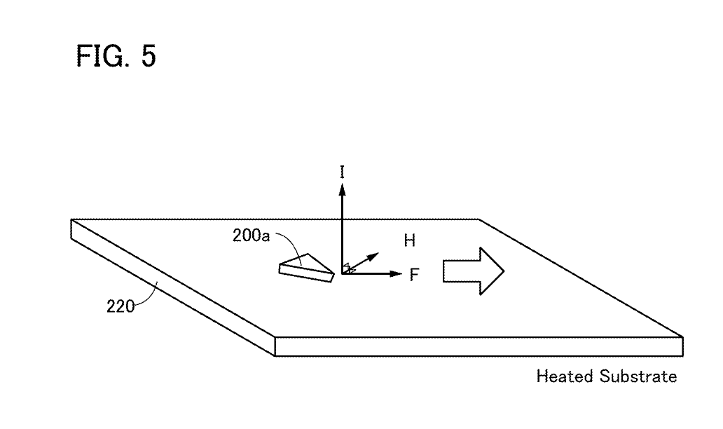

As illustrated in FIG. 3, the pellet 200a flies like a kite in plasma and flutters up to the substrate 220. Since the pellets 200a are charged, when the pellet 200a gets close to a region where another pellet has already been deposited, repulsion is generated. Here, above the substrate 220, a magnetic field in a direction parallel to the top surface of the substrate 220 (also referred to as a horizontal magnetic field) is generated. A potential difference is given between the substrate 220 and the target 230, and accordingly, a current flows from the substrate 220 toward the target 230. Thus, the pellet 200a is given a force (Lorentz force) on the top surface of the substrate 220 by an effect of the magnetic field and the current (see FIG. 5). This is explainable with Fleming's left-hand rule.

The mass of the pellet is larger than that of an atom. Therefore, to move the pellet over the top surface of the substrate 220, it is important to apply some force to the pellet from the outside. One kind of force may be force which is generated by the action of a magnetic field and a current. In order to increase a force applied to the pellet, it is preferable to provide, on the top surface, a region where a magnetic flux density of the magnetic field in a direction parallel to the top surface of the substrate 220 is 10 G or higher, preferably 20 G or higher, further preferably 30 G or higher, still further preferably 50 G or higher. Alternatively, it is preferable to provide, on the top surface, a region where the magnetic field in a direction parallel to the top surface of the substrate 220 is 1.5 times or higher, preferably twice or higher, further preferably 3 times or higher, still further preferably 5 times or higher as high as the magnetic field in a direction perpendicular to the top surface of the substrate 220.

At this time, the magnet units and/or the substrate 220 are/is moved or rotated relatively, whereby the direction of the horizontal magnetic field on the top surface of the substrate 220 continues to change. Therefore, the pellet can be moved in various directions on the top surface of the substrate 220 by receiving forces in various directions.

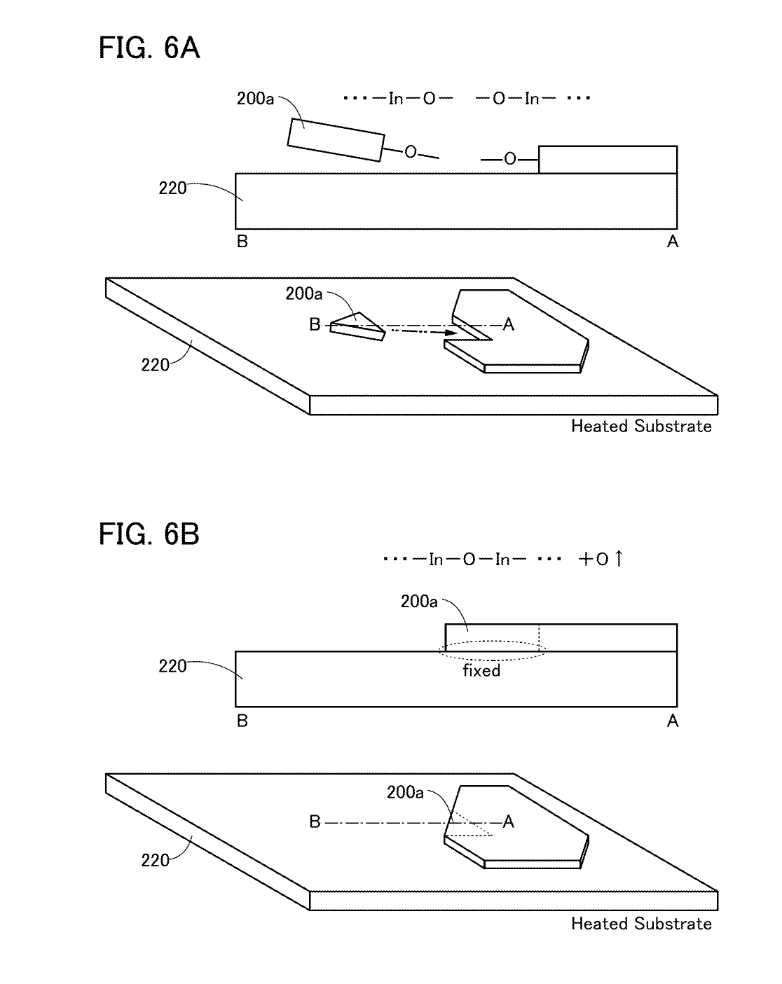

Furthermore, the substrate 220 is heated, and the resistance such as friction between the pellet and the substrate 220 is low. As a result, the pellet 200a glides above the top surface of the substrate 220 as illustrated in FIG. 6A. The glide of the pellet 200a is caused in a state where its flat plane faces the substrate 220. Then, when the pellet 200a reaches the side surface of another pellet that has been already deposited, the side surfaces of the pellets are bonded and the pellet is fixed to the substrate 220 as illustrated in FIG. 6B. At this time, the oxygen atom is released. With the released oxygen atom, oxygen vacancies in a CAAC-OS might be filled; thus, the CAAC-OS has a low density of defect states.

Furthermore, the pellet is heated on the substrate 220, whereby atoms are rearranged, and the structure distortion caused by the collision of the ion 201 can be reduced. The pellet whose structure distortion is reduced is substantially single crystal. Even when the pellets are heated after being bonded, expansion and contraction of the pellet itself hardly occur, which is caused by turning the pellet into substantially single crystal. Thus, formation of defects such as a grain boundary due to expansion of a space between the pellets can be prevented, and accordingly, generation of crevasses can be prevented.

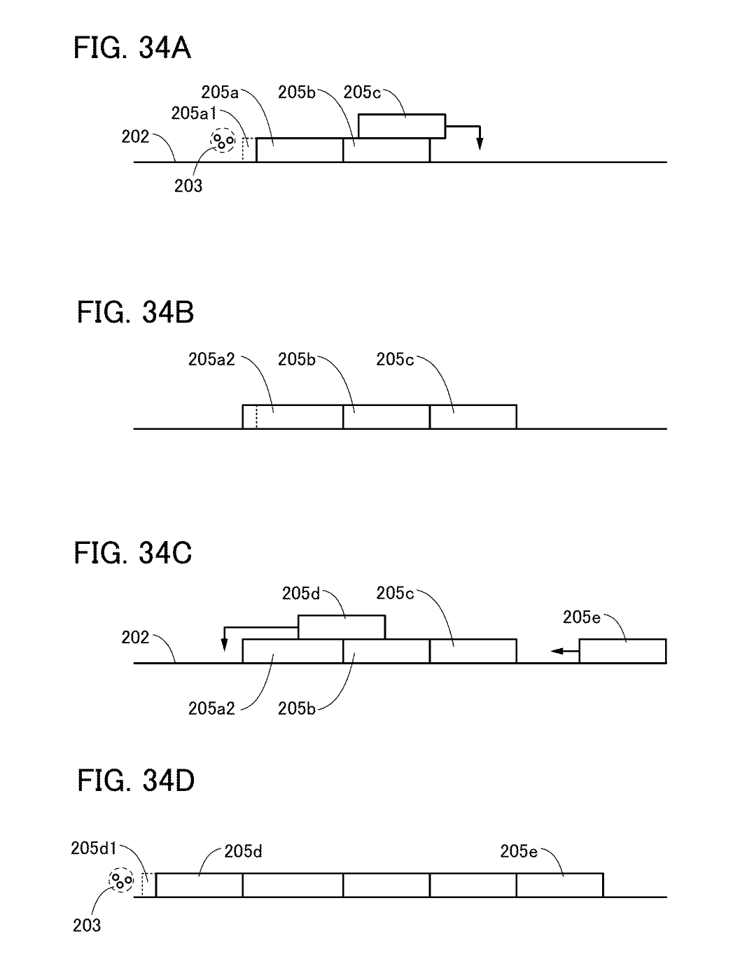

When the target 230 is sputtered with the ion 201, in addition to the pellets, zinc oxide or the like may be ejected. The zinc oxide is lighter than the pellet and thus reaches the top surface of the substrate 220 before the pellet. As a result, the zinc oxide forms a zinc oxide layer 202 with a thickness greater than or equal to 0.1 nm and less than or equal to 10 nm, greater than or equal to 0.2 nm and less than or equal to 5 nm, or greater than or equal to 0.5 nm and less than or equal to 2 nm. FIGS. 34A to 34D are schematic cross-sectional diagrams. Note that the description of the substrate 220 is omitted here.

As illustrated in FIG. 34A, a pellet 205a and a pellet 205b are deposited over the zinc oxide layer 202. Here, side surfaces of the pellet 205a and the pellet 205b are in contact with each other. In addition, a pellet 205c is deposited over the pellet 205b, and then glides over the pellet 205b. Furthermore, a plurality of particles 203 ejected from the target together with the zinc oxide is crystallized by heating of the substrate 220 to form a region 205a1 on another side surface of the pellet 205a. Note that the plurality of particles 203 may contain oxygen, zinc, indium, gallium, or the like.

Then, as illustrated in FIG. 34B, the region 205a1 grows to part of the pellet 205a to form a pellet 205a2. In addition, a side surface of the pellet 205c is in contact with another side surface of the pellet 205b.

Next, as illustrated in FIG. 34C, a pellet 205d is deposited over the pellet 205a2 and the pellet 205b, and then glides over the pellet 205a2 and the pellet 205b. Furthermore, a pellet 205e glides toward another side surface of the pellet 205c over the zinc oxide layer 202.

Then, as illustrated in FIG. 34D, the pellet 205d is placed so that a side surface of the pellet 205d is in contact with a side surface of the pellet 205a2. Furthermore, a side surface of the pellet 205e is in contact with another side surface of the pellet 205c. A plurality of particles 203 ejected from the target together with the zinc oxide is crystallized by heating of the substrate 220 to form a region 205d1 on another side surface of the pellet 205d.

As described above, placement of deposited pellets to be in contact with each other, crystal growth caused at side surfaces of the pellets, and the like are repeated, whereby a CAAC-OS is formed over the substrate 220.

When spaces between the pellets are extremely small, the pellets may form a large pellet. The large pellet has a single crystal structure. For example, the size of the large pellet may be greater than or equal to 10 nm and less than or equal to 200 nm, greater than or equal to 15 nm and less than or equal to 100 nm, or greater than or equal to 20 nm and less than or equal to 50 nm, when seen from the above. Therefore, when a channel formation region of a transistor is smaller than the large pellet, the region having a single crystal structure can be used as the channel formation region. Furthermore, when the size of the pellet is increased, the region having a single crystal structure can be used as the channel formation region, the source region, and the drain region of the transistor in some cases.

In this manner, when the channel formation region or the like of the transistor is formed in a region having a single crystal structure, the frequency characteristics of the transistor can be increased in some cases.

It is considered that as shown in such a model, the pellets are deposited on the substrate 220. Thus, a CAAC-OS can be deposited even when a formation surface does not have a crystal structure, which is different from film deposition by epitaxial growth. For example, even when the top surface (formation surface) of the substrate 220 has an amorphous structure, a CAAC-OS can be formed.

In addition, it is found that in formation of the CAAC-OS, the pellets are arranged in accordance with the top surface shape of the substrate 220 that is the formation surface even when the formation surface has unevenness. For example, in the case where the top surface of the substrate 220 is flat at the atomic level, the pellets are arranged so that flat planes parallel to the a-b plane face downwards; thus, a layer with a uniform thickness, flatness, and high crystallinity is formed. By stacking n layers (n is a natural number), the CAAC-OS can be obtained.

In the case where the top surface of the substrate 220 has unevenness, a CAAC-OS in which n layers (n is a natural number) in each of which the pellets are arranged along the convex surface are stacked is formed. Since the substrate 220 has unevenness, a gap is easily generated between the pellets in the CAAC-OS in some cases. Note that owing to intermolecular force, the pellets are arranged so that a gap between the pellets is as small as possible even on the unevenness surface. Therefore, even when the formation surface has unevenness, a CAAC-OS with high crystallinity can be obtained.

As a result, laser crystallization is not needed for formation of a CAAC-OS, and a uniform film can be formed even over a large-sized glass substrate or the like.

Since a CAAC-OS is deposited in accordance with such a model, the sputtered particle preferably has a pellet shape with a small thickness. Note that when the sputtered particle has a dice shape with a large thickness, planes facing the substrate 220 are not uniform; thus, the thicknesses and the orientations of the crystals cannot be uniform in some cases.

According to the deposition model described above, a CAAC-OS with high crystallinity can be formed even on a formation surface with an amorphous structure.

### <Cleavage Plane>

A cleavage plane that has been mentioned in the deposition model of the CAAC-OS is described below.

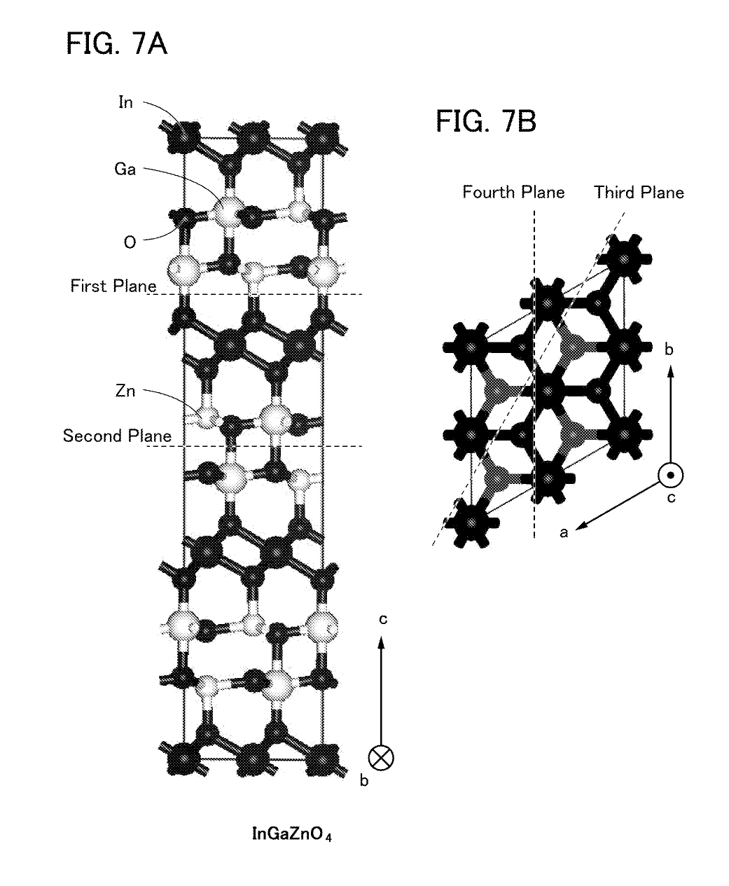

First, a cleavage plane of the target is described with reference to FIGS. 7A and 7B. FIGS. 7A and 7B show the crystal structure of InGaZnO₄. Note that FIG. 7A shows the structure of the case where an InGaZnO₄ crystal is observed from a direction parallel to the b-axis when the c-axis is in an upward direction. Furthermore, FIG. 7B shows the structure of the case where the InGaZnO₄ crystal is observed from a direction parallel to the c-axis.

Energy needed for cleavage at each crystal plane of the InGaZnO₄ crystal is calculated by the first principles calculation. Note that a pseudo potential and a density functional theory program (CASTEP) using the plane wave basis are used for the calculation. An ultrasoft type pseudo potential is used as the pseudo potential. Furthermore, GGA/PBE is used as the functional. Cut-off energy is 400 eV.

Energy of a structure in an initial state is obtained after structural optimization including a cell size is performed. Furthermore, energy of a structure after the cleavage at each plane is obtained after structural optimization of atomic order is performed in a state where the cell size is fixed.

On the basis of the structure of the InGaZnO₄ crystal in FIGS. 7A and 7B, a structure cleaved at any one of a first plane, a second plane, a third plane, and a fourth plane is formed and subjected to structural optimization calculation in which the cell size is fixed. Here, the first plane is a crystal plane between a Ga—Zn—O layer and an In—O layer and is parallel to the (0 0 1) plane (or the a-b plane) (see FIG. 7A). The second plane is a crystal plane between a Ga—Zn—O layer and a Ga—Zn—O layer and is parallel to the (0 0 1) plane (or the a-b plane) (see FIG. 7A). The third plane is a crystal plane parallel to the (1 1 0) plane (see FIG. 7B). The fourth plane is a crystal plane parallel to the (1 0 0) plane (or the b-c plane) (see FIG. 7B).

Under the above conditions, the energy of the structure at each plane after the cleavage is calculated. Next, a difference between the energy of the structure after the cleavage and the energy of the structure in the initial state is divided by the area of the cleavage plane; thus, cleavage energy that serves as a measure of easiness of cleavage at each plane is calculated. Note that the energy of a structure is calculated based on atoms and electrons included in the structure. That is, kinetic energy of the electrons and interactions between the atoms, between the atom and the electron, and between the electrons are considered in the calculation.

As calculation results, the cleavage energy of the first plane is 2.60 J/m², that of the second plane is 0.68 J/m², that of the third plane is 2.18 J/m², and that of the fourth plane is 2.12 J/m² (see Table 3).

TABLE 3

| | Cleavage energy [J/m²] |
|---|---|
| First plane | 2.60 |
| Second plane | 0.68 |
| Third plane | 2.18 |
| Fourth plane | 2.12 |

From the calculations, in the structure of the InGaZnO₄ crystal in FIGS. 7A and 7B, the cleavage energy of the second plane is the lowest. In other words, a plane between a Ga—Zn—O layer and a Ga—Zn—O layer is cleaved most easily (cleavage plane). Therefore, in this specification, the cleavage plane indicates the second plane, which is a plane where cleavage is performed most easily.

Since the cleavage plane is the second plane between the Ga—Zn—O layer and the Ga—Zn—O layer, the InGaZnO₄ crystals in FIG. 7A can be separated at a plane equivalent to two second planes. Thus, in the case where an ion or the like is made to collide with a target, a wafer-like unit (we call this a pellet) that is cleaved at a plane with the lowest cleavage energy is thought to be blasted off as the minimum unit. In that case, a pellet of InGaZnO₄ includes three layers: a Ga—Zn—O layer, an In—O layer, and a Ga—Zn—O layer.

The cleavage energies of the third plane (crystal plane parallel to the (1 1 0) plane) and the fourth plane (crystal plane parallel to the (1 0 0) plane (or the b-c plane)) are lower than that of the first plane (crystal plane between the Ga—Zn—O layer and the In—O layer and crystal plane parallel to the (0 0 1) plane (or the a-b plane)), which suggests that most of the flat planes of the pellets have triangle shapes or hexagonal shapes.

It is suggested that the pellet separated from the target includes a damaged region. In some cases, the damaged region included in the pellet can be repaired in such a manner that a defect caused by the damage reacts with oxygen.

The above calculation shows that when sputtering is performed using a target including the InGaZnO₄ crystal having a homologous structure, separation occurs from the cleavage plane to form a pellet. On the other hand, even when sputtering is performed on a region having another structure of a target without the cleavage plane, a pellet is not formed, and a sputtered particle with an atomic-level size that is minuter than a pellet is formed. Because the sputtered particle is smaller than the pellet, the sputtered particle is thought to be removed through a vacuum pump connected to a sputtering apparatus. Therefore, a model in which particles with a variety of sizes and shapes fly to a substrate and are deposited hardly applies to the case where sputtering is performed using a target including the InGaZnO₄ crystal having a homologous structure. The model in FIG. 3 where sputtered pellets are deposited to form a CAAC-OS is a reasonable model.

The CAAC-OS deposited in this manner has density substantially equal to that of a single crystal OS. For example, the density of the single crystal OS having a homologous structure of InGaZnO₄ is 6.36 g/cm³, and the density of the CAAC-OS having substantially the same atomic ratio is approximately 6.3 g/cm³.

### <Composition>

Composition of a CAAC-OS is described below. For explanation of the composition, the case of an In-M-Zn oxide that is an oxide semiconductor to be a CAAC-OS is described as an example. The element M is aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like.

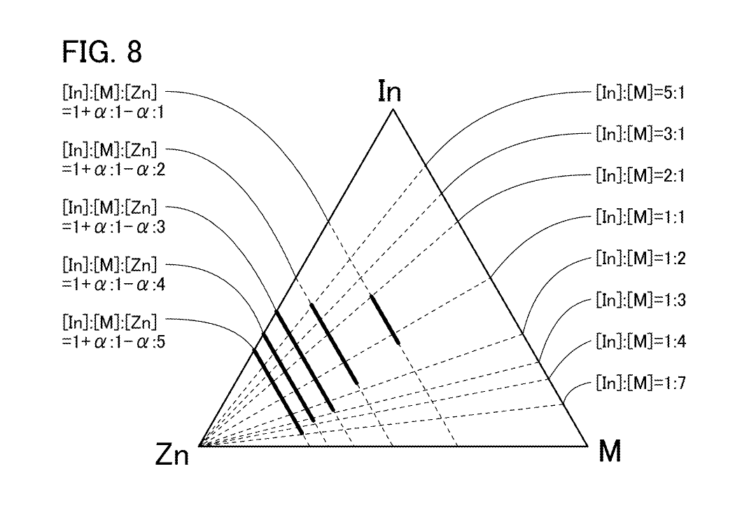

FIG. 8 is a triangular diagram in which the vertices represent In, M, and Zn. In the diagram, [In] means the atomic concentration of In, [M] means the atomic concentration of the element M, and [Zn] means the atomic concentration of Zn.

A crystal of an In-M-Zn oxide is known to have a homologous structure and is represented by InMO₃(ZnO)ₘ (m is a natural number). Since In and M can be interchanged, the crystal can also be represented by In_{1+α}M_{1-α}O₃(ZnO)ₘ. This composition is represented by any of the dashed lines denoted as [In]:[M]:[Zn]=1+α:1−α:1, [In]:[M]:[Zn]=1+α:1−α:2, [In]:[M]:[Zn]=1+α:1−α:3, [In]:[M]:[Zn]=1+α:1−α:4, and [In]:[M]:[Zn]=1+α:1−α:5. Note that the bold line on the dashed line represents, for example, the composition that allows an oxide as a raw material mixed and subjected to baking at 1350° C. to be a solid solution.

Therefore, when an oxide has a composition close to the above composition that allows the oxide to be a solid solution, a CAAC-OS having a large region with a single crystal structure can be obtained.

When a CAAC-OS is deposited, because of heating of a substrate surface (the surface on which the CAAC-OS is deposited), space heating, or the like, the composition of the film is sometimes different from that of a target as a source or the like. For example, since zinc oxide sublimates more easily than indium oxide, gallium oxide, or the like, the source and the film are likely to have different compositions. Thus, a source is preferably selected taking into account the change in composition. Note that a difference between the compositions of the source and the film is also affected by a pressure or a gas used for the deposition as well as a temperature.

### <Deposition Apparatus>

A deposition apparatus including a deposition chamber with which the above-described CAAC-OS can be deposited is described below.

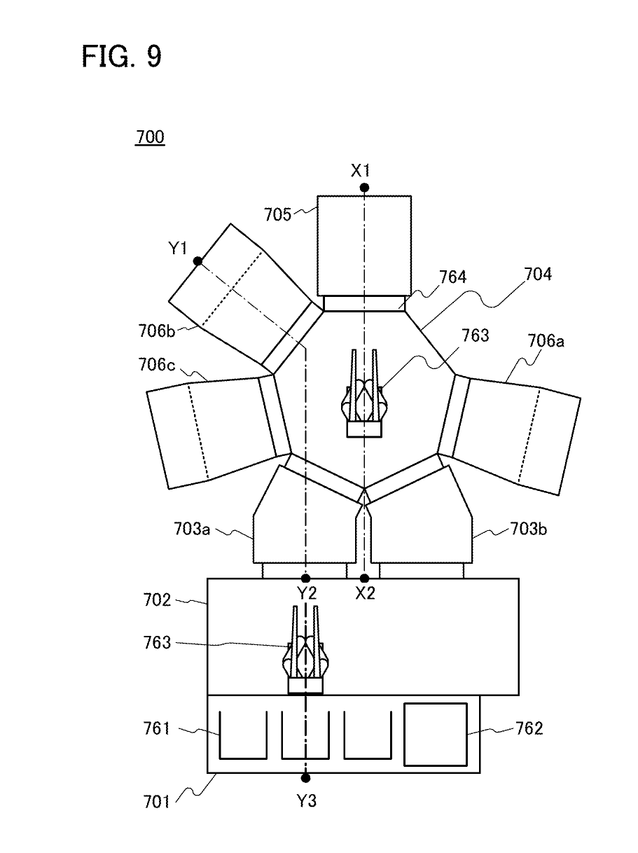

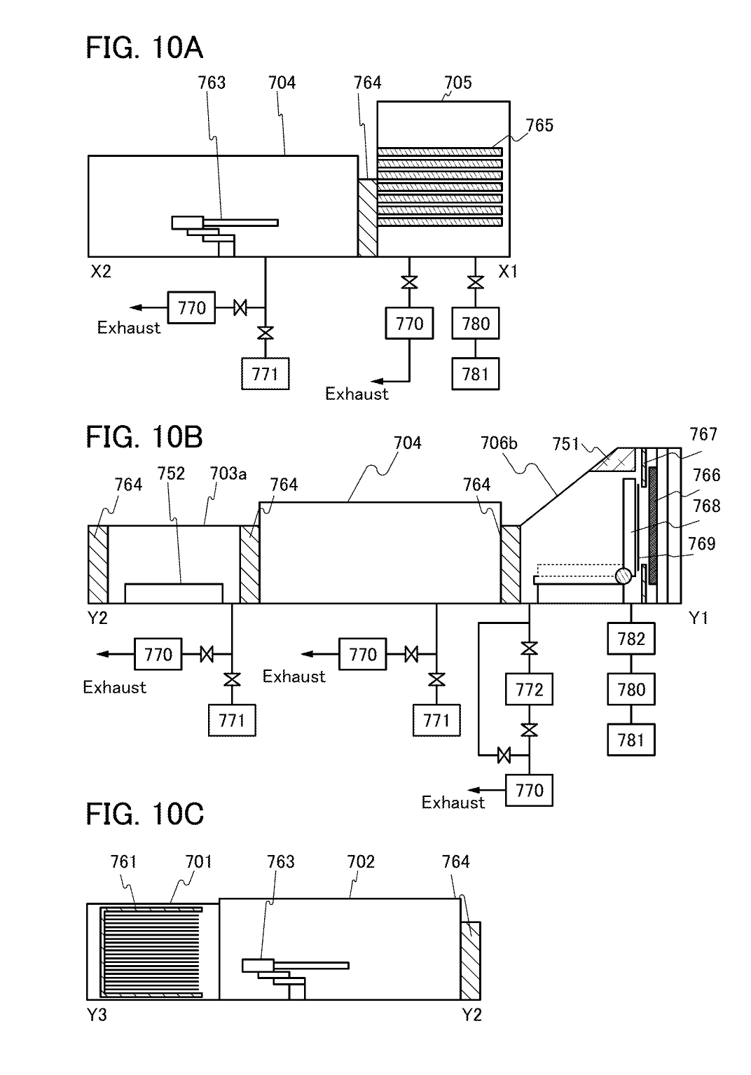

First, a structure of a deposition apparatus which allows the entry of few impurities into a film at the time of the deposition or the like is described with reference to FIG. 9 and FIGS. 10A to 10C.

FIG. 9 is a top view schematically illustrating a single wafer multi-chamber deposition apparatus 700. The deposition apparatus 700 includes an atmosphere-side substrate supply chamber 701 including a cassette port 761 for holding a substrate and an alignment port 762 for performing alignment of a substrate, an atmosphere-side substrate transfer chamber 702 through which a substrate is transferred from the atmosphere-side substrate supply chamber 701, a load lock chamber 703a where a substrate is carried and the pressure inside the chamber is switched from atmospheric pressure to reduced pressure or from reduced pressure to atmospheric pressure, an unload lock chamber 703b where a substrate is carried out and the pressure inside the chamber is switched from reduced pressure to atmospheric pressure or from atmospheric pressure to reduced pressure, a transfer chamber 704 through which a substrate is transferred in a vacuum, a substrate heating chamber 705 where a substrate is heated, and deposition chambers 706a, 706b, and 706c in each of which a target is placed for deposition. Note that for the deposition chambers 706a, 706b, and 706c, the structure of the deposition chamber 101 illustrated in FIG. 1A or FIG. 2A can be referred to, for example.

The atmosphere-side substrate transfer chamber 702 is connected to the load lock chamber 703a and the unload lock chamber 703b, the load lock chamber 703a and the unload lock chamber 703b are connected to the transfer chamber 704, and the transfer chamber 704 is connected to the substrate heating chamber 705 and the deposition chambers 706a, 706b, and 706c.

Gate valves 764 are provided for connecting portions between chambers so that each chamber except the atmosphere-side substrate supply chamber 701 and the atmosphere-side substrate transfer chamber 702 can be independently kept under vacuum. Moreover, the atmosphere-side substrate transfer chamber 702 and the transfer chamber 704 each include a transfer robot 763, with which a substrate can be transferred.

Furthermore, it is preferable that the substrate heating chamber 705 also serve as a plasma treatment chamber. In the deposition apparatus 700, it is possible to transfer a substrate without exposure to the air between treatment and treatment; therefore, adsorption of impurities on a substrate can be suppressed. In addition, the order of deposition, heat treatment, or the like can be freely determined. Note that the number of the transfer chambers, the number of the deposition chambers, the number of the load lock chambers, the number of the unload lock chambers, and the number of the substrate heating chambers are not limited to the above, and the numbers thereof can be set as appropriate depending on the space for placement or the process conditions.

Next, FIG. 10A, FIG. 10B, and FIG. 10C are a cross-sectional view taken along dashed-dotted line X1-X2, a cross-sectional view taken along dashed-dotted line Y1-Y2, and a cross-sectional view taken along dashed-dotted line Y2-Y3, respectively, in the deposition apparatus 700 illustrated in FIG. 9.

FIG. 10A is a cross section of the substrate heating chamber 705 and the transfer chamber 704, and the substrate heating chamber 705 includes a plurality of heating stages 765 which can hold a substrate. Furthermore, the substrate heating chamber 705 is connected to a vacuum pump 770 through a valve. As the vacuum pump 770, a dry pump and a mechanical booster pump can be used, for example.

As heating mechanism which can be used for the substrate heating chamber 705, a resistance heater may be used for heating, for example. Alternatively, heat conduction or heat radiation from a medium such as a heated gas may be used as the heating mechanism. For example, rapid thermal annealing (RTA) such as gas rapid thermal annealing (GRTA) or lamp rapid thermal annealing (LRTA) can be used. The LRTA is a method for heating an object by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. In the GRTA, heat treatment is performed using a high-temperature gas. An inert gas is used as the gas.

Moreover, the substrate heating chamber 705 is connected to a refiner 781 through a mass flow controller 780. Note that although the mass flow controller 780 and the refiner 781 can be provided for each of a plurality of kinds of gases, only one mass flow controller 780 and one refiner 781 are provided for easy understanding. As the gas introduced to the substrate heating chamber 705, a gas whose dew point is −80° C. or lower, preferably −100° C. or lower can be used; for example, an oxygen gas, a nitrogen gas, and a rare gas (e.g., an argon gas) are used.

The transfer chamber 704 includes the transfer robot 763. The transfer robot 763 can transfer a substrate to each chamber. Furthermore, the transfer chamber 704 is connected to the vacuum pump 770 and a cryopump 771 through valves. With such a structure, exhaust can be performed using the vacuum pump 770 when the pressure inside the transfer chamber 704 is in the range of atmospheric pressure to low or medium vacuum (about 0.1 Pa to several hundred pascals) and then, by switching the valves, exhaust can be performed using the cryopump 771 when the pressure inside the transfer chamber 704 is in the range of middle vacuum to high or ultra-high vacuum (0.1 Pa to 1×10⁻⁷ Pa).

Alternatively, two or more cryopumps 771 may be connected in parallel to the transfer chamber 704. With such a structure, even when one of the cryopumps is in regeneration, exhaust can be performed using any of the other cryopumps. Note that the above regeneration refers to treatment for discharging molecules (or atoms) entrapped in the cryopump. When molecules (or atoms) are entrapped too much in a cryopump, the exhaust capability of the cryopump is lowered; therefore, regeneration is performed regularly.

FIG. 10B is a cross section of the deposition chamber 706b, the transfer chamber 704, and the load lock chamber 703a.

Here, the details of the deposition chamber (sputtering chamber) are described with reference to FIG. 10B. The deposition chamber 706b illustrated in FIG. 10B includes a target 766, an attachment protection plate 767, and a substrate stage 768. Note that here, a substrate 769 is provided on the substrate stage 768. Although not illustrated, the substrate stage 768 may include a substrate holding mechanism which holds the substrate 769, a rear heater which heats the substrate 769 from the back surface, or the like. A magnet unit may be provided behind the target.

Note that the substrate stage 768 is held substantially vertically to a floor during deposition and is held substantially parallel to the floor when the substrate is delivered. In FIG. 10B, the position where the substrate stage 768 is held when the substrate is delivered is denoted by a dashed line. With such a structure, the probability that dust or a particle which might be mixed into a film during the deposition is attached to the substrate 769 can be suppressed as compared with the case where the substrate stage 768 is held parallel to the floor. However, there is a possibility that the substrate 769 falls when the substrate stage 768 is held vertically (90°) to the floor; therefore, the angle of the substrate stage 768 to the floor is preferably wider than or equal to 80° and narrower than 90°.

The attachment protection plate 767 can suppress deposition of a particle which is sputtered from the target 766 on a region where deposition is not needed. Moreover, the attachment protection plate 767 is preferably processed to prevent accumulated sputtered particles from being separated. For example, blasting treatment which increases surface roughness may be performed, or roughness may be formed on the surface of the attachment protection plate 767.

The deposition chamber 706b is connected to the mass flow controller 780 through a gas heating system 782, and the gas heating system 782 is connected to the refiner 781 through the mass flow controller 780. With the gas heating system 782, a gas which is introduced to the deposition chamber 706b can be heated to a temperature higher than or equal to 40° C. and lower than or equal to 400° C., preferably higher than or equal to 50° C. and lower than or equal to 200° C. Note that although the gas heating system 782, the mass flow controller 780, and the refiner 781 can be provided for each of a plurality of kinds of gases, only one gas heating system 782, one mass flow controller 780, and one refiner 781 are provided for easy understanding. As the gas introduced to the deposition chamber 706b, a gas whose dew point is −80° C. or lower, preferably −100° C. or lower can be used; for example, an oxygen gas, a nitrogen gas, and a rare gas (e.g., an argon gas) are used.

A facing-target-type sputtering apparatus may be provided in the deposition chamber 706b. In a facing-target-type sputtering apparatus, plasma is confined between targets; therefore, plasma damage to a substrate can be reduced. Furthermore, step coverage can be improved because an incident angle of a sputtered particle to the substrate can be made smaller depending on the inclination of the target.

Note that a parallel-plate-type sputtering apparatus or an ion beam sputtering apparatus may be provided in the deposition chamber 706b.

In the case where the refiner is provided near a gas inlet, the length of a pipe between the refiner and the deposition chamber 706b is less than or equal to 10 m, preferably less than or equal to 5 m, more preferably less than or equal to 1 m. When the length of the pipe is less than or equal to 10 m, less than or equal to 5 m, or less than or equal to 1 m, the effect of the release of gas from the pipe can be reduced accordingly. As the pipe for the gas, a metal pipe the inside of which is covered with iron fluoride, aluminum oxide, chromium oxide, or the like can be used. With the above pipe, the amount of released gas containing impurities is made small and the entry of impurities into the gas can be reduced as compared with a SUS316L-EP pipe, for example. Furthermore, a high-performance ultra-compact metal gasket joint (UPG joint) may be used as a joint of the pipe. A structure where all the materials of the pipe are metals is preferable because the effect of the generated released gas or the external leakage can be reduced as compared with a structure where a resin or the like is used.

The deposition chamber 706b is connected to a turbo molecular pump 772 and the vacuum pump 770 through valves.

In addition, the deposition chamber 706b is provided with a cryotrap 751.

The cryotrap 751 is a mechanism which can adsorb a molecule (or an atom) having a relatively high melting point, such as water. The turbo molecular pump 772 is capable of stably removing a large-sized molecule (or atom), needs low frequency of maintenance, and thus enables high productivity, whereas it has a low capability in removing hydrogen and water. Hence, the cryotrap 751 is connected to the deposition chamber 706b so as to have a high capability in removing water or the like. The temperature of a refrigerator of the cryotrap 751 is set to be lower than or equal to 100 K, preferably lower than or equal to 80 K. In the case where the cryotrap 751 includes a plurality of refrigerators, it is preferable to set the temperatures of the refrigerators at different temperatures because efficient exhaust is possible. For example, the temperature of a first-stage refrigerator may be set to be lower than or equal to 100 K and the temperature of a second-stage refrigerator may be set to be lower than or equal to 20 K. Note that when a titanium sublimation pump is used instead of the cryotrap, a higher vacuum can be achieved in some cases. Using an ion pump instead of a cryopump or a turbo molecular pump can also achieve higher vacuum in some cases.

Note that the exhaust method of the deposition chamber 706b is not limited to the above, and a structure similar to that in the exhaust method described above for the transfer chamber 704 (the exhaust method using the cryopump and the vacuum pump) may be employed. Needless to say, the exhaust method of the transfer chamber 704 may have a structure similar to that of the deposition chamber 706b (the exhaust method using the turbo molecular pump and the vacuum pump).

Note that in each of the transfer chamber 704, the substrate heating chamber 705, and the deposition chamber 706b which are described above, the back pressure (total pressure) and the partial pressure of each gas molecule (atom) are preferably set as follows. In particular, the back pressure and the partial pressure of each gas molecule (atom) in the deposition chamber 706b need to be noted because impurities might enter a film to be formed.

In each of the above chambers, the back pressure (total pressure) is less than or equal to 1×10⁻⁴ Pa, preferably less than or equal to 3×10⁻⁵ Pa, more preferably less than or equal to 1×10⁻⁵ Pa. In each of the above chambers, the partial pressure of a gas molecule (atom) having a mass-to-charge ratio (m/z) of 18 is less than or equal to 3×10⁻⁵ Pa, preferably less than or equal to 1×10⁻⁵ Pa, more preferably less than or equal to 3×10⁻⁶ Pa. Moreover, in each of the above chambers, the partial pressure of a gas molecule (atom) having a mass-to-charge ratio (m/z) of 28 is less than or equal to 3×10⁻⁵ Pa, preferably less than or equal to 1×10⁻⁵ Pa, more preferably less than or equal to 3×10⁻⁶ Pa. Furthermore, in each of the above chambers, the partial pressure of a gas molecule (atom) having a mass-to-charge ratio (m/z) of 44 is less than or equal to 3×10⁻⁵ Pa, preferably less than or equal to 1×10⁻⁵ Pa, more preferably less than or equal to 3×10⁻⁶ Pa.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc. may be used.

Moreover, the transfer chamber 704, the substrate heating chamber 705, and the deposition chamber 706b which are described above preferably have a small amount of external leakage or internal leakage.

For example, in each of the transfer chamber 704, the substrate heating chamber 705, and the deposition chamber 706b which are described above, the leakage rate is less than or equal to 3×10′ Pa·m³/s, preferably less than or equal to 1×10⁻⁶ Pa·m³/s. The leakage rate of a gas molecule (atom) having a mass-to-charge ratio (m/z) of 18 is less than or equal to 1×10⁻⁷ Pa·m³/s, preferably less than or equal to 3×10⁻⁸ Pa·m³/s. The leakage rate of a gas molecule (atom) having a mass-to-charge ratio (m/z) of 28 is less than or equal to 1×10⁻⁵ Pa·m³/s, preferably less than or equal to 1×10⁻⁶ Pa·m³/s. The leakage rate of a gas molecule (atom) having a mass-to-charge ratio (m/z) of 44 is less than or equal to 3×10⁻⁶ Pa·m³/s, preferably less than or equal to 1×10⁻⁶ Pa·m³/s.

Note that a leakage rate can be derived from the total pressure and partial pressure measured using the mass analyzer.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or due to released gas from an internal member. Measures need to be taken from both aspects of external leakage and internal leakage in order that the leakage rate can be set to be less than or equal to the above value.

For example, an open/close portion of the deposition chamber 706b can be sealed with a metal gasket. For the metal gasket, metal covered with iron fluoride, aluminum oxide, or chromium oxide is preferably used. The metal gasket realizes higher adhesion than an O-ring, and can reduce the external leakage. Furthermore, with the use of the metal covered with iron fluoride, aluminum oxide, chromium oxide, or the like, which is in the passive state, the release of gas containing impurities released from the metal gasket is suppressed, so that the internal leakage can be reduced.

For a member of the deposition apparatus 700, aluminum, chromium, titanium, zirconium, nickel, or vanadium, which releases a smaller amount of gas containing impurities, is used. Alternatively, for the above member, an alloy containing iron, chromium, nickel, and the like covered with the above material may be used. The alloy containing iron, chromium, nickel, and the like is rigid, resistant to heat, and suitable for processing. Here, when surface unevenness of the member is decreased by polishing or the like to reduce the surface area, the release of gas can be reduced.

Alternatively, the above member of the deposition apparatus 700 may be covered with iron fluoride, aluminum oxide, chromium oxide, or the like.

The member of the deposition apparatus 700 is preferably formed using only metal when possible. For example, in the case where a viewing window formed with quartz or the like is provided, it is preferable that the surface of the viewing window be thinly covered with iron fluoride, aluminum oxide, chromium oxide, or the like so as to suppress release of gas.

When an adsorbed substance is present in the deposition chamber, the adsorbed substance does not affect the pressure in the deposition chamber because it is adsorbed onto an inner wall or the like; however, the adsorbed substance causes gas to be released when the inside of the deposition chamber is evacuated. Therefore, although there is no correlation between the leakage rate and the exhaust rate, it is important that the adsorbed substance present in the deposition chamber be desorbed as much as possible and exhaust be performed in advance with the use of a pump with high exhaust capability. Note that the deposition chamber may be subjected to baking to promote desorption of the adsorbed substance. By the baking, the desorption rate of the adsorbed substance can be increased about tenfold. The baking can be performed at a temperature in the range of 100° C. to 450° C. At this time, when the adsorbed substance is removed while an inert gas is introduced to the deposition chamber, the desorption rate of water or the like, which is difficult to be desorbed simply by exhaust, can be further increased. Note that when the inert gas which is introduced is heated to substantially the same temperature as the baking temperature, the desorption rate of the adsorbed substance can be further increased. Here, a rare gas is preferably used as an inert gas. Depending on the kind of a film to be deposited, oxygen or the like may be used instead of an inert gas. For example, in deposition of an oxide, the use of oxygen which is the main component of the oxide is preferable in some cases. The baking is preferably performed using a lamp.

Alternatively, treatment for evacuating the inside of the deposition chamber is preferably performed a certain period of time after heated oxygen, a heated inert gas such as a heated rare gas, or the like is introduced to increase a pressure in the deposition chamber. The introduction of the heated gas can desorb the adsorbed substance in the deposition chamber, and the impurities present in the deposition chamber can be reduced. Note that an advantageous effect can be achieved when this treatment is repeated more than or equal to 2 times and less than or equal to 30 times, preferably more than or equal to 5 times and less than or equal to 15 times. Specifically, an inert gas, oxygen, or the like with a temperature higher than or equal to 40° C. and lower than or equal to 400° C., preferably higher than or equal to 50° C. and lower than or equal to 200° C. is introduced to the deposition chamber, so that the pressure therein can be kept to be greater than or equal to 0.1 Pa and less than or equal to 10 kPa, preferably greater than or equal to 1 Pa and less than or equal to 1 kPa, more preferably greater than or equal to 5 Pa and less than or equal to 100 Pa in the time range of 1 minute to 300 minutes, preferably 5 minutes to 120 minutes. After that, the inside of the deposition chamber is evacuated in the time range of 5 minutes to 300 minutes, preferably 10 minutes to 120 minutes.

The desorption rate of the adsorbed substance can be further increased also by dummy deposition. Here, the dummy deposition refers to deposition on a dummy substrate by a sputtering method or the like, in which a film is deposited on the dummy substrate and the inner wall of the deposition chamber so that impurities in the deposition chamber and an adsorbed substance on the inner wall of the deposition chamber are confined in the film. For a dummy substrate, a substrate which releases a smaller amount of gas is preferably used. By performing dummy deposition, the concentration of impurities in a film to be formed later can be reduced. Note that the dummy deposition may be performed at the same time as the baking of the deposition chamber.

Next, the details of the transfer chamber 704 and the load lock chamber 703a illustrated in FIG. 10B and the atmosphere-side substrate transfer chamber 702 and the atmosphere-side substrate supply chamber 701 illustrated in FIG. 10C are described. Note that FIG. 10C is a cross section of the atmosphere-side substrate transfer chamber 702 and the atmosphere-side substrate supply chamber 701.

For the transfer chamber 704 illustrated in FIG. 10B, the description of the transfer chamber 704 illustrated in FIG. 10A can be referred to.

The load lock chamber 703a includes a substrate delivery stage 752. When a pressure in the load lock chamber 703a becomes atmospheric pressure by being increased from reduced pressure, the substrate delivery stage 752 receives a substrate from the transfer robot 763 provided in the atmosphere-side substrate transfer chamber 702. After that, the load lock chamber 703a is evacuated into vacuum so that the pressure therein becomes reduced pressure and then the transfer robot 763 provided in the transfer chamber 704 receives the substrate from the substrate delivery stage 752.

Furthermore, the load lock chamber 703a is connected to the vacuum pump 770 and the cryopump 771 through valves. For a method for connecting exhaust systems such as the vacuum pump 770 and the cryopump 771, the description of the method for connecting the transfer chamber 704 can be referred to, and the description thereof is omitted here. Note that the unload lock chamber 703b illustrated in FIG. 9 can have a structure similar to that in the load lock chamber 703a.

The atmosphere-side substrate transfer chamber 702 includes the transfer robot 763. The transfer robot 763 can deliver a substrate from the cassette port 761 to the load lock chamber 703a or deliver a substrate from the load lock chamber 703a to the cassette port 761. Furthermore, a mechanism for suppressing entry of dust or a particle, such as high efficiency particulate air (HEPA) filter, may be provided above the atmosphere-side substrate transfer chamber 702 and the atmosphere-side substrate supply chamber 701.

The atmosphere-side substrate supply chamber 701 includes a plurality of cassette ports 761. The cassette port 761 can hold a plurality of substrates.

The surface temperature of the target is set to be lower than or equal to 100° C., preferably lower than or equal to 50° C., more preferably about room temperature (typically, 25° C.). In a sputtering apparatus for a large substrate, a large target is often used. However, it is difficult to form a target for a large substrate without a juncture. In fact, a plurality of targets are arranged so that there is as little space as possible therebetween to obtain a large shape; however, a slight space is inevitably generated. When the surface temperature of the target increases, in some cases, zinc or the like is volatilized from such a slight space and the space might be expanded gradually. When the space expands, a metal of a backing plate or a metal used for adhesion might be sputtered and might cause an increase in impurity concentration. Thus, it is preferable that the target be cooled sufficiently.

Specifically, for the backing plate, a metal having high conductivity and a high heat dissipation property (specifically copper) is used. The target can be cooled efficiently by making a sufficient amount of cooling water flow through a water channel which is formed in the backing plate.

Note that in the case where the target includes zinc, plasma damage is alleviated by the deposition in an oxygen gas atmosphere; thus, an oxide in which zinc is unlikely to be volatilized can be obtained.

When the above-described deposition apparatus is used, the concentration of hydrogen in the CAAC-OS, which is measured by SIMS, can be set to be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

The concentration of nitrogen in the CAAC-OS, which is measured by SIMS, can be set to be lower than 5×10¹⁹ atoms/cm³, preferably lower than or equal to 1×10¹⁹ atoms/cm³, more preferably lower than or equal to 5×10¹⁸ atoms/cm³, still more preferably lower than or equal to 1×10¹⁸ atoms/cm³.

The concentration of carbon in the CAAC-OS, which is measured by SIMS, can be set to be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The amount of each of the following gas molecules (atoms) released from the CAAC-OS can be less than or equal to 1×10¹⁹/cm³, preferably less than or equal to 1×10¹⁸/cm³, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

With the above deposition apparatus, entry of impurities into the CAAC-OS can be suppressed. Furthermore, when a film in contact with the CAAC-OS is formed with the use of the above deposition apparatus, the entry of impurities into the CAAC-OS from the film in contact therewith can be suppressed.

### <Transistor>

A transistor of one embodiment of the present invention is described below.

Note that a transistor of one embodiment of the present invention preferably includes the above-described CAAC-OS.

### <Transistor Structure 1>

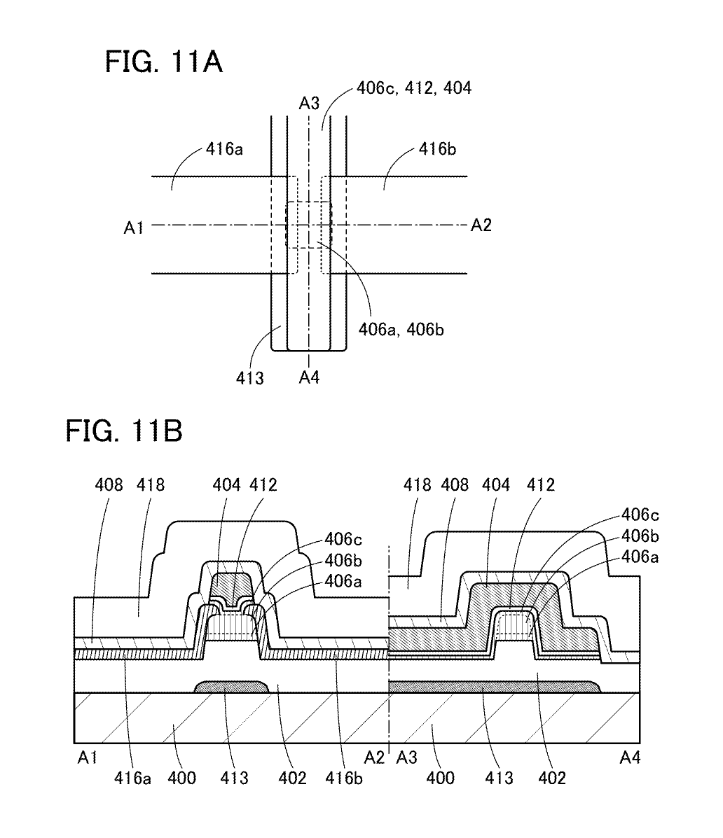

FIGS. 11A and 11B are a top view and a cross-sectional view of a transistor of one embodiment of the present invention. FIG. 11A is a top view and FIG. 11B is a cross-sectional view taken along dashed-dotted line A1-A2 and dashed-dotted line A3-A4 in FIG. 11A. Note that for simplification of the drawing, some components are not illustrated in the top view in FIG. 11A.

The transistor in FIGS. 11A and 11B includes a conductor 413 over a substrate 400, an insulator 402 having a projection over the substrate 400 and the conductor 413, a semiconductor 406a over the projection of the insulator 402, a semiconductor 406b over the semiconductor 406a, a conductor 416a and a conductor 416b which are in contact with a top surface and a side surface of the semiconductor 406b and which are arranged to be apart from each other, a semiconductor 406c over the semiconductor 406b, the conductor 416a, and the conductor 416b, an insulator 412 over the semiconductor 406c, a conductor 404 over the insulator 412, an insulator 408 over the conductor 416a, the conductor 416b, and the conductor 404, and an insulator 418 over the insulator 408. Here, the conductor 413 is part of the transistor, but is not limited to this. For example, the conductor 413 may be a component independent of the transistor.

Note that the semiconductor 406c is in contact with at least a top surface and a side surface of the semiconductor 406b in the cross section taken along line A3-A4. Furthermore, the conductor 404 faces the top surface and the side surface of the semiconductor 406b through the semiconductor 406c and the insulator 412 in the cross section taken along line A3-A4. The conductor 413 faces a bottom surface of the semiconductor 406b with the insulator 402 provided therebetween. The insulator 402 does not necessarily include a projection. The semiconductor 406c, the insulator 408, and/or the insulator 418 are/is not necessarily provided.

The semiconductor 406b serves as a channel formation region of the transistor. The conductor 404 serves as a first gate electrode (also referred to as a front gate electrode) of the transistor. The conductor 413 serves as a second gate electrode (also referred to as a back gate electrode) of the transistor. The conductor 416a and the conductor 416b serve as a source electrode and a drain electrode of the transistor. The insulator 408 functions as a barrier layer. The insulator 408 has, for example, a function of blocking oxygen and/or hydrogen. Alternatively, the insulator 408 has, for example, a higher capability of blocking oxygen and/or hydrogen than the semiconductor 406a and/or the semiconductor 406c.

The insulator 402 is preferably an insulator containing excess oxygen.

The insulator containing excess oxygen means an insulator from which oxygen is released by heat treatment, for example. The silicon oxide layer containing excess oxygen means a silicon oxide layer which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406a.

The insulator containing excess oxygen has a function of reducing oxygen vacancies in the semiconductor 406b in some cases. Such oxygen vacancies form DOS in the semiconductor 406b and serve as hole traps or the like. In addition, hydrogen comes into the site of such oxygen vacancies and forms electrons serving as carriers. Therefore, by reducing the oxygen vacancies in the semiconductor 406b, the transistor can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in TDS analysis in the range of a surface temperature of 100° C. to 700° C. or 100° C. to 500° C.

Here, the method for measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal.

N_{O2}=N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value α is a coefficient affecting the ion intensity in the TDS analysis. Refer to Japanese Published Patent Application No. H6-275697 for details of the above formula. The amount of released oxygen is measured with a thermal desorption spectroscopy apparatus produced by ESCO Ltd., EMD-WA1000S/W using a silicon substrate containing hydrogen atoms at 1×10¹⁶ atoms/cm², for example, as the reference sample.

Furthermore, in the TDS analysis, oxygen is partly detected as an oxygen atom. The ratio between oxygen molecules and oxygen atoms can be calculated from the ionization rate of the oxygen molecules. Note that since the above α includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in ESR.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

As illustrated in FIG. 11B, the side surfaces of the semiconductor 406b are in contact with the conductor 416a and the conductor 416b. The semiconductor 406b can be electrically surrounded by an electric field of the conductor 404 (a transistor structure in which a semiconductor is electrically surrounded by an electric field of a conductor is referred to as a surrounded channel (s-channel) structure). Therefore, a channel is formed in the entire semiconductor 406b (bulk) in some cases. In the s-channel structure, a large amount of current can flow between a source and a drain of a transistor, so that a high on-state current can be obtained.

The s-channel structure is suitable for a miniaturized transistor because a high on-state current can be obtained. A semiconductor device including the miniaturized transistor can have a high integration degree and high density. For example, the channel length of the transistor is preferably less than or equal to 40 nm, more preferably less than or equal to 30 nm, still more preferably less than or equal to 20 nm in a region and the channel width of the transistor is preferably less than or equal to 40 nm, more preferably less than or equal to 30 nm, still more preferably less than or equal to 20 nm in a region.

Furthermore, by applying a lower voltage or a higher voltage than a source electrode to the conductor 413, the threshold voltage of the transistor may be shifted in the positive direction or the negative direction. For example, when the threshold voltage of the transistor is shifted in the positive direction, a normally-off transistor which is in a non-conduction state (off state) when the gate voltage is 0 V can be obtained in some cases. The voltage applied to the conductor 413 may be a variable or a fixed voltage. When a variable voltage is applied to the conductor 413, a circuit for controlling the voltage may be electrically connected to the conductor 413.

An oxide semiconductor which can be used as the semiconductor 406a, the semiconductor 406b, the semiconductor 406c, or the like is described below.

The semiconductor 406b is an oxide semiconductor containing indium, for example. The oxide semiconductor 406b can have high carrier mobility (electron mobility) by containing indium, for example. The semiconductor 406b preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having high bonding energy with oxygen, for example. The element M is an element whose bonding energy with oxygen is higher than that of indium. The element M is an element that can increase the energy gap of the oxide semiconductor, for example. Furthermore, the semiconductor 406b preferably contains zinc. When the oxide semiconductor contains zinc, the oxide semiconductor is easily crystallized, for example.

Note that the semiconductor 406b is not limited to the oxide semiconductor containing indium. The semiconductor 406b may be, for example, an oxide semiconductor which does not contain indium and contains zinc, an oxide semiconductor which does not contain indium and contains gallium, or an oxide semiconductor which does not contain indium and contains tin, e.g., a zinc tin oxide or a gallium tin oxide.

For the semiconductor 406b, an oxide with a wide energy gap may be used. For example, the energy gap of the semiconductor 406b is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

For example, the semiconductor 406a and the semiconductor 406c are oxide semiconductors including one or more elements other than oxygen included in the semiconductor 406b. Since the semiconductor 406a and the semiconductor 406c each include one or more elements other than oxygen included in the semiconductor 406b, an interface state is less likely to be formed at the interface between the semiconductor 406a and the semiconductor 406b and the interface between the semiconductor 406b and the semiconductor 406c.

The semiconductor 406a, the semiconductor 406b, and the semiconductor 406c preferably include at least indium. In the case of using an In-M-Zn oxide as the semiconductor 406a, when a summation of In and M is assumed to be 100 atomic %, the proportions of In and M are preferably set to be less than 50 atomic % and greater than 50 atomic %, respectively, more preferably less than 25 atomic % and greater than 75 atomic %, respectively. In the case of using an In-M-Zn oxide as the semiconductor 406b, when a summation of In and M is assumed to be 100 atomic %, the proportions of In and M are preferably set to be greater than 25 atomic % and less than 75 atomic %, respectively, more preferably greater than 34 atomic % and less than 66 atomic %, respectively. In the case of using an In-M-Zn oxide as the semiconductor 406c, when a summation of In and M is assumed to be 100 atomic %, the proportions of In and M are preferably set to be less than 50 atomic % and greater than 50 atomic %, respectively, more preferably less than 25 atomic % and greater than 75 atomic %, respectively. Note that the semiconductor 406c may be an oxide that is a type the same as that of the semiconductor 406a. Note that the semiconductor 406a and/or the semiconductor 406c do/does not necessarily contain indium in some cases. For example, the semiconductor 406a and/or the semiconductor 406c may be gallium oxide.

As the semiconductor 406b, an oxide having an electron affinity higher than those of the semiconductors 406a and 406c is used. For example, as the semiconductor 406b, an oxide having an electron affinity higher than those of the semiconductors 406a and 406c by 0.07 eV or higher and 1.3 eV or lower, preferably 0.1 eV or higher and 0.7 eV or lower, more preferably 0.15 eV or higher and 0.4 eV or lower is used. Note that the electron affinity refers to an energy difference between the vacuum level and the bottom of the conduction band.

An indium gallium oxide has small electron affinity and a high oxygen-blocking property. Therefore, the semiconductor 406c preferably includes an indium gallium oxide. The gallium atomic ratio [Ga/(In+Ga)] is, for example, higher than or equal to 70%, preferably higher than or equal to 80%, more preferably higher than or equal to 90%.

Note that the composition of the semiconductor 406a is preferably in the neighborhood of the composition represented by the bold line in FIG. 8. The composition of the semiconductor 406b is preferably in the neighborhood of the composition represented by the bold line in FIG. 8. The composition of the semiconductor 406c is preferably in the neighborhood of the composition represented by the bold line in FIG. 8. When these compositions are employed, the channel formation region of the transistor can have a single crystal structure. Alternatively, the channel formation region, the source region, and the drain region of the transistor can have a single crystal structure in some cases. When the channel formation region of the transistor has a single crystal structure, the transistor can have high frequency characteristics in some cases.

At this time, when a gate voltage is applied, a channel is formed in the semiconductor 406b having the highest electron affinity in the semiconductor 406a, the semiconductor 406b, and the semiconductor 406c.

Here, in some cases, there is a mixed region of the semiconductor 406a and the semiconductor 406b between the semiconductor 406a and the semiconductor 406b. Furthermore, in some cases, there is a mixed region of the semiconductor 406b and the semiconductor 406c between the semiconductor 406b and the semiconductor 406c. The mixed region has a low interface state density. For that reason, the stack including the semiconductor 406a, the semiconductor 406b, and the semiconductor 406c has a band structure where energy at each interface and in the vicinity of the interface is changed continuously (continuous junction).

At this time, electrons move mainly in the semiconductor 406b, not in the semiconductor 406a and the semiconductor 406c. As described above, when the interface state density at the interface between the semiconductor 406a and the semiconductor 406b and the interface state density at the interface between the semiconductor 406b and the semiconductor 406c are decreased, electron movement in the semiconductor 406b is less likely to be inhibited and the on-sate current of the transistor can be increased.

As factors of inhibiting electron movement are decreased, the on-state current of the transistor can be increased. For example, in the case where there is no factor of inhibiting electron movement, electrons are assumed to be efficiently moved. Electron movement is inhibited, for example, in the case where physical unevenness in the channel formation region is large.

To increase the on-state current of the transistor, for example, root mean square (RMS) roughness with a measurement area of 1 μm×1 μm of a top surface or a bottom surface of the semiconductor 406b (a formation surface; here, the semiconductor 406a) is less than 1 nm, preferably less than 0.6 nm, more preferably less than 0.5 nm, still more preferably less than 0.4 nm. The average surface roughness (also referred to as Ra) with the measurement area of 1 μm×1 μm is less than 1 nm, preferably less than 0.6 nm, more preferably less than 0.5 nm, still more preferably less than 0.4 nm. The maximum difference (P−V) with the measurement area of 1 μm×1 μm is less than 10 nm, preferably less than 9 nm, more preferably less than 8 nm, still more preferably less than 7 nm. RMS roughness, Ra, and P−V can be measured using a scanning probe microscope SPA-500 manufactured by SII Nano Technology Inc.

The electron movement is also inhibited, for example, in the case where the density of defect states is high in a region where a channel is formed.

For example, in the case where the semiconductor 406b contains oxygen vacancies (also denoted by V_{O}), donor levels are formed by entry of hydrogen into sites of oxygen vacancies in some cases. A state in which hydrogen enters sites of oxygen vacancies are denoted by V_{O}H in the following description in some cases. V_{O}H is a factor of decreasing the on-state current of the transistor because V_{O}H scatters electrons. Note that sites of oxygen vacancies become more stable by entry of oxygen than by entry of hydrogen. Thus, by decreasing oxygen vacancies in the semiconductor 406b, the on-state current of the transistor can be increased in some cases.

To decrease oxygen vacancies in the semiconductor 406b, for example, there is a method in which excess oxygen in the insulator 402 is moved to the semiconductor 406b through the semiconductor 406a. In this case, the semiconductor 406a is preferably a layer having an oxygen-transmitting property (a layer through which oxygen passes or is transmitted).

In the case where the transistor has an s-channel structure, a channel is formed in the whole of the semiconductor 406b. Therefore, as the semiconductor 406b has a larger thickness, a channel region becomes larger. In other words, the thicker the semiconductor 406b is, the larger the on-state current of the transistor is. For example, the semiconductor 406b has a region with a thickness of greater than or equal to 20 nm, preferably greater than or equal to 40 nm, more preferably greater than or equal to 60 nm, still more preferably greater than or equal to 100 nm. Note that the semiconductor 406b has a region with a thickness of, for example, less than or equal to 300 nm, preferably less than or equal to 200 nm, more preferably less than or equal to 150 nm because the productivity of the semiconductor device might be decreased.

Moreover, the thickness of the semiconductor 406c is preferably as small as possible to increase the on-state current of the transistor. The thickness of the semiconductor 406c is less than 10 nm, preferably less than or equal to 5 nm, more preferably less than or equal to 3 nm, for example. Meanwhile, the semiconductor 406c has a function of blocking entry of elements other than oxygen (such as hydrogen and silicon) included in the adjacent insulator into the semiconductor 406b where a channel is formed. For this reason, it is preferable that the semiconductor 406c have a certain thickness. The thickness of the semiconductor 406c is greater than or equal to 0.3 nm, preferably greater than or equal to 1 nm, more preferably greater than or equal to 2 nm, for example. The semiconductor 406c preferably has an oxygen blocking property to suppress outward diffusion of oxygen released from the insulator 402 and the like.

To improve reliability, preferably, the thickness of the semiconductor 406a is large and the thickness of the semiconductor 406c is small. For example, the semiconductor 406a has a region with a thickness of, for example, greater than or equal to 10 nm, preferably greater than or equal to 20 nm, more preferably greater than or equal to 40 nm, still more preferably greater than or equal to 60 nm. When the thickness of the semiconductor 406a is made large, a distance from an interface between the adjacent insulator and the semiconductor 406a to the semiconductor 406b in which a channel is formed can be large. Since the productivity of the semiconductor device might be decreased, the semiconductor 406a has a region with a thickness of, for example, less than or equal to 200 nm, preferably less than or equal to 120 nm, more preferably less than or equal to 80 nm.

For example, a region with a silicon concentration of lower than 1×10¹⁹ atoms/cm³, preferably lower than 5×10¹⁸ atoms/cm³, more preferably lower than 2×10¹⁸ atoms/cm³ which is measured by secondary ion mass spectrometry (SIMS) is provided between the semiconductor 406b and the semiconductor 406a. A region with a silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the semiconductor 406b and the semiconductor 406c.

It is preferable to reduce the concentration of hydrogen in the semiconductor 406a and the semiconductor 406c in order to reduce the concentration of hydrogen in the semiconductor 406b. The semiconductor 406a and the semiconductor 406c each have a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. It is preferable to reduce the concentration of nitrogen in the semiconductor 406a and the semiconductor 406c in order to reduce the concentration of nitrogen in the semiconductor 406b. The semiconductor 406a and the semiconductor 406c each have a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The above three-layer structure is an example. For example, a two-layer structure without the semiconductor 406a or the semiconductor 406c may be employed. A four-layer structure in which any one of the semiconductors described as examples of the semiconductor 406a, the semiconductor 406b, and the semiconductor 406c is provided under or over the semiconductor 406a or under or over the semiconductor 406c may be employed. An n-layer structure (n is an integer of 5 or more) in which any one of the semiconductors described as examples of the semiconductor 406a, the semiconductor 406b, and the semiconductor 406c is provided at two or more of the following positions: over the semiconductor 406a, under the semiconductor 406a, over the semiconductor 406c, and under the semiconductor 406c.

As the substrate 400, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The thickness of the substrate 400 is, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 400 has a small thickness, the weight of the semiconductor device can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, metal, an alloy, resin, glass, or fiber thereof can be used, for example. The flexible substrate 400 preferably has a lower coefficient of linear expansion because deformation due to an environment is suppressed. The flexible substrate 400 is formed using, for example, a material whose coefficient of linear expansion is lower than or equal to 1×10⁻³/K, lower than or equal to 5×10⁻⁵/K, or lower than or equal to 1×10⁻³/K. Examples of the resin include polyester, polyolefin, polyamide (e.g., nylon or aramid), polyimide, polycarbonate, and acrylic. In particular, aramid is preferably used for the flexible substrate 400 because of its low coefficient of linear expansion.

The conductor 413 may be formed to have a single-layer structure or a stacked-layer structure using a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten, for example. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 402 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 402 may have a function of preventing diffusion of impurities from the substrate 400. In the case where the semiconductor 406b is an oxide semiconductor, the insulator 402 can have a function of supplying oxygen to the semiconductor 406b.

Each of the conductor 416a and the conductor 416b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 412 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 412 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The conductor 404 may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

The insulator 408 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 408 may be preferably formed to have, for example, a single-layer structure or a stacked-layer structure including an insulator containing aluminum oxide, silicon nitride oxide, silicon nitride, gallium oxide, yttrium oxide, zirconium oxide, lanthanum oxide, neodymium oxide, hafnium oxide, or tantalum oxide.

The insulator 418 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 418 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

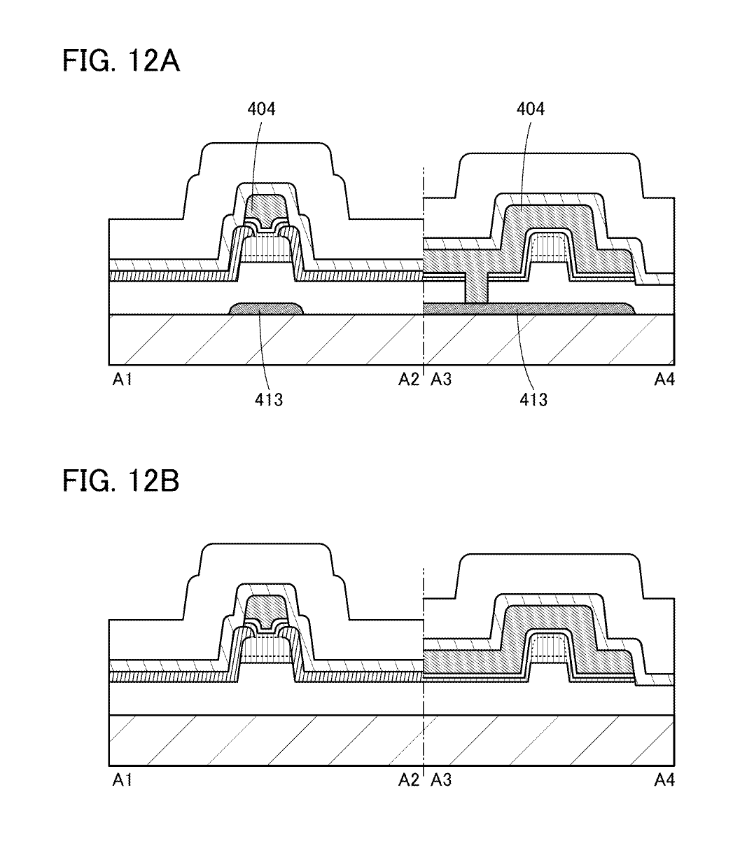

Although FIGS. 11A and 11B show an example where the conductor 404 which is a first gate electrode of a transistor is not electrically connected to the conductor 413 which is a second gate electrode, a transistor structure of one embodiment of the present invention is not limited thereto. For example, as illustrated in FIG. 12A, the conductor 404 may be electrically connected to the conductor 413. With such a structure, the conductor 404 and the conductor 413 are supplied with the same potential; thus, switching characteristics of the transistor can be improved. Alternatively, as illustrated in FIG. 12B, the conductor 413 is not necessarily provided.

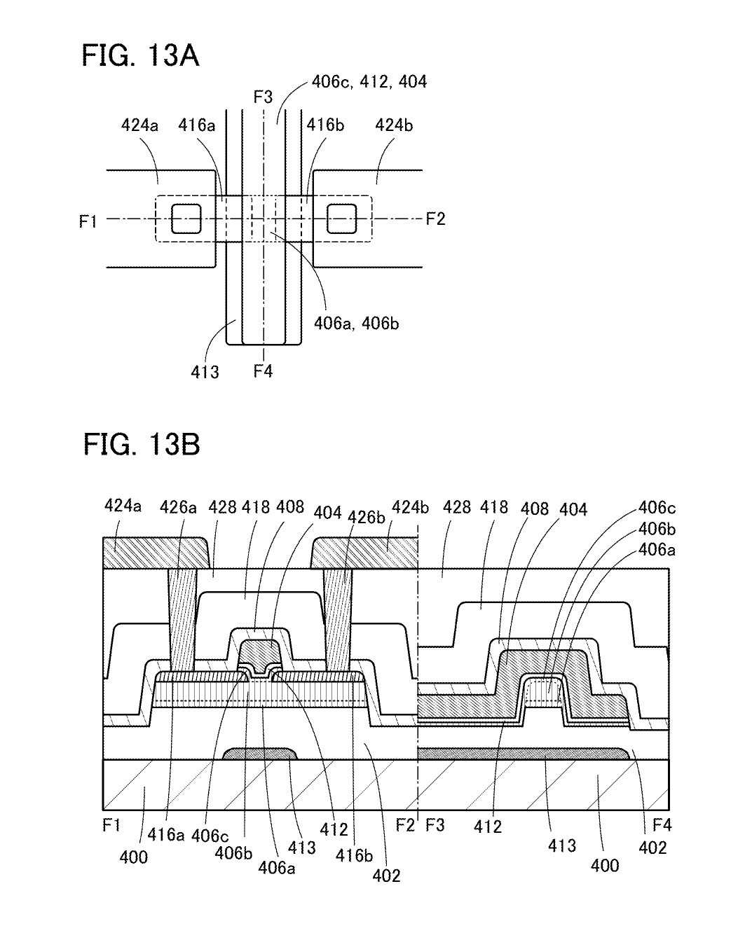

FIG. 13A is an example of a top view of a transistor. FIG. 13B is an example of a cross-sectional view taken along dashed-dotted line F1-F2 and dashed-dotted line F3-F4 in FIG. 13A. Note that some components such as an insulator are omitted in FIG. 13A for easy understanding.

Although FIGS. 11A and 11B and the like show an example where the conductor 416a and the conductor 416b which function as a source electrode and a drain electrode are in contact with a top surface and a side surface of the semiconductor 406b, a top surface of the insulator 402, and the like, a transistor structure of one embodiment of the present invention is not limited thereto. For example, as illustrated in FIGS. 13A and 13B, the conductor 416a and the conductor 416b may be in contact with only the top surface of the semiconductor 406b.

As illustrated in FIG. 13B, an insulator 428 may be provided over the insulator 418. The insulator 428 preferably has a flat top surface. The insulator 428 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 428 may be formed using aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide. To planarize the top surface of the insulator 428, planarization treatment may be performed by a chemical mechanical polishing (CMP) method or the like.

A resin may be used as the insulator 428. For example, a resin containing polyimide, polyamide, acrylic, silicone, or the like may be used. The use of a resin does not need planarization treatment performed on the top surface of the insulator 428 in some cases. By using a resin, a thick film can be formed in a short time; thus, the productivity can be increased.

As illustrated in FIGS. 13A and 13B, a conductor 424a and a conductor 424b may be provided over the insulator 428. The conductor 424a and the conductor 424b may function as wirings, for example. The insulator 428 may include an opening and the conductor 416a and the conductor 424a may be electrically connected to each other through the opening. The insulator 428 may have another opening and the conductor 416b and the conductor 424b may be electrically connected to each other through the opening. In this case, the conductor 426a and the conductor 426b may be provided in the respective openings.

Each of the conductor 424a and the conductor 424b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

In the transistor illustrated in FIGS. 13A and 13B, the conductor 416a and the conductor 416b are not in contact with side surfaces of the semiconductor 406b. Thus, an electric field applied from the conductor 404 functioning as a first gate electrode to the side surfaces of the semiconductor 406b is less likely to be blocked by the conductor 416a and the conductor 416b. The conductor 416a and the conductor 416b are not in contact with a top surface of the insulator 402. Thus, excess oxygen (oxygen) released from the insulator 402 is not consumed to oxidize the conductor 416a and the conductor 416b. Accordingly, excess oxygen (oxygen) released from the insulator 402 can be efficiently used to reduce oxygen vacancies in the semiconductor 406b. In other words, the transistor having the structure illustrated in FIGS. 13A and 13B has excellent electrical characteristics such as a high on-state current, high field-effect mobility, a small subthreshold swing value, and high reliability.

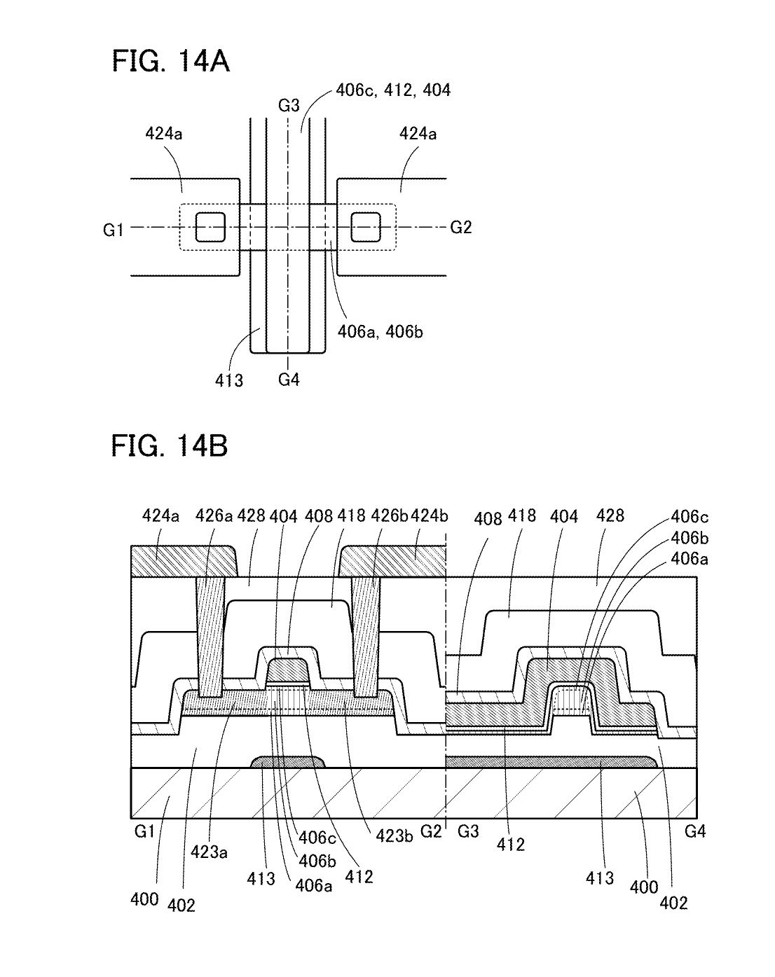

FIGS. 14A and 14B are a top view and a cross-sectional view of a transistor of one embodiment of the present invention. FIG. 14A is a top view and FIG. 14B is a cross-sectional view taken along dashed-dotted line G1-G2 and dashed-dotted line G3-G4 in FIG. 14A. Note that for simplification of the drawing, some components are not illustrated in the top view in FIG. 14A.

The transistor may have a structure in which, as illustrated in FIGS. 14A and 14B, the conductor 416a and the conductor 416b are not provided and the conductor 426a and the conductor 426b are in contact with the semiconductor 406b. In this case, the low-resistance region 423a (low-resistance region 423b) is preferably provided in a region in contact with at least the conductor 426a and the conductor 426b in the semiconductor 406b and/or the semiconductor 406a. The low-resistance region 423a and the low-resistance region 423b may be formed in such a manner that, for example, the conductor 404 and the like are used as masks and impurities are added to the semiconductor 406b and/or the semiconductor 406a. The conductor 426a and the conductor 426b may be provided in holes (portions which penetrate) or recessed portions (portions which do not penetrate) of the semiconductor 406b. When the conductor 426a and the conductor 426b are provided in holes or recessed portions of the semiconductor 406b, contact areas between the conductors 426a and 426b and the semiconductor 406b are increased; thus, the adverse effect of the contact resistance can be decreased. In other words, the on-state current of the transistor can be increased.

### <Transistor Structure 2>

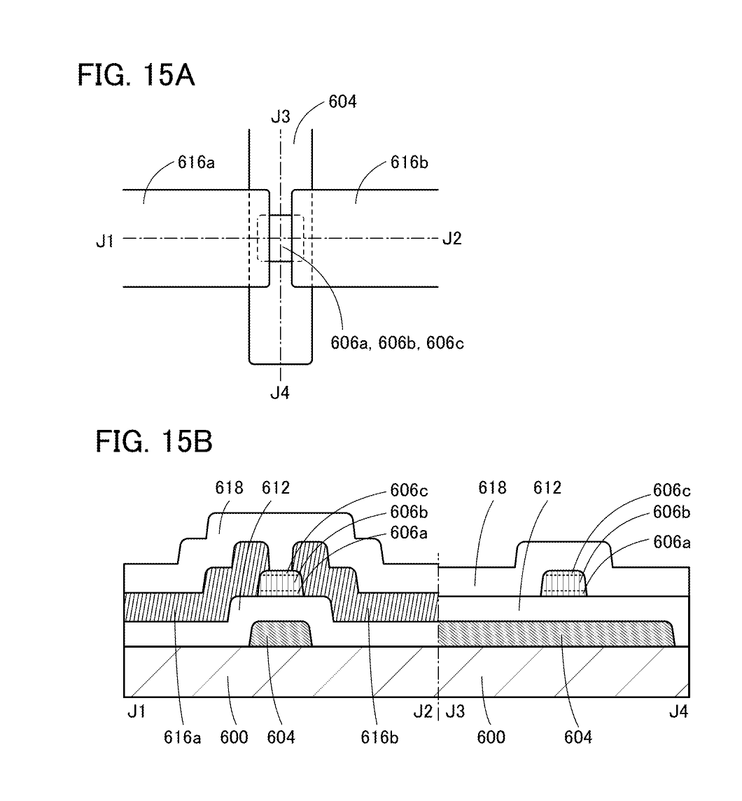

FIGS. 15A and 15B are a top view and a cross-sectional view which illustrate a transistor of one embodiment of the present invention. FIG. 15A is a top view and FIG. 15B is a cross-sectional view taken along dashed-dotted line J1-J2 and dashed-dotted line J3-J4 in FIG. 15A. Note that for simplification of the drawing, some components are not illustrated in the top view in FIG. 15A.

The transistor in FIGS. 15A and 15B includes a conductor 604 over a substrate 600, an insulator 612 over the conductor 604, a semiconductor 606a over the insulator 612, a semiconductor 606b over the semiconductor 606a, a semiconductor 606c over the semiconductor 606b, a conductor 616a and a conductor 616b which are in contact with the semiconductor 606a, the semiconductor 606b, and the semiconductor 606c and which are arranged to be apart from each other, and an insulator 618 over the semiconductor 606c, the conductor 616a, and the conductor 616b. The conductor 604 faces a bottom surface of the semiconductor 606b with the insulator 612 provided therebetween. The insulator 612 may have a projection. An insulator may be provided between the substrate 600 and the conductor 604. For the insulator, the description of the insulator 402 or the insulator 408 is referred to. The semiconductor 606a and/or the insulator 618 are/is not necessarily provided.

The semiconductor 606b serves as a channel formation region of the transistor. The conductor 604 serves as a first gate electrode (also referred to as a front gate electrode) of the transistor. The conductor 616a and the conductor 616b serve as a source electrode and a drain electrode of the transistor.

The insulator 618 is preferably an insulator containing excess oxygen.

For the substrate 600, the description of the substrate 400 is referred to. For the conductor 604, the description of the conductor 404 is referred to. For the insulator 612, the description of the insulator 412 is referred to. For the semiconductor 606a, the description of the semiconductor 406c is referred to. For the semiconductor 606b, the description of the semiconductor 406b is referred to. For the semiconductor 606c, the description of the semiconductor 406a is referred to. For the conductor 616a and the conductor 616b, the description of the conductor 416a and the conductor 416b is referred to. For the insulator 618, the description of the insulator 402 is referred to.

Over the insulator 618, a display element may be provided. For example, a pixel electrode, a liquid crystal layer, a common electrode, a light-emitting layer, an organic EL layer, an anode electrode, a cathode electrode, or the like may be provided. The display element is connected to the conductor 616a or the like, for example.

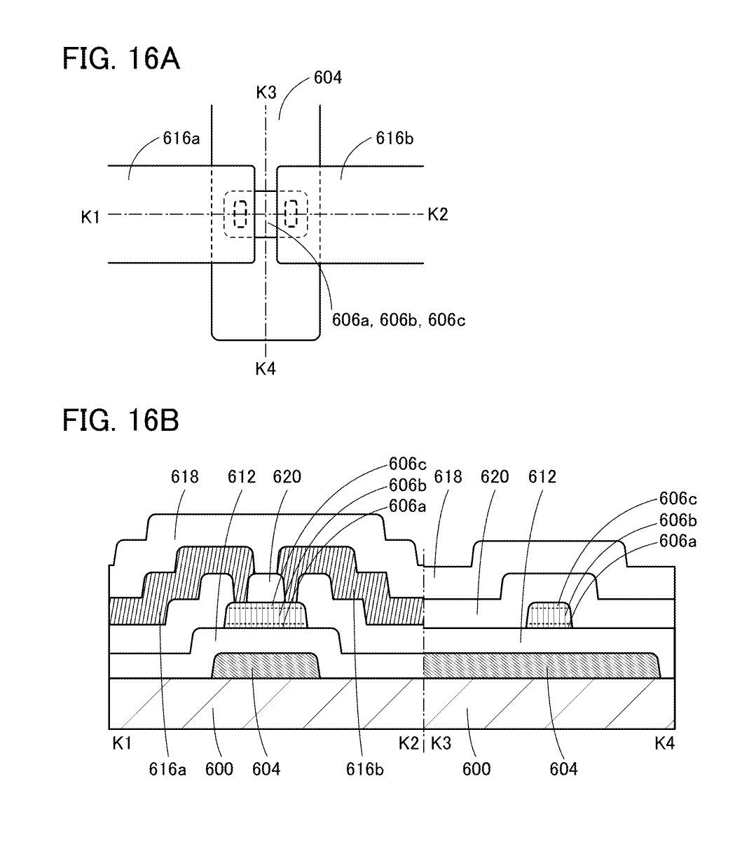

FIG. 16A is an example of a top view of a transistor. FIG. 16B is an example of a cross-sectional view taken along dashed-dotted line K1-K2 and dashed-dotted line K3-K4 in FIG. 16A. Note that some components such as an insulator are omitted in FIG. 16A for easy understanding.

Over the semiconductor, an insulator that can function as a channel protective film may be provided. For example, as illustrated in FIGS. 16A and 16B, an insulator 620 may be provided between the semiconductor 606c and the conductors 616a and 616b. In that case, the conductor 616a (conductor 616b) and the semiconductor 606c are connected to each other through an opening in the insulator 620. For the insulator 620, the description of the insulator 618 may be referred to.

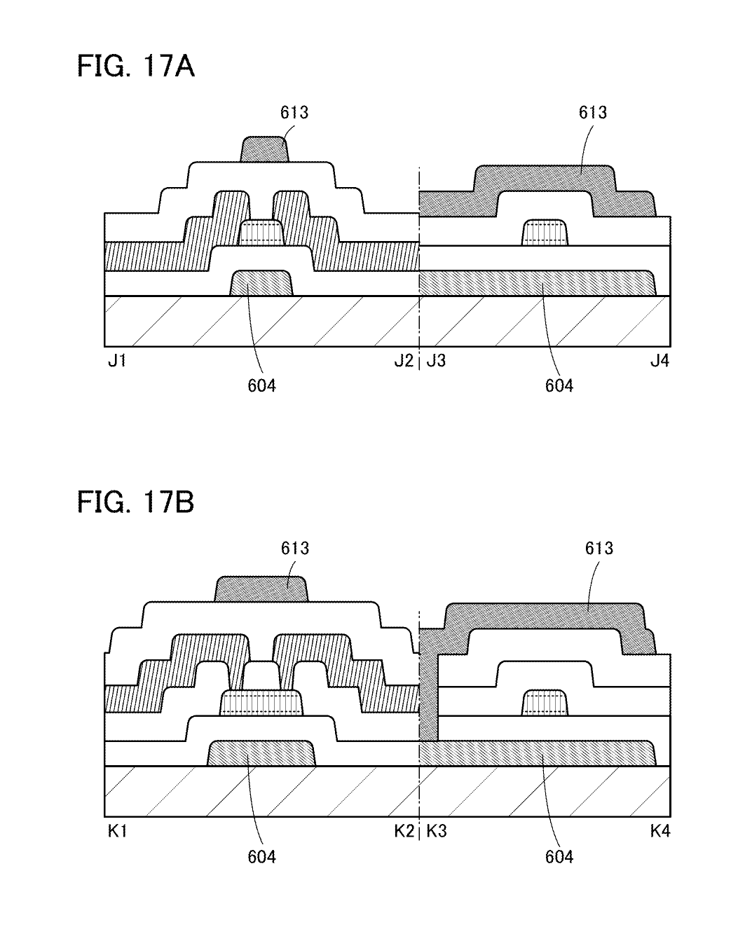

In FIG. 15B and FIG. 16B, a conductor 613 may be provided over the insulator 618. Examples in that case are shown in FIGS. 17A and 17B. For the conductor 613, the description of the conductor 413 is referred to. A potential or signal which is the same as that supplied to the conductor 604 or a potential or signal which is different from that supplied to the conductor 604 may be supplied to the conductor 613. For example, by supplying a constant potential to the conductor 613, the threshold voltage of a transistor may be controlled. In other words, the conductor 613 can function as a second gate electrode. Note that the transistor may have an s-channel structure using the conductor 613 or the like.

### <PLD Method>

An In—Ga—Zn oxide deposited by a pulsed laser deposition (PLD) method, which has a deposition mechanism different from the above-described deposition model, is described below.

A method for fabricating a sample is described. First, a silicon substrate is prepared. Then, a thermal oxidation film is formed to a thickness of 100 nm. Next, an In—Ga—Zn oxide is deposited by a PLD method, whereby the sample is fabricated.

Note that a polycrystalline In—Ga—Zn oxide with an atomic ratio of In:Ga:Zn=1:1:1 is used as a target. For ablation of the target, laser light with a wavelength of 266 nm is generated with a Nd:YAG laser and is used with an output power of 0.1 W and a pulse frequency of 10 Hz.

The In—Ga—Zn oxide is deposited under four conditions, where different pressures are used. A sample 1 is an In—Ga—Zn oxide deposited without changing the pressure after exhaust using a turbo molecular pump, i.e., under a pressure of 2.6×10⁻⁵ Pa. A sample 2 is an In—Ga—Zn oxide deposited using an oxygen gas under a pressure of 1.0×10⁻³ Pa. A sample 3 is an In—Ga—Zn oxide deposited using an oxygen gas under a pressure of 0.7 Pa. A sample 4 is an In—Ga—Zn oxide deposited using an oxygen gas under a pressure of 7.0 Pa. Note that for each sample, deposition time is 30 minutes and a substrate temperature is room temperature.

High-resolution cross-sectional TEM images of the samples 1 to 4 are obtained. The high-resolution cross-sectional TEM images are obtained using a Hitachi H-9000NAR transmission electron microscope at an accelerating voltage of 300 kV.

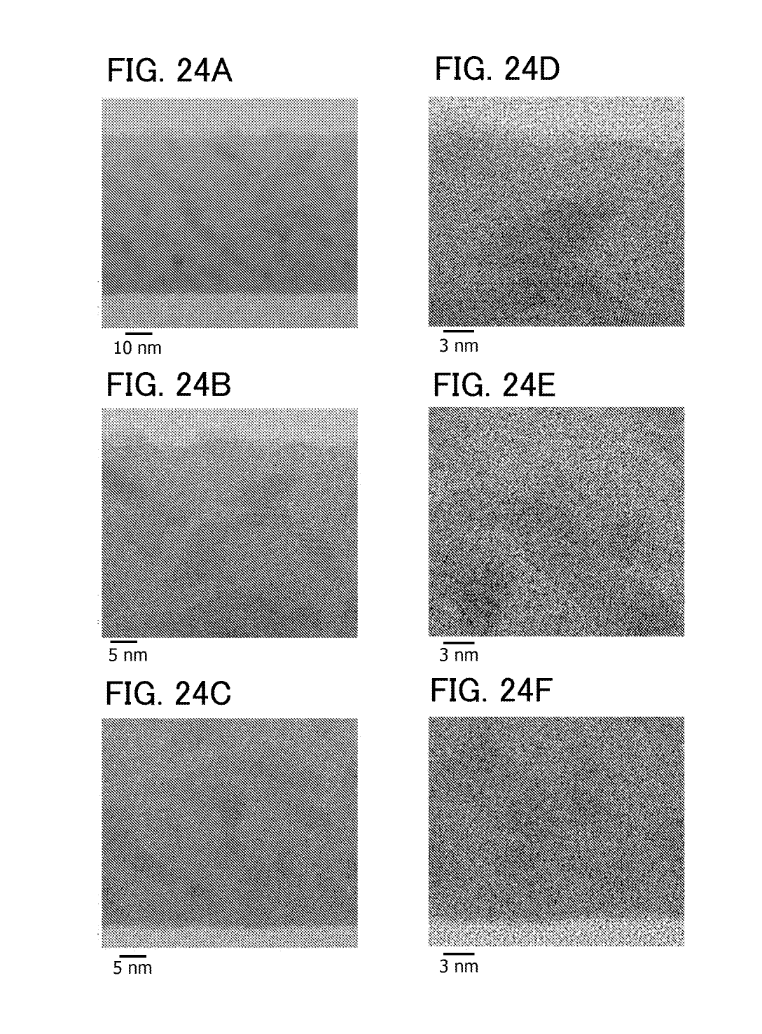

FIGS. 24A to 24F show the high-resolution cross-sectional TEM images of the sample 1. Note that the high-resolution cross-sectional TEM image in FIG. 24A is obtained with a magnification such that the whole film in the thickness direction appears in the image. From FIG. 24A, it is found that the film thickness is approximately 70 nm. The high-resolution cross-sectional TEM images in FIGS. 24B and 24C are respectively obtained with a magnification such that the top portion of the film appears in the image and a magnification such that the bottom portion of the film appears in the image. The high-resolution cross-sectional TEM images in FIGS. 24D, 24E, and 24F are respectively those of the top portion, the middle portion, and the bottom portion of the film obtained with a higher magnification.

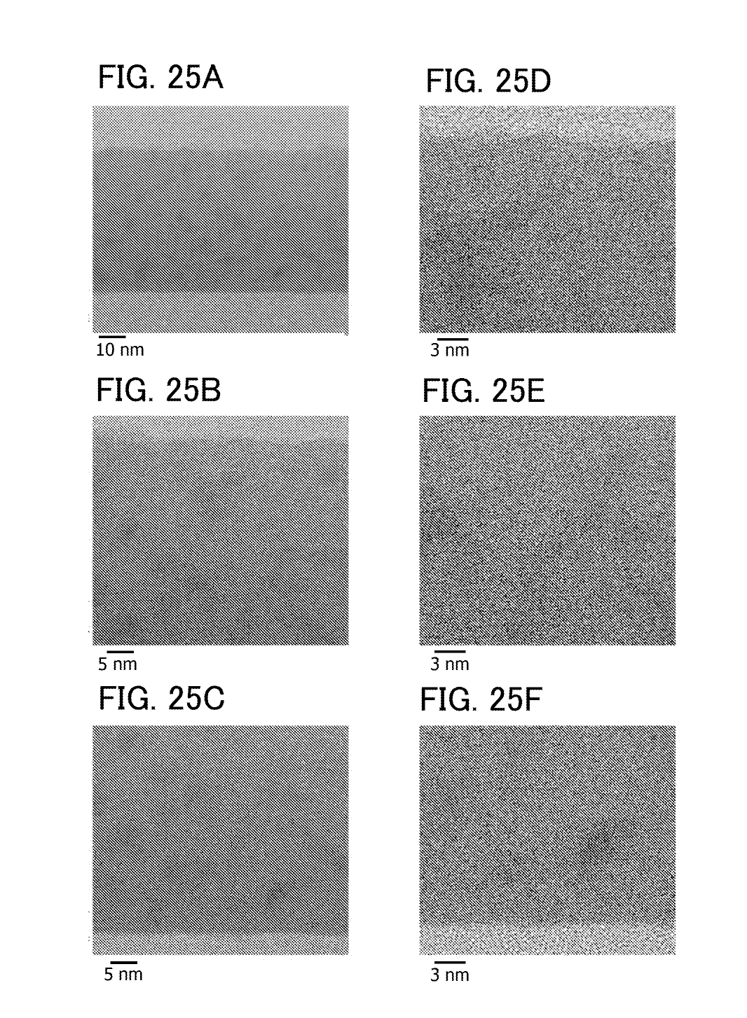

FIGS. 25A to 25F show the high-resolution cross-sectional TEM images of the sample 2. Note that the high-resolution cross-sectional TEM image in FIG. 25A is obtained with a magnification such that the whole film in the thickness direction appears in the image. From FIG. 25A, it is found that the film thickness is approximately 68 nm. The high-resolution cross-sectional TEM images in FIGS. 25B and 25C are respectively obtained with a magnification such that the top portion of the film appears in the image and a magnification such that the bottom portion of the film appears in the image. The high-resolution cross-sectional TEM images in FIGS. 25D, 25E, and 25F are respectively those of the top portion, the middle portion, and the bottom portion of the film obtained with a higher magnification.

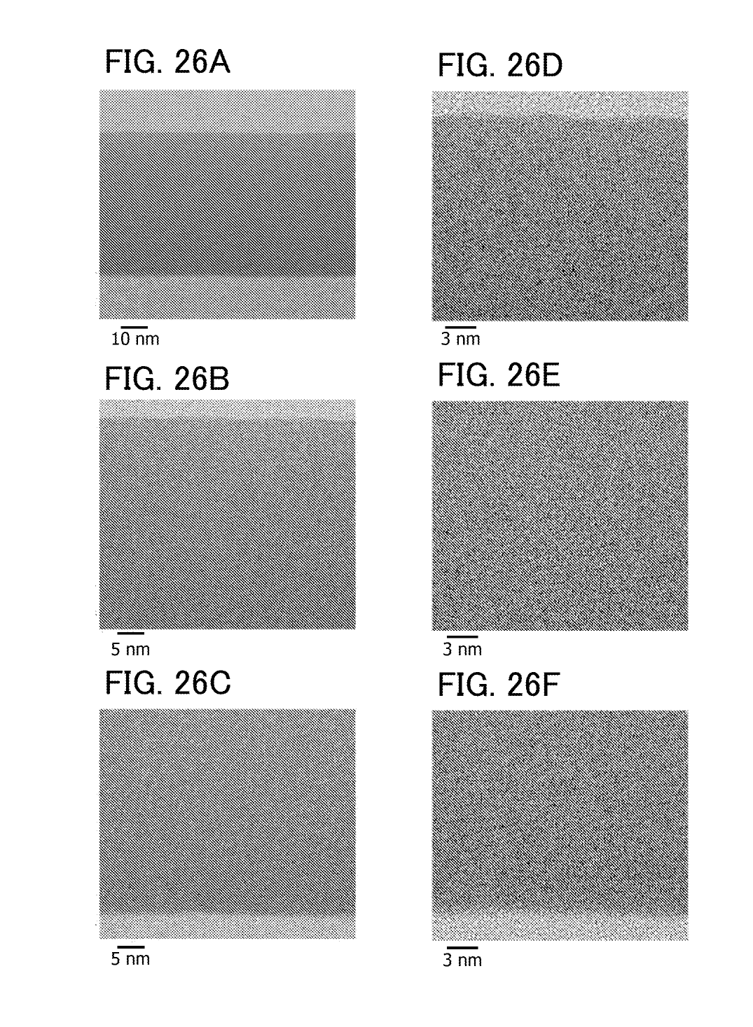

FIGS. 26A to 26F show the high-resolution cross-sectional TEM images of the sample 3. Note that the high-resolution cross-sectional TEM image in FIG. 26A is obtained with a magnification such that the whole film in the thickness direction appears in the image. From FIG. 26A, it is found that the film thickness is approximately 56 nm. The high-resolution cross-sectional TEM images in FIGS. 26B and 26C are respectively obtained with a magnification such that the top portion of the film appears in the image and a magnification such that the bottom portion of the film appears in the image. The high-resolution cross-sectional TEM images in FIGS. 26D, 26E, and 26F are respectively those of the top portion, the middle portion, and the bottom portion of the film obtained with a higher magnification.

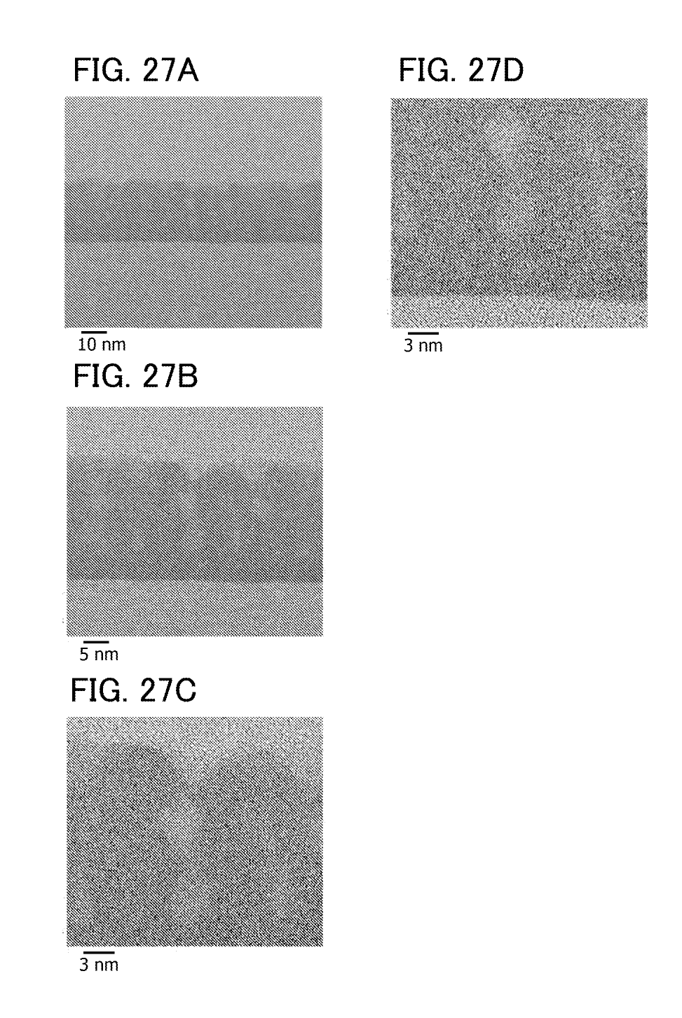

FIGS. 27A to 27D show the high-resolution cross-sectional TEM images of the sample 4. Note that the high-resolution cross-sectional TEM images in FIGS. 27A and 27B are obtained with a magnification such that the whole film in the thickness direction appears in the images. From FIGS. 27A and 27B, it is found that the film thickness is approximately 26 nm. The high-resolution cross-sectional TEM images in FIGS. 27C and 27D are respectively obtained with a magnification such that the top portion of the film appears in the image and a magnification such that the bottom portion of the film appears in the image.

Given regions of the samples 1 to 4 are subjected to nanobeam electron diffraction, so that diffraction patterns are obtained. Note that the nanobeam electron diffraction patterns are obtained using a Hitachi HF-2000 field-emission transmission electron microscope under conditions where the accelerating voltage is 200 kV, the probe diameter is 1 nm, and the camera length is 0.8 m. A high-resolution cross-sectional TEM image showing the portions subjected to the nanobeam electron diffraction is obtained using a Hitachi H-9000NAR transmission electron microscope at an accelerating voltage of 300 kV.

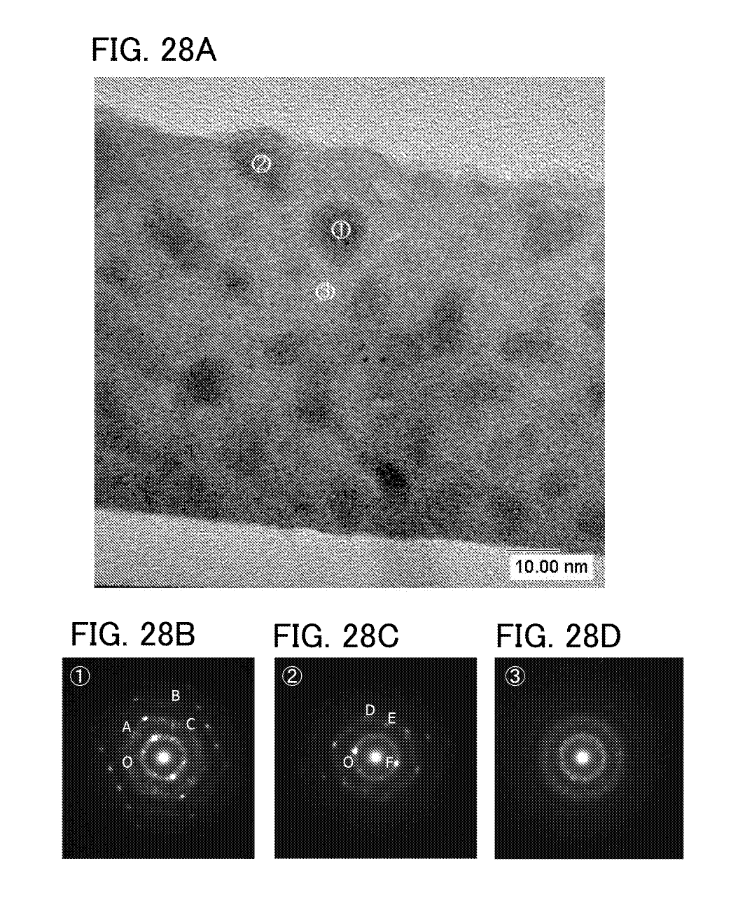

FIG. 28A shows the high-resolution cross-sectional TEM image of the sample 1. FIGS. 28B, 28C, and 28D show the nanobeam electron diffraction patterns of measurement regions 1, 2, and 3 in FIG. 28A.

Analysis of FIG. 28B shows that the d value of a spot A is 0.278 nm, the d value of a spot B is 0.095 nm, and the d value of a spot C is 0.108 nm. These values are well consistent with a d value of 0.279 nm of the (1 0 2) plane (denoted as A′), a d value of 0.095 nm of the (3 −3 0) plane (denoted as B′), and a d value of 0.107 nm of the (2 −3 −2) plane (denoted as C′) in InGaZnO₄ including a rhombohedral crystal. Furthermore, ∠AOB is 60.2°, ∠AOC is 79.9°, and ∠BOC is 19.7°. These values are well consistent with ∠A′OB′ of 60.8°, ∠A′OC′ of 80.4°, and ∠B′OC′ of 19.7°. Therefore, the diffraction pattern shown in FIG. 28B can be attributed to InGaZnO₄ including a rhombohedral crystal. In other words, there is the possibility that the vicinity of the measurement region of FIG. 28B is a crystal part of InGaZnO₄ including a rhombohedral crystal. Note that for data on InGaZnO₄ including a rhombohedral crystal, JCPDS card No. 38-1104 is referred to.

In attribution of the diffraction pattern in FIG. 28B to In₂Ga₂ZnO₇ including a hexagonal crystal, the above d values of the spots A to C are well consistent with a d value of 0.281 nm of the (1 0 −2) plane (denoted as A′), a d value of 0.095 nm of the (3 −3 1) plane (denoted as B′), and a d value of 0.108 nm of the (2 −3 3) plane (denoted as C′). Furthermore, the above values of ∠AOB, ∠AOC, and ∠BOC are well consistent with ∠A′OB′ of 61.0°, ∠A′OC′ of 80.6°, and ∠B′OC′ of 19.6°. Therefore, the diffraction pattern shown in FIG. 28B can be attributed to In₂Ga₂ZnO₇ including a hexagonal crystal. In other words, there is the possibility that the vicinity of the measurement region of FIG. 28B is a crystal part of In₂Ga₂ZnO₇ including a hexagonal crystal. Note that for data on In₂Ga₂ZnO₇ including a hexagonal crystal, JCPDS card No. 38-1097 is referred to.

Analysis of FIG. 28C shows that the d value of a spot D is 0.166 nm, the d value of a spot E is 0.143 nm, and the d value of a spot F is 0.275 nm. These values are well consistent with a d value of 0.165 nm of the (1 1 0) plane (denoted as D′), a d value of 0.142 nm of the (2 0 2) plane (denoted as E′), and a d value of 0.279 nm of the (1 −1 2) plane (denoted as F′) in InGaZnO₄ including a rhombohedral crystal. Furthermore, ∠DOE is 32.1°, ∠DOF is 89.7°, and ∠EOF is 57.6°. These values are well consistent with ∠D′OE′ of 30.6°, ∠D′OF′ of 90.0°, and ∠E′OF′ of 59.4°. Therefore, the diffraction pattern shown in FIG. 28C can be attributed to InGaZnO₄ including a rhombohedral crystal. In other words, there is the possibility that the vicinity of the measurement region of FIG. 28C is a crystal part of InGaZnO₄ including a rhombohedral crystal.

In attribution of the diffraction pattern in FIG. 28C to In₂Ga₂ZnO₇ including a hexagonal crystal, the above d values of the spots D to F are well consistent with a d value of 0.165 nm of the (2 −1 0) plane (denoted as D′), a d value of 0.141 nm of the (2 −2 4) plane (denoted as E′), and a d value of 0.267 nm of the (0 −1 4) plane (denoted as F′). Furthermore, the above values of ∠DOE, ∠DOF, and ∠EOF are well consistent with ∠D′OE′ of 31.8°, ∠D′OF′ of 90.0°, and ∠E′OF′ of 58.2°. Therefore, the diffraction pattern shown in FIG. 28C can be attributed to In₂Ga₂ZnO₇ including a hexagonal crystal. In other words, there is the possibility that the vicinity of the measurement region of FIG. 28C is a crystal part of In₂Ga₂ZnO₇ including a hexagonal crystal.

In analysis of FIG. 28D, a plurality of spots are seen in a ring-like region, which means that the diffraction pattern is that of an nc-OS. Here, such a region is called an nc-OS portion for convenience.

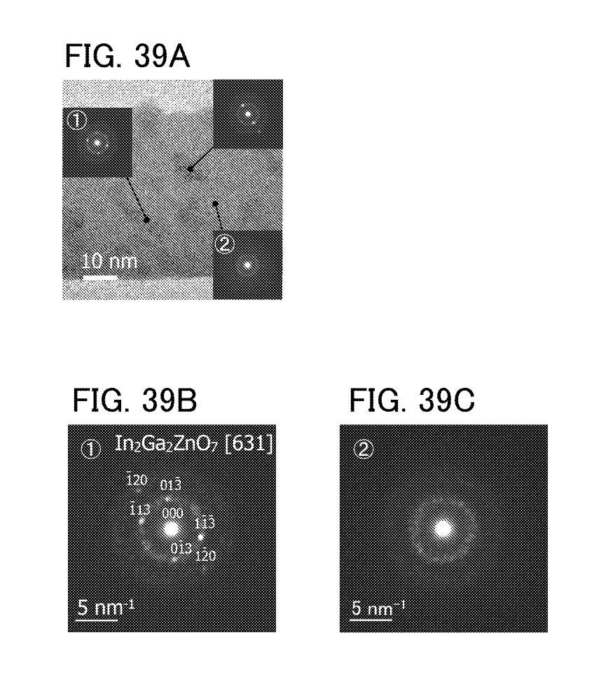

Different portions of the sample 1 are subjected to nanobeam electron diffraction, so that diffraction patterns are obtained. FIG. 39A shows a high-resolution cross-sectional TEM image of the sample 1. FIGS. 39B and 39C show nanobeam electron diffraction patterns of measurement regions 1 and 2 in FIG. 39A, and attribution of spots. The diffraction pattern of the measurement region 1 can be attributed to a diffraction pattern obtained by making electrons enter In₂Ga₂ZnO₇ including a hexagonal crystal from the [631] direction thereof. The measurement region 2 produces a diffraction pattern of an nc-OS.

It is revealed from FIGS. 28A to 28D and FIGS. 39A to 39C that the diffraction patterns vary between the crystal parts in the sample 1. In addition, it is shown that a region where a spot which can be attributed to a crystal structure is not observed has an nc-OS structure. From the high-resolution cross-sectional TEM images in FIGS. 24A to 24F and the like, no clear crystal grain boundaries can be observed between crystal parts or between a crystal part and an nc-OS portion. In view of these features, the sample 1 can be classified into a microcrystalline structure.

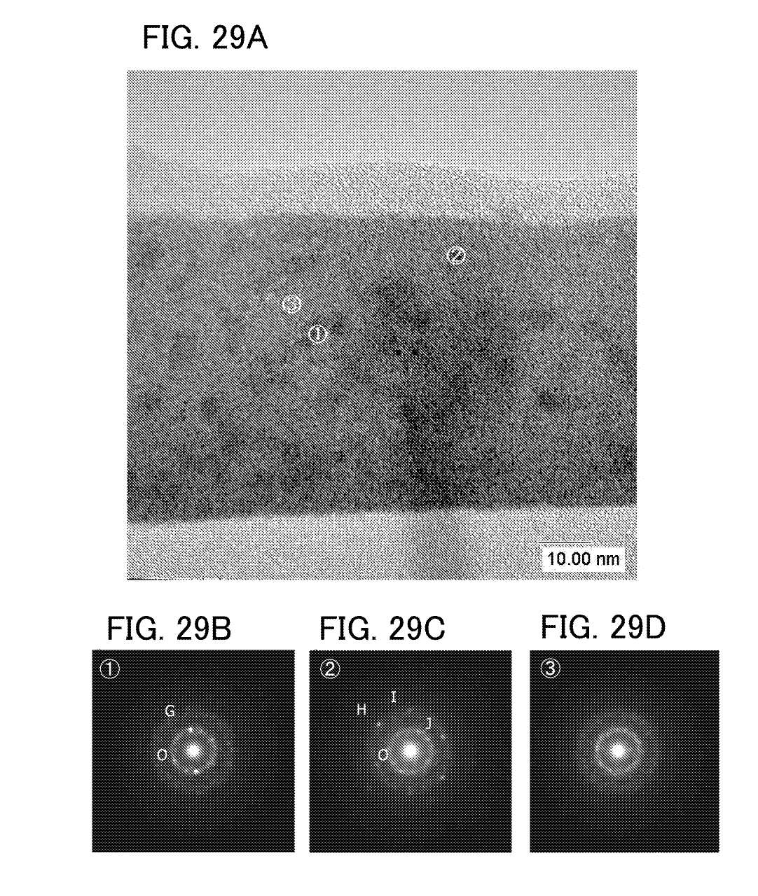

Nanobeam electron diffraction patterns of the sample 2 are obtained. FIG. 29A shows a high-resolution cross-sectional TEM image of the sample 2. FIGS. 29B, 29C, and 29D show nanobeam electron diffraction patterns of measurement regions 1, 2, and 3 in FIG. 29A.

Analysis of the diffraction pattern in FIG. 29B shows that the d value of a spot G is 0.277 nm. No clear spot is observed other than the spot G, and it is difficult to attribute the diffraction pattern to a specific crystal structure.

Analysis of FIG. 29C shows that the d value of a spot H is 0.138 nm, the d value of a spot I is 0.140 nm, and the d value of a spot J is 0.162 nm. These values are well consistent with a d value of 0.135 nm of the (1 0 −17) plane (denoted as H′), a d value of 0.140 nm of the (2 0 −4) plane (denoted as I′), and a d value of 0.162 nm of the (1 0 13) plane (denoted as J′) in InGaZnO₄ including a rhombohedral crystal. Furthermore, ∠HOI is 49.6°, ∠HOJ is 115.9°, and ∠IOJ is 66.3°. These values are well consistent with ∠H′OI′ of 49.4°, ∠H′OJ′ of 116.6°, and ∠I′OJ′ of 67.2°. Therefore, the diffraction pattern shown in FIG. 29C can be attributed to InGaZnO₄ including a rhombohedral crystal. In other words, there is the possibility that the vicinity of the measurement region of FIG. 29C is a crystal part of InGaZnO₄ including a rhombohedral crystal. In a manner similar to that of the vicinity of the measurement region of FIG. 28B or 28C, there is the possibility that the vicinity of the measurement region of FIG. 29C is a crystal part of In₂Ga₂ZnO₇ including a hexagonal crystal.

In analysis of FIG. 29D, a plurality of spots are seen in a ring-like region, which means that the diffraction pattern is that of an nc-OS.

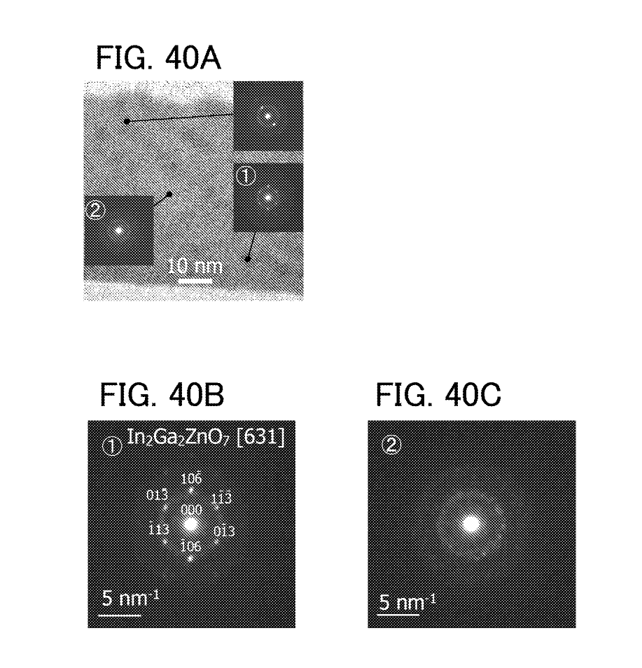

Different portions of the sample 2 are subjected to nanobeam electron diffraction, so that diffraction patterns are obtained. FIG. 40A shows a high-resolution cross-sectional TEM image of the sample 2. FIGS. 40B and 40C show nanobeam electron diffraction patterns of measurement regions 1 and 2 in FIG. 40A, and attribution of spots. The diffraction pattern of the measurement region 1 can be attributed to a diffraction pattern obtained by making electrons enter In₂Ga₂ZnO₇ including a hexagonal crystal from the [631] direction thereof. The measurement region 2 produces a diffraction pattern of an nc-OS.

It is revealed from FIGS. 29A to 29D and FIGS. 40A to 40C that the diffraction patterns vary between the crystal parts in the sample 2. In addition, it is shown that a region where a spot which can be attributed to a crystal structure is not observed has an nc-OS structure. From the high-resolution cross-sectional TEM images in FIGS. 25A to 25F and the like, no clear crystal grain boundaries can be observed between crystal parts or between a crystal part and an nc-OS portion. In view of these features, the sample 2 can be classified into a microcrystalline structure.

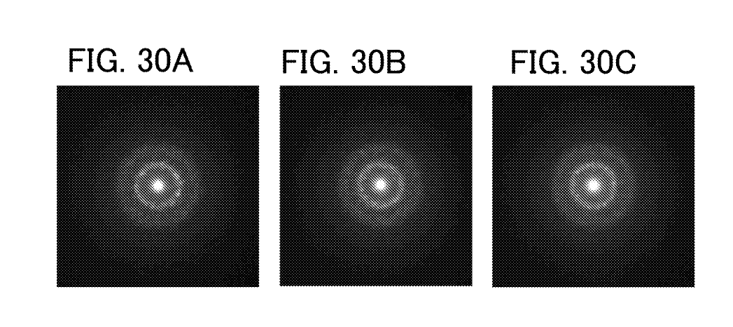

Nanobeam electron diffraction patterns of the sample 3 are obtained. FIGS. 30A, 30B, and 30C respectively show nanobeam electron diffraction patterns of measurement regions in the top portion, the middle portion, and the bottom portion of the sample 3.

In analysis of FIGS. 30A, 30B, and 30C, a plurality of spots are seen in a ring-like region, which means that the diffraction patterns are those of an nc-OS. Thus, the sample 3 turned out to have an nc-OS structure. According to the high-resolution cross-sectional TEM images in FIGS. 26A to 26F and the like, the sample 3 can be classified into an nc-OS structure with relatively uniform quality.

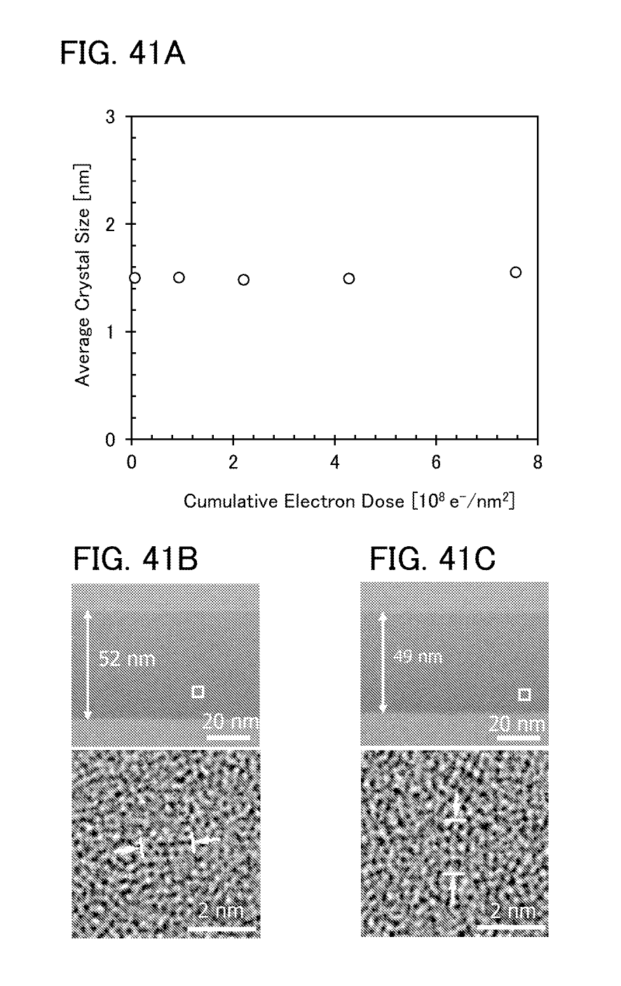

Then, the size of the crystal part of the sample 3 is measured. FIG. 41A shows the change in average size of crystal parts (at 30 points to 35 points) in the sample 3. From FIG. 41A, it is found that the crystal part size in the sample 3 shows little change from the start of electron irradiation to a cumulative electron dose of 7.6×10⁸ e⁻/nm² regardless of the cumulative electron dose. Note that FIG. 41B shows a high-resolution cross-sectional TEM image at the start of the electron irradiation and an enlarged high-resolution cross-sectional TEM image of the surrounded portion. As shown in FIG. 41B, a crystal part, which is interposed between arrows in the image, can be observed by magnification of the high-resolution cross-sectional TEM image of the sample 3. FIG. 41C shows a high-resolution cross-sectional TEM image after the electron irradiation with an amount of electron irradiation of 7.6×10⁸ e⁻/nm² and an enlarged high-resolution cross-sectional TEM image of the surrounded portion. A crystal part can be observed also in FIG. 41C.

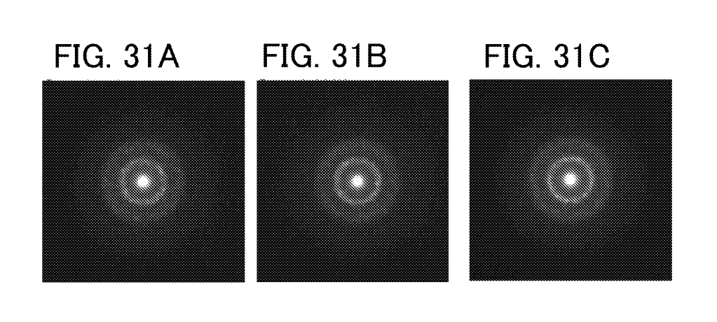

Nanobeam electron diffraction patterns of the sample 4 are obtained. FIGS. 31A, 31B, and 31C respectively show nanobeam electron diffraction patterns of measurement regions in the top portion, the middle portion, and the bottom portion of the sample 4.

In analysis of FIGS. 31A, 31B, and 31C, a plurality of spots are seen in a ring-like region, which means that the diffraction patterns are those of an nc-OS. According to the high-resolution cross-sectional TEM images in FIGS. 27A to 27D and the like, the sample 4 partly contains voids. Thus, the sample 4 can be classified into an a-like OS structure.

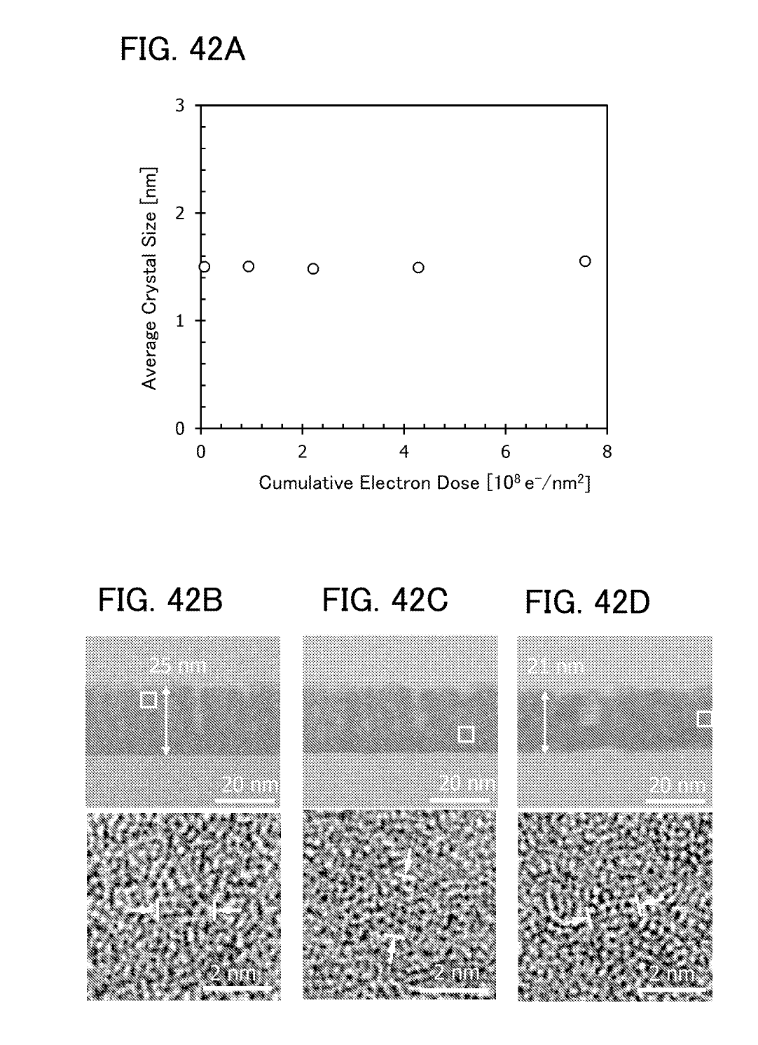

Then, the size of the crystal part of the sample 4 is measured. FIG. 42A shows the change in average size of crystal parts (at 20 points to 30 points) in the sample 4. From FIG. 42A, it is found that the crystal part size in the sample 4 changes as a function of the cumulative electron dose from the start of electron irradiation to a cumulative electron dose of 7.6×10⁸ e⁻/nm². Note that FIG. 42B shows a high-resolution cross-sectional TEM image at the start of the electron irradiation and an enlarged high-resolution cross-sectional TEM image of the surrounded portion. As shown in FIG. 42B, a crystal part, which is interposed between arrows in the image, can be observed by magnification of the high-resolution cross-sectional TEM image of the sample 4. FIG. 42C shows a high-resolution cross-sectional TEM image after the electron irradiation with an amount of electron irradiation of 9.4×10⁷ e⁻/nm² and an enlarged high-resolution cross-sectional TEM image of the surrounded portion. A crystal part can be observed also in FIG. 42C. In addition, the crystal part size is larger in FIG. 42C than in FIG. 42B. FIG. 42D shows a high-resolution cross-sectional TEM image after the electron irradiation with an amount of electron irradiation of 7.6×10⁸ e⁻/nm² and an enlarged high-resolution cross-sectional TEM image of the surrounded portion. A crystal part can be observed also in FIG. 42D. The crystal part size is smaller in FIG. 42D than in FIG. 42C.

In the sample 4, the crystal part size increased first and then decreased, which suggests the possibility that a crystal part that had grown by electron irradiation was broken by further electron irradiation.

Table 4 shows change in size of the crystal parts and the like for the samples 3 and 4.

TABLE 4

| | | Cumulative | Cumulative | Cumulative | Cumulative | Cumulative |
|---|---|---|---|---|---|---|
| | | irradiation | irradiation | irradiation | irradiation | irradiation |
| Sample | | time: 0 min | time: 2 min | time: 5 min | time: 10 min | time: 18 min |
| 3 | Average [nm] | 1.50 | 1.50 | 1.49 | 1.49 | 1.55 |
| | Standard deviation | 0.29 | 0.28 | 0.29 | 0.29 | 0.24 |
| | Minimum [nm] | 1.00 | 0.99 | 0.90 | 0.97 | 0.96 |
| | Maximum [nm] | 2.19 | 2.20 | 2.21 | 2.01 | 2.17 |
| | Number of points | 30 | 33 | 31 | 31 | 35 |
| 4 | Average nm | 1.48 | 1.69 | 1.64 | 1.51 | 1.46 |
| | Standard deviation | 0.22 | 0.30 | 0.27 | 0.36 | 0.28 |
| | Minimum [nm] | 0.96 | 1.18 | 1.21 | 1.01 | 1.04 |
| | Maximum [nm] | 1.87 | 2.27 | 2.16 | 2.43 | 1.97 |
| | Number of points | 24 | 30 | 23 | 24 | 20 |

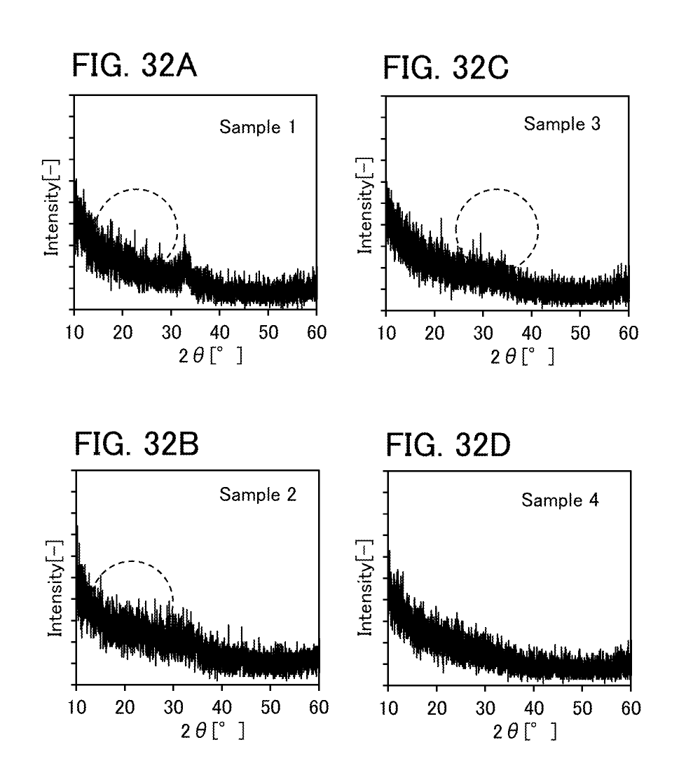

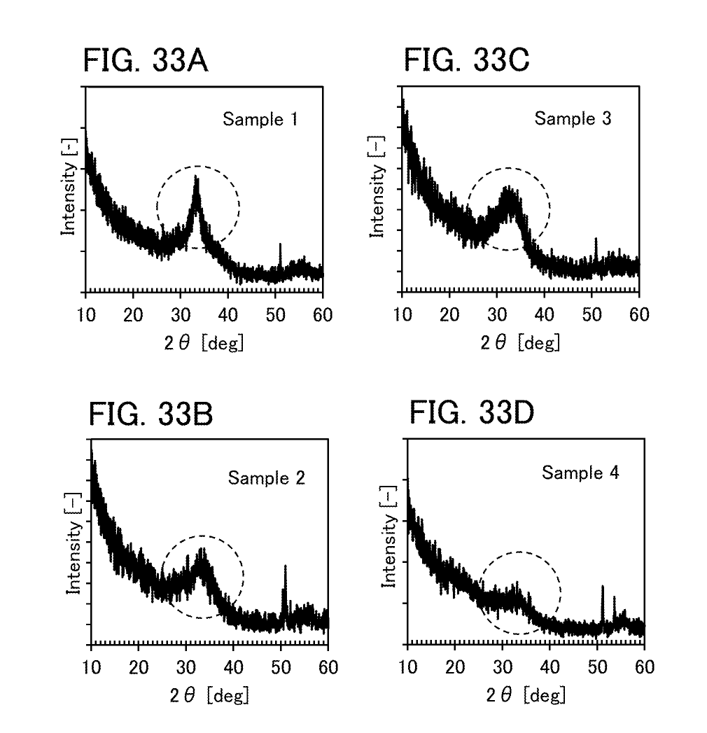

FIGS. 32A to 32D and FIGS. 33A to 33D show results of analysis of the samples 1 to 4 using an XRD apparatus. The analysis using the XRD apparatus is performed by a powder method (also called a θ-2θ method) and a grazing-incidence XRD (GIXRD) method (also called a thin film method or a Seemann-Bohlin method), each of which is a kind of an out-of-plane method. Note that in a θ-2θ method, X-ray diffraction intensity is measured while an incident angle of an X-ray is changed and the angle of a detector facing an X-ray source is equal to the incident angle. In a GIXRD method, X-ray diffraction intensity is measured while the incident angle of an X-ray is fixed at an extremely shallow angle and the angle of a detector facing an X-ray source is changed. Note that in the analysis by a GIXRD method, the incident angle is fixed at 0.40°.

FIG. 32A shows results of analysis of the sample 1 by a θ-2θ method. FIG. 32B shows results of analysis of the sample 2 by a θ-2θ method. FIG. 32C shows results of analysis of the sample 3 by a θ-2θ method. FIG. 32D shows results of analysis of the sample 4 by a θ-2θ method. FIG. 33A shows results of analysis of the sample 1 by a GIXRD method. FIG. 33B shows results of analysis of the sample 2 by a GIXRD method. FIG. 33C shows results of analysis of the sample 3 by a GIXRD method. FIG. 33D shows results of analysis of the sample 4 by a GIXRD method.

For the sample 1, a slightly sharp peak is observed in a range of 32°≦2θ≦35° by a θ-2θ method. Furthermore, for the sample 1, a sharp peak is observed in a range of 33°≦2θ≦34° by a GIXRD method. Crystal planes corresponding to the peaks that appear at these positions are not specified. Accordingly, it is highly likely that peaks representing a plurality of crystal planes overlap with each other. For the samples 2 and 3, broad peaks are observed in a range of 25°<28<40° by a θ-2θ method. Furthermore, for the samples 2 and 3, broad peaks are also observed in a range of 25°≦2θ≦40° by a GIXRD method. It is highly likely that these peaks reflect short-range order. For the sample 4, no clear peaks are observed by a θ-2θ method. This is very likely because the film thickness of the sample 4 is small. On the other hand, for the sample 4, a broad peak is observed in a range of 25°≦2θ≦40° by a GIXRD method. It is highly likely that this peak also reflects short-range order.

It is known that by a PLD method, an atomic particle, an ionic particle, a molecular particle, a cluster-like particle, or the like is ejected from a target by laser light. On the basis of this premise, difference in crystallinity between the In—Ga—Zn oxides deposited by a PLD method is discussed below.

The deposition pressures for the samples 1 and 2 are low. A relatively large proportion of the ejected cluster-like particles are deposited over a formation surface as they are. The cluster-like particle is deposited over the formation surface while maintaining the crystal structure; thus, the possibility of formation of a crystal part in a film is high. Note that in a PLD method, a cluster-like particle does not pass through plasma, so that the particle is not charged. In a PLD method, a magnetic field due to a magnet is not generated, so that force that makes a cluster-like particle move over the formation surface is not applied. Therefore, it can be said that cluster-like particles are not regularly deposited over the formation surface, unlike in the deposition model described with reference to FIG. 3 and the like. In other words, orientation is different between crystal parts.

Furthermore, since the deposition pressure for the sample 3 is high, the mean free path of a cluster-like particle is shorter than that in the deposition of the sample 1 or 2. As a result, a relatively low proportion of cluster-like particles are deposited over the formation surface, and a relatively high proportion of small particles, e.g., atomic particles, are deposited over the formation surface as they are. However, even in such deposition, a plurality of spots are seen in a ring-like region in a nanobeam electron diffraction pattern, which suggests that migration at the formation surface leads to formation of an nc-OS structure with a certain degree of order.

Furthermore, since the deposition pressure for the sample 4 is even higher, the mean free path of a cluster-like particle is shorter than that in the deposition of the sample 1 or 2. The number of atomic particles or the like that are deposited over the formation surface as they are is smaller in the deposition of the sample 4 than that in the deposition of the sample 3. Thus, a particle has a collision in some way to have reduced energy before being deposited over the formation surface. In other words, migration over the formation surface is not likely to occur, whereby a low-density film is formed.

The analysis results of the In—Ga—Zn oxides deposited at room temperature by a PLD method are described above. Analysis results of an In—Ga—Zn oxide formed by thermal deposition using a PLD method are described below. Note that the temperature of the thermal deposition is measured with the use of a thermocouple placed in the vicinity of the substrate surface.

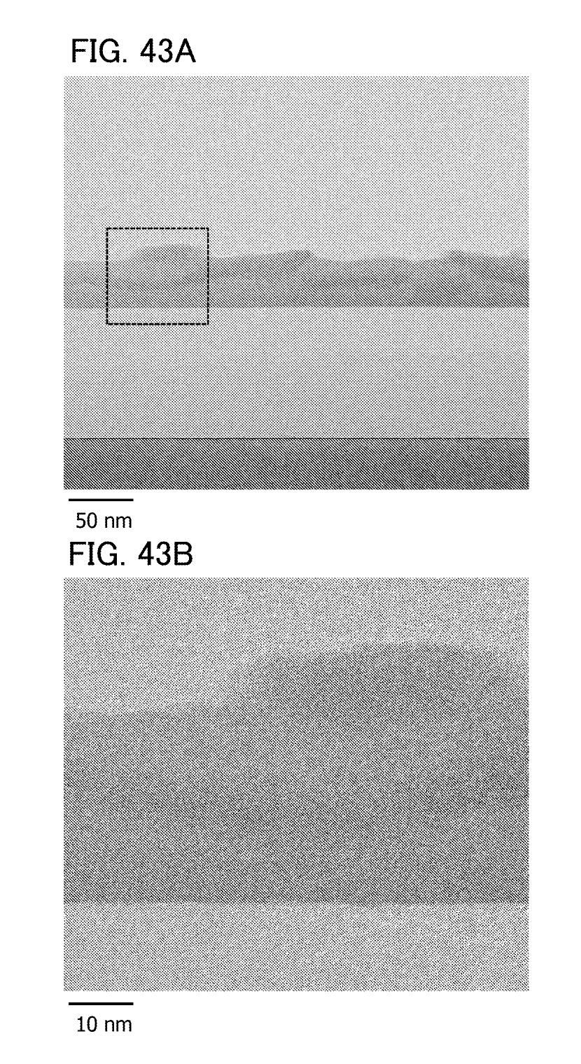

FIGS. 43A and 43B show cross-sectional TEM images of an In—Ga—Zn oxide deposited at a substrate surface temperature of 300° C. Other deposition conditions are similar to those for the sample 3. The TEM images in FIGS. 43A and 43B are observed with a spherical aberration corrector function. The TEM images are obtained using an atomic resolution analytical electron microscope JEM-ARM200F manufactured by JEOL Ltd. FIG. 43B is an enlarged TEM image of the surrounded portion in FIG. 43A.

As shown in FIGS. 43A and 43B, in the In—Ga—Zn oxide formed by thermal deposition using a PLD method, surface unevenness and nonuniformity in the film are observed. Furthermore, a CAAC-OS structure is not observed although the thermal deposition is employed.

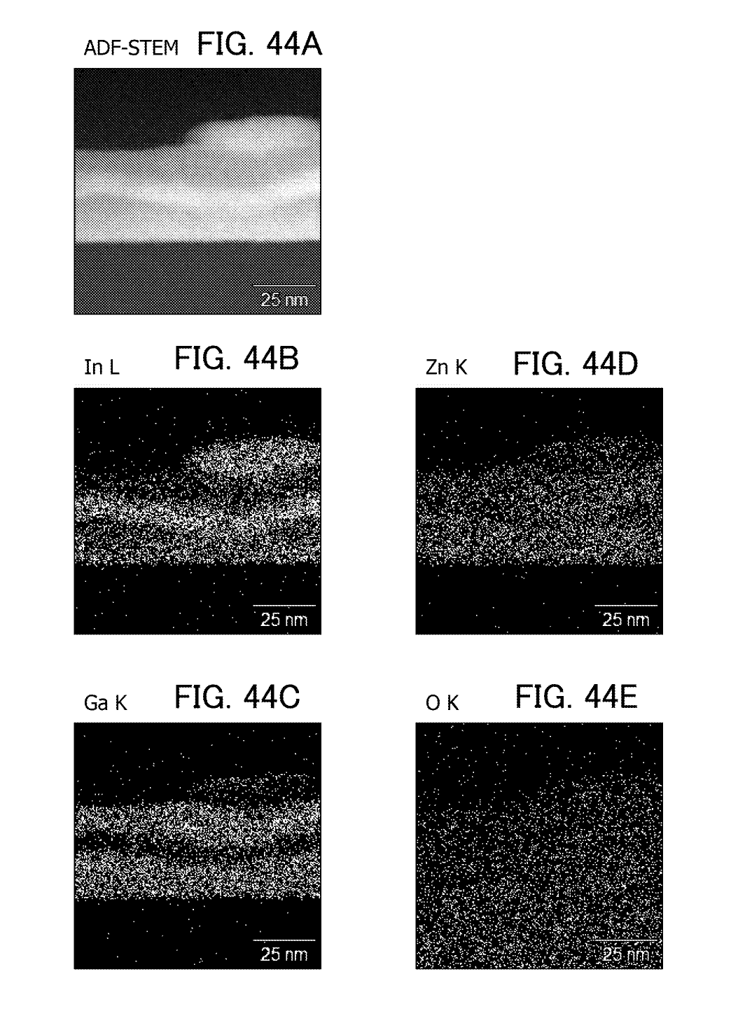

FIG. 44A is an annular dark-field scanning transmission electron microscopy (ADF-STEM) image of the measurement portion shown in FIG. 43B, and FIGS. 44B to 44E are mapping images thereof obtained by energy dispersive X-ray spectroscopy (EDX). Note that FIG. 44B is the mapping image of indium, FIG. 44C is that of gallium, FIG. 44D is that of zinc, and FIG. 44E is that of oxygen.

As FIGS. 44B and 44E reveal, segregation of an oxide containing indium is caused in a bright region in FIG. 44A. It is thus found that the surface unevenness and nonuniformity in the film by the thermal deposition resulted from segregation of the oxide containing indium.

As described above, it is possible that the In—Ga—Zn oxide deposited by a PLD method has a microcrystalline structure, an nc-OS structure, or an a-like OS structure but does not have a CAAC-OS structure. This is explainable with the deposition model described above with reference to FIG. 3 and the like. Note that the amorphous oxide containing a microcrystal reported in Patent Document 1 and the like is deposited by a PLD method as clearly stated therein. Thus, there is the possibility that the amorphous oxide is similar to the In—Ga—Zn oxide disclosed in this specification.

However, analysis by nanobeam electron diffraction and the like did not show that the In—Ga—Zn oxide disclosed in this specification has an amorphous structure, and thus, there is the possibility that the In—Ga—Zn oxide is not an amorphous oxide.

### <Electrical Characteristics of Transistor>

The electrical characteristics of transistors each including an In—Ga—Zn oxide deposited by a PLD method are described.

The transistor structure is similar to that illustrated in FIG. 12B. Thus, the reference numerals in FIG. 12B and the like are used in the description below. Note that the semiconductor 406a and the semiconductor 406c are not provided. The semiconductor 406b had a thickness of 35 nm. The insulator 412 is formed using silicon oxide and had a thickness of 40 nm.

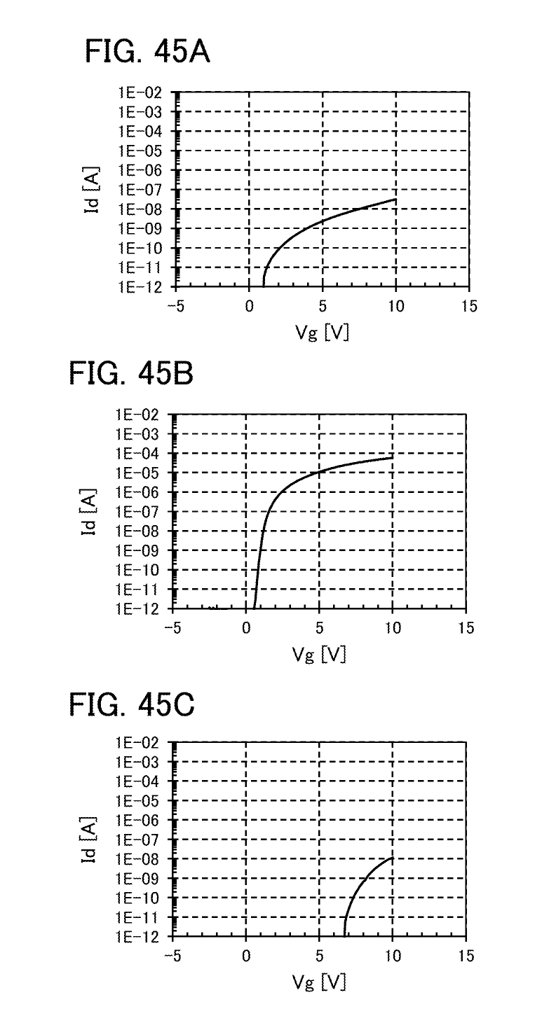

FIGS. 45A, 45B, and 45C show Id-Vg characteristics of the transistors at a drain voltage Vd of 4 V. The transistors each include an In—Ga—Zn oxide deposited by a PLD method as the semiconductor 406b. FIG. 45A shows the Id-Vg characteristics of the transistor that includes the In—Ga—Zn oxide deposited under the above-described conditions for the sample 2. FIG. 45B shows the Id-Vg characteristics of the transistor that includes the In—Ga—Zn oxide deposited under the above-described conditions for the sample 3. FIG. 45C shows the Id-Vg characteristics of the transistor that includes the In—Ga—Zn oxide deposited under the above-described conditions for the sample 4. The channel length is 50 μm and the channel width is 200 μm. Here, Id means a drain current and Vg means gate voltage.

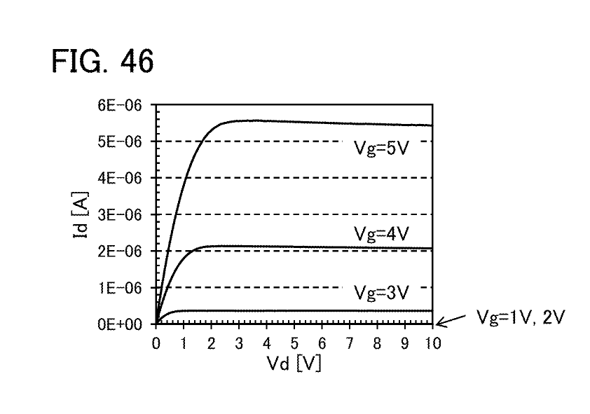

FIG. 46 shows the Id-Vd characteristics of the transistor that includes an In—Ga—Zn oxide deposited by a PLD method under the conditions for the sample 3. The channel length is 50 μm and the channel width is 200 μm.

From the above, the transistor that includes the In—Ga—Zn oxide deposited under the conditions for the sample 3 turned out to have favorable electrical characteristics. It is also found that the transistor that includes the In—Ga—Zn oxide deposited under the conditions for the sample 2 or 4 has a lower on-state current than the transistor that includes the In—Ga—Zn oxide deposited under the conditions for the sample 3.

### <Semiconductor Device>

An example of a semiconductor device of one embodiment of the present invention is shown below.

### <Circuit>

An example of a circuit including a transistor of one embodiment of the present invention is shown below.

### [CMOS Inverter]

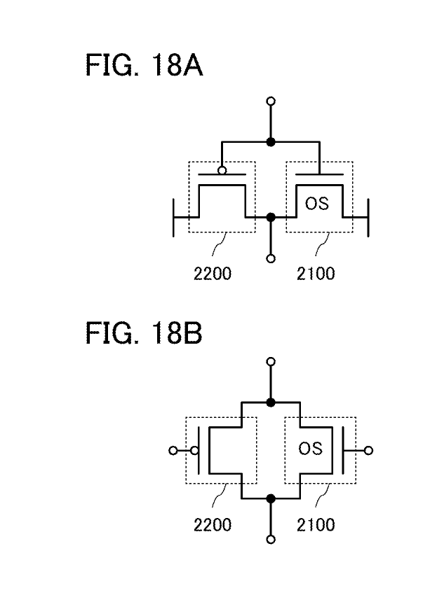

A circuit diagram in FIG. 18A shows a configuration of a so-called CMOS inverter in which the p-channel transistor 2200 and the n-channel transistor 2100 are connected to each other in series and in which gates of them are connected to each other. The transistor 2100 is a transistor using an oxide semiconductor.

### [CMOS Analog Switch]

A circuit diagram in FIG. 18B shows a configuration in which sources of the transistors 2100 and 2200 are connected to each other and drains of the transistors 2100 and 2200 are connected to each other. With such a configuration, the transistors can function as a so-called CMOS analog switch.

### [Memory Device Example]

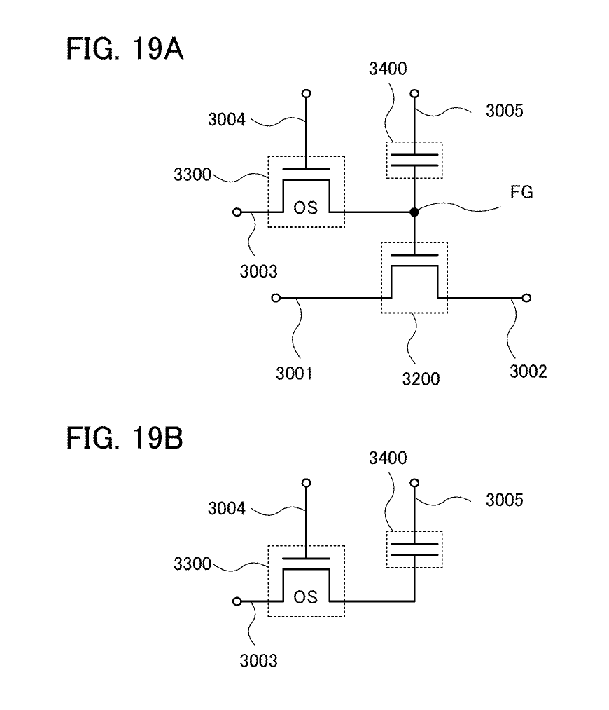

An example of a semiconductor device (memory device) which includes the transistor of one embodiment of the present invention, which can retain stored data even when not powered, and which has an unlimited number of write cycles is shown in FIGS. 19A and 19B.

The semiconductor device illustrated in FIG. 19A includes a transistor 3200 using a first semiconductor, a transistor 3300 using a second semiconductor, and a capacitor 3400. Note that any of the above-described transistors can be used as the transistor 3300.

The transistor 3300 is a transistor using an oxide semiconductor. Since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 19A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to the one electrode of the capacitor 3400. A fifth wiring 3005 is electrically connected to the other electrode of the capacitor 3400.

The semiconductor device in FIG. 19A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off Thus, the charge is held at the node FG (retaining).

Since the off-state current of the transistor 3300 is extremely low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is turned on. On the other hand, in the case where the low-level charge is supplied to the node FG in writing, even when the potential of the fifth wiring 3005 is V₀ (<Vₜₕ_{_{—}}_{L}), the transistor 3200 remains off. Thus, the data retained in the node FG can be read by determining the potential of the second wiring 3002.

Note that in the case where memory cells are arrayed, it is necessary that data of a desired memory cell is read in read operation. In the case where data of the other memory cells is not read, the fifth wiring 3005 may be supplied with a potential at which the transistor 3200 is turned off regardless of the charge supplied to the node FG, that is, a potential lower than Vₜₕ_{_{—}}_{H}. Alternatively, the fifth wiring 3005 may be supplied with a potential at which the transistor 3200 is turned on regardless of the charge supplied to the node FG, that is, a potential higher than Vₜₕ_{_{—}}_{L}.

The semiconductor device in FIG. 19B is different form the semiconductor device in FIG. 19A in that the transistor 3200 is not provided. Also in this case, writing and retaining operation of data can be performed in a manner similar to that of the semiconductor device in FIG. 19A.

Reading of data in the semiconductor device in FIG. 19B is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When including a transistor using an oxide semiconductor and having an extremely low off-state current, the semiconductor device described above can retain stored data for a long time. In other words, power consumption of the semiconductor device can be reduced because refresh operation becomes unnecessary or the frequency of refresh operation can be extremely low. Moreover, stored data can be retained for a long time even when power is not supplied (note that a potential is preferably fixed).

In the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the state of the transistor (on or off), whereby high-speed operation can be achieved.

### <CPU>

A CPU including a semiconductor device such as any of the above-described transistors or the above-described memory device is described below.

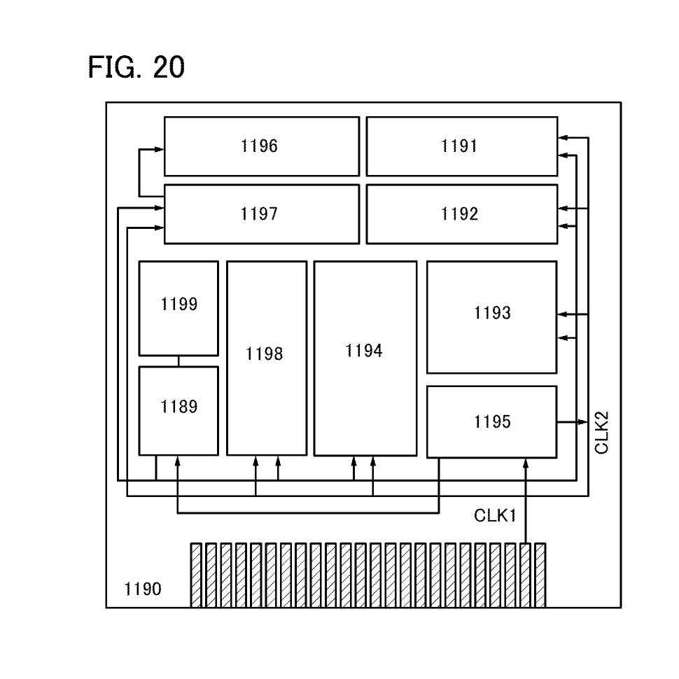

FIG. 20 is a block diagram illustrating a configuration example of a CPU including any of the above-described transistors as a component.

The CPU illustrated in FIG. 20 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and a ROM interface 1189. A semiconductor substrate, an SOI substrate, a glass substrate, or the like is used as the substrate 1190. The ROM 1199 and the ROM interface 1189 may be provided over a separate chip. Needless to say, the CPU in FIG. 20 is just an example in which the configuration has been simplified, and an actual CPU may have a variety of configurations depending on the application. For example, the CPU may have the following configuration: a structure including the CPU illustrated in FIG. 20 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

In the CPU illustrated in FIG. 20, a memory cell is provided in the register 1196. For the memory cell of the register 1196, any of the above-described transistors, the above-described memory device, or the like can be used.

In the CPU illustrated in FIG. 20, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

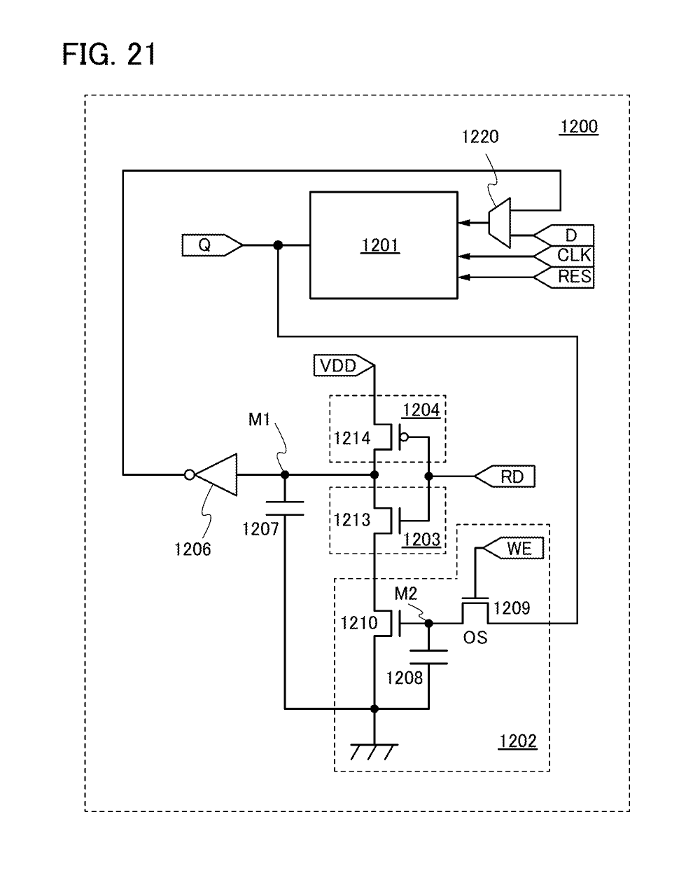

FIG. 21 is an example of a circuit diagram of a memory element 1200 that can be used as the register 1196. The memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the gate of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 21 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 21, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 21, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor. Further alternatively, in the memory element 1200, a transistor in which a channel is formed in an oxide semiconductor may be included besides the transistor 1209, and a transistor in which a channel is formed in a layer formed using a semiconductor other than an oxide semiconductor or in the substrate 1190 can be used for the rest of the transistors.

As the circuit 1201 in FIG. 21, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### [Configuration Example]

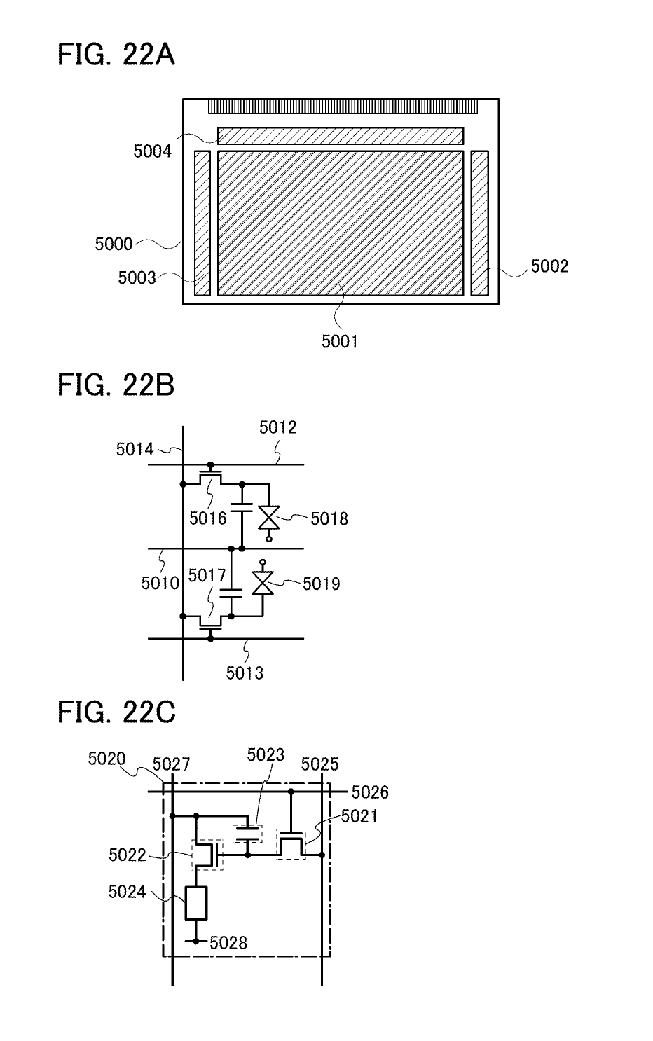

FIG. 22A is a top view of a display device of one embodiment of the present invention. FIG. 22B illustrates a pixel circuit where a liquid crystal element is used for a pixel of a display device of one embodiment of the present invention. FIG. 22C illustrates a pixel circuit where an organic EL element is used for a pixel of a display device of one embodiment of the present invention.

Any of the above-described transistors can be used as a transistor used for the pixel. Here, an example in which an n-channel transistor is used is shown. Note that a transistor manufactured through the same steps as the transistor used for the pixel may be used for a driver circuit. Thus, by using any of the above-described transistors for a pixel or a driver circuit, the display device can have high display quality and/or high reliability.

FIG. 22A illustrates an example of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Furthermore, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 22B illustrates an example of a circuit configuration of the pixel. Here, a pixel circuit which is applicable to a pixel of a VA liquid crystal display device, or the like is illustrated.

This pixel circuit can be applied to a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A scan line 5012 of a transistor 5016 and a scan line 5013 of a transistor 5017 are separated so that different gate signals can be supplied thereto. In contrast, a signal line 5014 is shared by the transistors 5016 and 5017. Any of the above-described transistors can be used as appropriate as each of the transistors 5016 and 5017. Thus, the liquid crystal display device can have high display quality and/or high reliability.

The shapes of a first pixel electrode electrically connected to the transistor 5016 and a second pixel electrode electrically connected to the transistor 5017 are described. The first pixel electrode and the second pixel electrode are separated. Shapes of the first pixel electrode and the second pixel electrode are not especially limited. For example, the first pixel electrode may have a V-like shape.

A gate electrode of the transistor 5016 is electrically connected to the scan line 5012, and a gate electrode of the transistor 5017 is electrically connected to the scan line 5013. When different gate signals are supplied to the scan line 5012 and the scan line 5013, operation timings of the transistor 5016 and the transistor 5017 can be varied. As a result, alignment of liquid crystals can be controlled.

Furthermore, a capacitor may be formed using a capacitor line 5010, a gate insulator functioning as a dielectric, and a capacitor electrode electrically connected to the first pixel electrode or the second pixel electrode.

The pixel structure is a multi-domain structure in which a first liquid crystal element 5018 and a second liquid crystal element 5019 are provided in one pixel. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 22B. For example, a switch, a resistor, a capacitor, a transistor, a sensor, a logic circuit, or the like may be added to the pixel circuit shown in FIG. 22B.

### [Organic EL Panel]

FIG. 22C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, a current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 22C illustrates an example of a pixel circuit. Here, one pixel includes two n-channel transistors. Note that any of the above-described transistors can be used as the n-channel transistors. Furthermore, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, any of the above-described transistors can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby a current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that a current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply a current to the light-emitting element 5024 in accordance with the video signal and perform analog grayscale driving.

Note that in the display device of one embodiment of the present invention, a pixel configuration is not limited to that shown in FIG. 22C. For example, a switch, a resistor, a capacitor, a sensor, a transistor, a logic circuit, or the like may be added to the pixel circuit shown in FIG. 22C.

In the case where any of the above-described transistors is used for the circuit shown in FIGS. 22A to 22C, the source electrode (the first electrode) is electrically connected to the low potential side and the drain electrode (the second electrode) is electrically connected to the high potential side. Furthermore, the potential of the first gate electrode may be controlled by a control circuit or the like and the potential described above as an example, e.g., a potential lower than the potential applied to the source electrode, may be input to the second gate electrode.

### <Electronic Device>

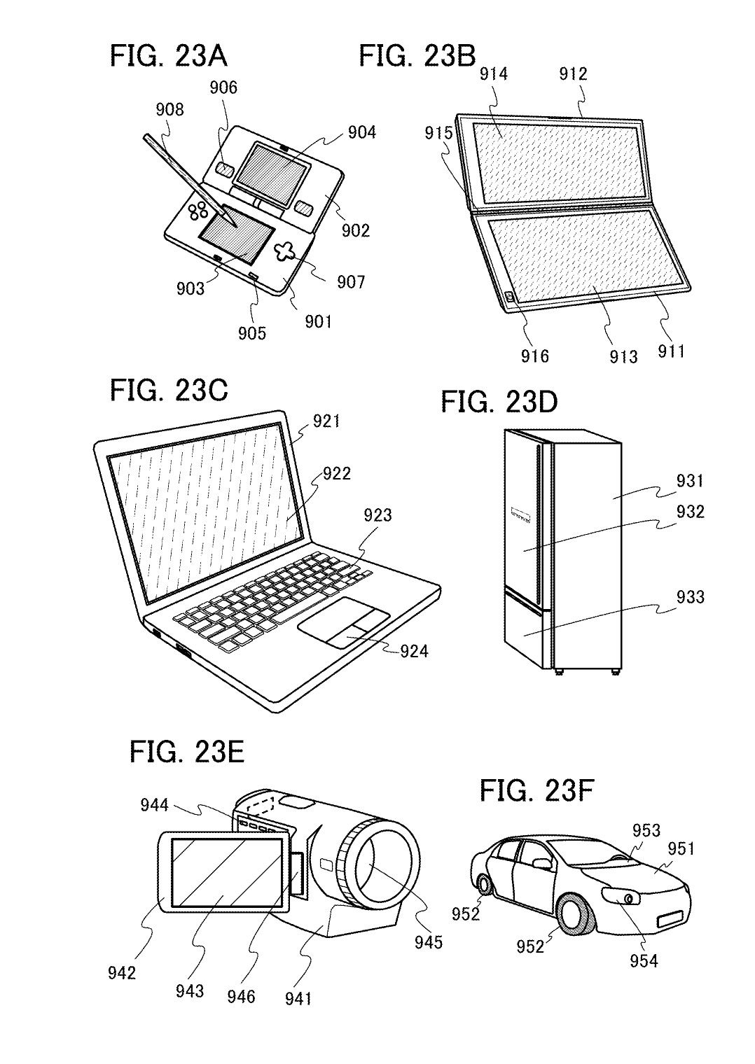

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 23A to 23F illustrate specific examples of these electronic devices.

FIG. 23A illustrates a portable game console including a housing 901, a housing 902, a display portion 903, a display portion 904, a microphone 905, a speaker 906, an operation key 907, a stylus 908, and the like. Although the portable game console in FIG. 23A has the two display portions 903 and 904, the number of display portions included in a portable game console is not limited to this.

FIG. 23B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched in accordance with the angle at the joint 915 between the first housing 911 and the second housing 912. A display device with a position input function may be used as at least one of the first display portion 913 and the second display portion 914. Note that the position input function can be added by providing a touch panel in a display device. Alternatively, the position input function can be added by providing a photoelectric conversion element called a photosensor in a pixel portion of a display device.

FIG. 23C illustrates a laptop personal computer, which includes a housing 921, a display portion 922, a keyboard 923, a pointing device 924, and the like.

FIG. 23D illustrates an electric refrigerator-freezer, which includes a housing 931, a door for a refrigerator 932, a door for a freezer 933, and the like.

FIG. 23E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 23F illustrates an ordinary vehicle including a car body 951, wheels 952, a dashboard 953, lights 954, and the like.

This application is based on Japanese Patent Application serial no. 2014-095302 filed with Japan Patent Office on May 2, 2014, Japanese Patent Application serial no. 2014-102747 filed with Japan Patent Office on May 16, 2014, and Japanese Patent Application serial no. 2014-126083 filed with Japan Patent Office on Jun. 19, 2014, the entire contents of which are hereby incorporated by reference.

What is claimed is:

1. A method for manufacturing an oxide, comprising the step of:
by a magnetron sputtering method in which a magnetic field containing a component in a direction parallel to a substrate is applied, the magnetic field comprises a region with a magnetic flux density of greater than or equal to 10 G and less than or equal to 100 G, and a target is a crystal body or a polycrystalline body, making a crystal in the crystal body or the polycrystalline body have a pellet-like shape, fly in plasma, and be stacked on a formation surface to be arranged parallel or substantially parallel to the formation surface.

2. The method for manufacturing the oxide according to claim 1,
wherein the crystal having the pellet-like shape is charged up, and
wherein the magnetic field is rotated or moved with a beat of greater than or equal to 0.1 Hz and less than or equal to 1 kHz with respect to the formation surface to arrange the crystal having the pellet-like shape on the formation surface.

3. A method for manufacturing an oxide,
wherein the oxide is formed by a magnetron sputtering method,
wherein the magnetron sputtering method comprises a first step and a second step,
wherein a magnetic field containing a component in a direction parallel to a top surface of a substrate is applied in the first step and the second step,
wherein a target used in the magnetron sputtering method comprises a region with a polycrystalline structure,
wherein the target is placed to face the substrate,
wherein the target comprises a crystal grain,
wherein in the first step, the crystal grain has a pellet-like shape and flies in plasma, and
wherein in the second step, the crystal grain having the pellet-like shape is stacked on the top surface of the substrate to be arranged parallel or substantially parallel to the top surface.

4. A method for manufacturing an oxide with a sputtering apparatus, comprising a first step, a second step, and a third step,
wherein the sputtering apparatus comprises a target, a substrate, and a magnet unit,
wherein the target comprises indium, zinc, oxygen, and an element M selected from the group consisting of aluminum, gallium, yttrium, and tin,
wherein the target comprises a region with a polycrystalline structure,
wherein the target is placed to face the substrate,
wherein the magnet unit is placed on a back side of the target and comprises a first magnet whose N pole is on the target side, a second magnet whose S pole is on the target side, and a base,
wherein a magnetic field is formed between the first magnet and the second magnet,
wherein the first step comprises a step in which the substrate and the magnet unit are moved or rotated relatively,
wherein the first step comprises a step in which a potential difference is applied between the target and the substrate to generate plasma,
wherein the first step comprises a step in which an ion generated in the plasma is made to collide with a front side of the target to separate a flat-plate oxide,
wherein the flat-plate oxide comprises: a first layer comprising the element M, zinc, and oxygen; a second layer comprising indium and oxygen; and a third layer comprising the element M, zinc, and oxygen,
wherein the second step comprises a step in which the flat-plate oxide is negatively charged by passing through the plasma and then approaches a top surface of the substrate while maintaining a crystal structure,
wherein the third step comprises a step in which the flat-plate oxide moves over the top surface of the substrate and is then deposited by an effect of the magnetic field and a current flowing from the substrate toward the target.

5. The method for manufacturing the oxide according to claim 4, wherein a magnetic flux density of a horizontal magnetic field on the top surface of the substrate is greater than or equal to 10 G and less than or equal to 100 G.

6. The method for manufacturing the oxide according to claim 4,
wherein the magnet unit is rotated about a center of the base, and
wherein rotation speed of the magnet unit is greater than or equal to 0.1 Hz and less than or equal to 1 kHz.

7. The method for manufacturing the oxide according to claim 4, wherein an oxygen atom positioned on a side surface of the flat-plate oxide and bonded to an indium atom, an atom of the element M, or a zinc atom is negatively charged.

8. The method for manufacturing the oxide according to claim 7, wherein negatively charged oxygen atoms repel each other, thereby maintaining a shape of the flat-plate oxide.

9. The method for manufacturing the oxide according to claim 7, wherein the flat-plate oxide moves over the top surface of the substrate, the side surface of the flat-plate oxide is bonded to a side surface of another flat-plate oxide that has already been deposited, and the flat-plate oxide is then fixed to the top surface of the substrate.

10. The method for manufacturing the oxide according to claim 4, wherein when the flat-plate oxide is deposited on the top surface of the substrate, an angle between a normal vector of the top surface of the substrate and a c-axis is greater than or equal to −30° and less than or equal to 30°.

11. The method for manufacturing the oxide according to claim 4, wherein a composition formula of a crystalline oxide contained in the target is InMO₃(ZnO)ₘ, m is a natural number.

12. The method for manufacturing the oxide according to claim 4, wherein the ion is a positive oxygen ion.

13. A method for manufacturing an oxide, comprising the steps of:
applying a magnetic field containing a component in a direction parallel to a surface of a substrate facing a target, the target being a crystal body or a polycrystalline body, wherein the magnetic field comprises a region with a magnetic flux density of greater than or equal to 10 G and less than or equal to 100 G; and
stacking a crystal having a pellet-like shape in the crystal body or the polycrystalline body on the surface of the substrate by magnetron sputtering, the crystal having the pellet-like shape flying in a plasma and then being arranged parallel or substantially parallel to the surface of the substrate.
